(19) United States
(12) Patent Application Publication
(10) Pub. No.: US 2021/0173309 A1
(43) Pub. Date: Jun. 10, 2021

(54) METHOD OF FORMING REVERSED PATTERN AND METHOD OF MANUFACTURING ELECTRONIC DEVICE

(71) Applicant: FUJIFILM Corporation, Tokyo (JP)

(72) Inventor: Kyohei SAKITA, Haibara-gun, Shizuoka (JP)

(73) Assignee: FUJIFILM Corporation, Tokyo (JP)

(21) Appl. No.: 16/761,080

(22) PCT Filed: Sep. 3, 2018
(86) PCT No.: PCT/JP2018/032668

§ 371 Date: May 1, 2020

(30) Foreign Application Priority Data
Sep. 4, 2017 (JP) 2017-169261

(51) Int. Cl. G03F 7/40; G03F 7/004; C08F 220/28; C08F 212/14; G03F 7/038; G03F 7/039; H01L 21/027

(52) U.S. Cl. CPC G03F 7/40; G03F 7/0045; C08F 220/282; H01L 21/0274; G03F 7/038; G03F 7/039; C08F 212/22

(57) ABSTRACT

A method of forming a reversed pattern including: a step of forming a resist film on a substrate using a photosensitive composition having an A value of 0.14 or more, which is determined by Expression (1); a step of exposing the resist film to light; a step of developing the exposed resist film to form a resist pattern; a step of applying a pattern reversal film forming composition such that the resist pattern is coated and thereby forming a pattern reversal film; a step of performing etch-back on the pattern reversal film and exposing a surface of the resist pattern to light; and a step of removing the resist pattern to form the reversed pattern,

A=([H]×0.04+[C]×1.0+[N]×2.1+[O]×3.6+[F]×5.6+[S]×0.04+[I]×39.5)/([H]×1+[C]×12+[N]×14+[O]×16+[F]×19+[S]×32+[I]×127) Expression (1):

### BACKGROUND OF THE INVENTION

### 1. Field of the Invention

The present invention relates to a method of forming a reversed pattern and a method of manufacturing an electronic device.

### 2. Description of the Related Art

In the process of manufacturing a semiconductor device such as an integrated circuit (IC) and a large scale integrated circuit (LSI), microfabrication by lithography has been carried out, and techniques using pattern reversal film forming compositions are proposed (JP5282920B).

### SUMMARY OF THE INVENTION

On the other hand, according to the studies conducted by the present inventors, in a method described in JP5282920B, there is a case where the pattern reversal film forming compositions are not sufficiently embedded between the formed resist patterns, and therefore the pattern reversal film includes bubbles. As a result, there was a case in which a height of the formed pattern reversal film is uneven, or voids are included in the pattern reversal film.

Furthermore, in removal of the resist patterns which is performed during the formation of reversed patterns, there is room for further improvement with respect to removal selectivity of a resist pattern.

An object of the present invention is to provide a method of forming a reversed pattern which has an excellent embedability of a pattern reversal film forming composition between resist patterns and which is also excellent in the removal selectivity of a resist pattern.

In addition, the object of the present invention is also to provide a method of manufacturing an electronic device.

The present inventors have found that the above problems can be solved by the following configurations.

(I) A method of forming a reversed pattern comprising: a step of forming a resist film on a substrate using a photosensitive composition having an A value of 0.14 or more, which is determined by Expression (1) described later;
a step of exposing the resist film to light;
a step of developing the exposed resist film to form a resist pattern;
a step of applying a pattern reversal film forming composition such that the resist pattern is coated and thereby forming a pattern reversal film;
a step of performing etch-back on the pattern reversal film and exposing a surface of the resist pattern to light; and
a step of removing the resist pattern to form the reversed pattern.

(2) The method of forming a reversed pattern according to (1), in which the photosensitive composition includes a resin whose solubility in an alkaline developer increases and solubility in an organic solvent decreases due to increase in polarity by an action of an acid, and a photoacid generator consisting of a cationic moiety and an anionic moiety.

(3) The method of forming a reversed pattern according to (2), in which a content of the photoacid generator is 5% to 50% by mass with respect to a total solid content in the photosensitive composition.

(4) The method of forming a reversed pattern according to (2) or (3), in which the resin includes an acid group having an acid dissociation constant of 13 or less.

(5) The method of forming a reversed pattern according to (4), in which a content of the acid group is 0.80 to 4.50 mmol/g.

(6) The method of forming a reversed pattern according to any one of (2) to (5), in which an acid generated from the photoacid generator has a volume of 270 Å³ or more.

(7) The method of forming a reversed pattern according to any one of (1) to (6), in which the step of exposing is carried out with extreme ultraviolet rays.

(8) A method of manufacturing an electronic device which includes the method of forming a reversed pattern according to any one of (1) to (7).

According to an aspect of the present invention, a method of forming a reversed pattern which has an excellent embedability of a pattern reversal film forming composition between resist patterns and which is also excellent in the removal selectivity of a resist pattern can be provided.

In addition, according to the present invention, a method of manufacturing an electronic device can be provided.

### BRIEF DESCRIPTION OF THE DRAWINGS

FIG. 1 is a diagram for illustrating Step 1.

FIG. 2 is a diagram for illustrating Step 2.

FIG. 3 is a diagram for illustrating Step 3.

FIG. 4 is a diagram for illustrating Step 4.

FIG. 5 is a diagram for illustrating Step 5.

FIG. 6 is a diagram for illustrating Step 6.

### DESCRIPTION OF THE PREFERRED EMBODIMENTS

Hereinafter, an example according to an embodiment of the present invention will be described.

In the present specification, numerical values indicated by using the expression “to” mean a range including the numerical values indicated before and after the expression “to” as a lower limit and an upper limit.

In addition, in the indication of a group (atomic group) in the present specification, the indication not including substitution or unsubstitution includes a group having a substituent and also a group not having a substituent. For example, an “alkyl group” includes not only an alkyl group containing no substituent (unsubstituted alkyl group) but also an alkyl group having a substituent (substituted alkyl group).

In addition, the term “actinic rays” or “radiation” in the present invention indicates, for example, a bright line spectrum of mercury lamp, far ultraviolet rays represented by excimer laser light, extreme ultraviolet rays (EUV light), X-rays, a particle beam such as an electron beam and an ion beam, and the like. Furthermore, in the present invention, the “light” means actinic rays or radiation.

Furthermore, unless otherwise specified, the term “exposure” as used in the present specification includes not only exposure to a bright line spectrum of mercury lamp, far ultraviolet rays represented by excimer laser light, X-rays, extreme ultraviolet rays (EUV light), or the like but also lithography with a particle beam such as an electron beam and an ion beam.

In the present specification, the term “(meth)acrylic” includes both of acrylic and methacrylic and means “at least one of acrylic or methacrylic”. Similarly, “(meth)acrylic acid” means “at least one of acrylic acid or methacrylic acid”.

In the present specification, unless otherwise indicated, the weight-average molecular weight (Mw), the number-average molecular weight (Mn), and the dispersity (also referred to as a molecular weight distribution) (Mw/Mn) of a resin are defined as values in terms of polystyrene by gel permeation chromatography (GPC) measurement (solvent: tetrahydrofuran, flow amount (amount of a sample injected): 10 μL, columns: TSK gel Multipore HXL-M manufactured by Tosoh Corporation, column temperature: 40° C., flow rate: 1.0 mL/min, and detector: differential refractive index detector) using a GPC apparatus (HLC-8120GPC manufactured by Tosoh Corporation).

1 Å is 1×10⁻¹⁰ m.

A feature of the method of forming a reversed pattern of the present invention is that a photosensitive composition having an A value of a predetermined value or more, which will be described later, is used. The A value is a numerical value derived from atoms of materials constituting the photosensitive composition to be used, and the A value is large in a case where a large number of atoms such as iodine atoms, oxygen atoms, and fluorine atoms are included.

According to the studies conducted by the present inventors, the detailed mechanism by which a photosensitive composition having an A value of a predetermined value or more is used to obtain a predetermined effect is not clarified, but it is presumed that the physical properties of the photosensitive composition change so as to obtain the above effect. For example, regarding removal selectivity of a resist pattern, in a case where dry etching is performed during removal of the resist pattern as described later, the density of carbon atoms is decreased by including atoms capable of increasing the A value so as to facilitate dry etching, and as a result, it is presumed that removability of the resist pattern is improved. It is also presumed that affinity with a pattern reversal film forming composition is improved due to the presence of the atoms capable of increasing the A value, so that an embedability of a pattern reversal film forming composition is improved.

The method of forming a reversed pattern according to an embodiment of the present invention includes the following Steps 1 to 6.
Step 1: a step of forming a resist film on a substrate using a photosensitive composition having an A value of 0.14 or more, which is determined by Expression (1) described later.

Step 2: a step of exposing the resist film to light.

Step 3: a step of developing the exposed resist film to form a resist pattern.

Step 4: a step of applying a pattern reversal film forming composition such that the resist pattern is coated and thereby forming a pattern reversal film.

Step 5: a step of performing etch-back on the pattern reversal film and exposing a surface of the resist pattern to light.

Step 6: a step of removing the resist pattern to form the reversed pattern.

Hereinafter, each step will be described in detail.

[Step 1]

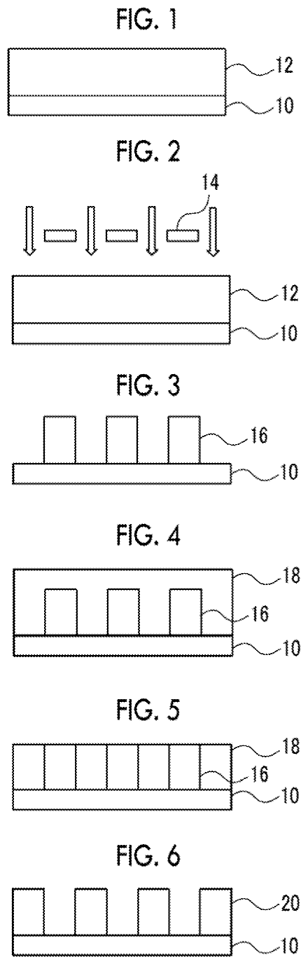

Step 1 is a step of forming a resist film on a substrate using a predetermined photosensitive composition. More specifically, as shown in FIG. 1, Step 1 is a step of forming a resist film 12 on a substrate 10.

Hereinafter, firstly, the photosensitive composition will be described in detail, and then the procedure of the steps will be described in detail.

The photosensitive composition (resist composition) has an A value of 0.14 or more determined by Expression (1) described later. As described above, in a case where the A value is high, a desired effect (an embedability of a pattern reversal film forming composition between resist patterns is excellent and removal selectivity of a resist pattern is also excellent) is obtained.

A=([H]×0.04+[C]×1.0+[N]×2.1+[O]×3.6+[F]×5.6+[S]×0.04+[I]×39.5)/([H]×1+[C]×12+[N]×14+[O]×16+[F]×19+[S]×32+[I]×127) Expression (1):

Particularly, from the viewpoint that at least one of a point in which the embedability of a pattern reversal film forming composition between the resist patterns is more excellent, or a point in which the removal selectivity of a resist pattern is more excellent is obtained (hereinafter, simply referred to as “a point in which the effect of the present invention is more excellent”), the A value is preferably 0.15 or more, more preferably 0.17 or more, and even more preferably 0.19 or more. An upper limit is not particularly limited, but is preferably 0.25 or less, more preferably 0.23 or less, from the viewpoint that a good resist pattern profile is easily obtained.

In addition, the photosensitive composition (resist composition) preferably has an A1 value of 0.14 or more, which is determined by Expression (1-1) described later. An upper limit is not particularly limited, but is preferably 0.25 or less, more preferably 0.23 or less, from the viewpoint that a good resist pattern profile is easily obtained.

A1=([H]×0.04+[C]×1.0+[N]×2.1+[O]×3.6+[F]×5.6+[S]×1.5+[I]×39.5)/([H]×1+[C]×12+[N]×14+[O]×16+[F]×19+[S]×32+[I]×127) Expression (1-1):

In Expression (1) (and Expression (1-1)), [H] represents a molar ratio of hydrogen atoms derived from a total solid content to all atoms of the total solid content in the photosensitive composition, [C] represents a molar ratio of carbon atoms derived from a total solid content to all atoms of the total solid content in the photosensitive composition, [N] represents a molar ratio of nitrogen atoms derived from a total solid content to all atoms of the total solid content in the photosensitive composition, [O] represents a molar ratio of oxygen atoms derived from a total solid content to all atoms of the total solid content in the photosensitive composition, [F] represents a molar ratio of fluorine atoms derived from a total solid content to all atoms of the total solid content in the photosensitive composition, [S] represents a molar ratio of sulfur atoms derived from a total solid content to all atoms of the total solid content in the photosensitive composition, and [I] represents a molar ratio of iodine atoms derived from a total solid content to all atoms of the total solid content in the photosensitive composition.

For example, in a case where the photosensitive composition includes a resin whose solubility in an alkaline developer increases and solubility in an organic solvent decreases due to increase in polarity by the action of an acid, a photoacid generator, an acid diffusion control agent, and a solvent, the resin, the photoacid generator, and the acid diffusion control agent correspond to the solid content. That is, all atoms of the total solid content correspond to a total of all atoms derived from the resin, all atoms derived from the photoacid generator, and all atoms derived from the acid diffusion control agent. For example, [H] represents a molar ratio of hydrogen atoms derived from a total solid content to all atoms of the total solid content, and in a case of describing based on the above example, [H] represents a molar ratio of a total of hydrogen atoms derived from the resin, hydrogen atoms derived from the photoacid generator, and hydrogen atoms derived from the acid diffusion control agent with respect to a total of all atoms derived from the resin, all atoms derived from the photoacid generator, and all atoms derived from the acid diffusion control agent.

In a case where a structure and a content of constituent components of the total solid content in the photosensitive composition are known, the A value and the A1 value can be calculated by calculating a ratio of the number of atoms included. In addition, even in a case where the constituent components are unknown, it is possible to calculate a ratio of the number of constituting atoms by an analytical method such as elemental analysis with respect to a resist film obtained by evaporating solvent components of the photosensitive composition.

Furthermore, as described below, the exposure may be performed using EUV light.

On the other hand, since EUV light has a wavelength of 13.5 nm and has a shorter wavelength than ArF (wavelength of 193 nm) light or the like, the number of incident photons in a case of being exposed with the same sensitivity is small. Therefore, the influence of “photon shot noise”, in which the number of photons varies stochastically, is large, and LER (line edge roughness) is deteriorated. In order to reduce the photon shot noise, there is a method of increasing the exposure amount to increase the number of incident photons, but which causes a trade-off with a demand for higher sensitivity. In addition, there is also a method of increasing a thickness of the resist film to increase the number of absorbed photons, but which causes a decrease in resolution.

In contrast, the present inventors have found that in a case where the A value is high, EUV light absorption of the resist film formed of the photosensitive composition is high. It has been found that in a case where the A value is within the above described predetermined range, the LER of the resist pattern is also excellent in a case where the exposure to EUV light is performed.

The photosensitive composition may be either a positive tone or a negative tone, but a positive tone is preferable. Exposed portions are more easily dissolved by an alkaline developer.

The constituent components of the photosensitive composition are not particularly limited as long as the constituent components satisfy the above A value, but typically, the photosensitive composition includes a resin whose solubility in an alkaline developer increases and solubility in an organic solvent decreases due to increase in polarity by the action of an acid, and a resin which includes a photoacid generator or includes a repeating unit containing a photoacid generating group, and whose solubility in an alkaline developer increases and solubility in an organic solvent decreases due to increase in polarity by the action of an acid. Particularly, as will be described later, the photosensitive composition preferably includes a resin whose solubility in an alkaline developer increases and solubility in an organic solvent decreases due to increase in polarity by the action of an acid, and a photoacid generator consisting of a cationic moiety and an anionic moiety.

Hereinafter, the components which may be included in the photosensitive composition will be described in detail.

<(A) Resin Whose Solubility in Alkaline Developer Increases and Solubility in Organic Solvent Decreases Due to Increase in Polarity by Action of Acid>

The photosensitive composition preferably includes a resin (hereinafter, referred to as a “resin (A)”) whose solubility in an alkaline developer increases and solubility in an organic solvent decreases due to increase in polarity by the action of an acid. In addition, as described later, the resin (A) may include a repeating unit containing a photoacid generating group.

Particularly, the resin (A) preferably includes an acid group having an acid dissociation constant (pKa) of 13 or less. As described above, the acid dissociation constant of the acid group is preferably 13 or less, more preferably 3 to 13, and even more preferably 5 to 10.

In a case where the photosensitive composition includes an acid group having a predetermined pKa, preservation stability of the photosensitive composition is excellent, and an excellent development is carried out.

Examples of the acid group having an acid dissociation constant (pKa) of 13 or less include a carboxyl group, a phenolic hydroxyl group, a fluorinated alcohol group (preferably, a hexafluoroisopropanol group), a sulfonic acid group, and a sulfonamide group.

In a case where the resin (A) includes an acid group having a pKa of 13 or less, a content of the acid group in the resin (A) is not particularly limited, but the content is often 0.20 to 6.00 mmol/g. Particularly, 0.80 to 4.50 mmol/g is preferable, 1.20 to 4.50 mmol/g is more preferable, and 1.60 to 4.00 mmol/g is even more preferable, from the viewpoint that the effect of the present invention is more excellent.

(Repeating Unit Having a Structure in which a Polar Group is Protected by Leaving Group Capable of Leaving by Action of Acid)

The resin (A) preferably includes a repeating unit having a structure in which a polar group is protected by a leaving group capable of leaving by the action of an acid. That is, the resin (A) preferably includes a repeating unit which contains a group capable of decomposing by the action of an acid to generate a polar group. In a resin including the repeating unit, solubility of the resin in alkaline developer increases and solubility of the resin in an organic solvent decreases due to increase in polarity by an action of acid.

A polar group in the repeating unit having a structure in which the polar group is protected by a leaving group capable of leaving by the action of an acid (an acid-decomposable group) preferably includes an alkali-soluble group, and examples thereof include an acid group such as a carboxyl group, a phenolic hydroxyl group, a fluorinated alcohol group, a sulfonic acid group, a sulfonamide group, a sulfonylimide group, an (alkylsulfonyl) (alkylcarbonyl) methylene group, an (alkylsulfonyl) (alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, or a tris(alkylsulfonyl)methylene group, an alcoholic hydroxyl group, and the like.

Among these, the polar group preferably includes a carboxyl group, a phenolic hydroxyl group, a fluorinated alcohol group (preferably, a hexafluoroisopropanol group), or a sulfonic acid group.

Examples of the leaving group capable of leaving by the action of an acid include groups represented by Formulae (Y1) to (Y4).

—C(Rx₁)(Rx₂)(Rx₃) Formula (Y1):

—C(═O)OC(Rx₁)(Rx₂)(Rx₃) Formula (Y2):

—C(R₃₆)(R₃₇)(OR₃₈) Formula (Y3):

—C(Rn)(H)(Ar) Formula (Y4):

In Formulae (Y1) and (Y2), Rx₁ to Rx₃ each independently represent an alkyl group (linear or branched) or a cycloalkyl group (monocyclic or polycyclic). In a case where all of Rx₁ to Rx₃ are alkyl groups, it is preferable that at least two of Rx₁, Rx₂, or Rx₃ are methyl groups.

Among these, it is preferable that Rx₁ to Rx₃ each independently represent a linear or branched alkyl group, and it is more preferable that Rx₁ to Rx₃ each independently represent a linear alkyl group.

Two of Rx₁ to Rx₃ may be bonded to each other to form a ring (monocyclic or polycyclic).

As the alkyl group of Rx₁ to Rx₃, an alkyl group having 1 to 4 carbon atoms such as a methyl group, an ethyl group, an n-propyl group, an isopropyl group, an n-butyl group, an isobutyl group, and a t-butyl group is preferable.

As the cycloalkyl group of Rx₁ to Rx₃, a monocyclic cycloalkyl group such as a cyclopentyl group and a cyclohexyl group, or a polycyclic cycloalkyl group such as a norbornyl group, a tetracyclodecanyl group, a tetracyclododecanyl group, and an adamantyl group is preferable.

As the cycloalkyl group formed by the bonding of two of Rx₁ to Rx₃ to each other, a monocyclic cycloalkyl group such as a cyclopentyl group and a cyclohexyl group, or a polycyclic cycloalkyl group such as a norbornyl group, a tetracyclodecanyl group, a tetracyclododecanyl group, and an adamantyl group is preferable, and a monocyclic cycloalkyl group having 5 or 6 carbon atoms is more preferable.

In the cycloalkyl group formed by the bonding of two of Rx₁ to Rx₃ to each other, for example, one of the methylene groups constituting the ring may be substituted with a heteroatom such as an oxygen atom, or with a group having a heteroatom such as a carbonyl group.

An embodiment of the group represented by Formula (Y1) or Formula (Y2), for example, in which Rx₁ is a methyl group or an ethyl group, and Rx₂ and Rx₃ are bonded to each other to form the above described cycloalkyl group, is preferable.

In Formula (Y3), R₃₆ and R₃₇ each independently represent a hydrogen atom or a monovalent organic group. R₃₈ represents a monovalent organic group. R₃₇ and R₃₈ may be bonded to each other to form a ring. Examples of the monovalent organic group include an alkyl group, a cycloalkyl group, an aryl group, an aralkyl group, an alkenyl group, and the like. R₃₆ is also preferably a hydrogen atom.

As Formula (Y3), a group represented by Formula (Y3-1) is preferable.

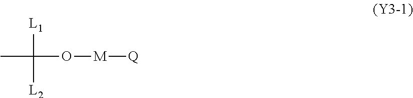

Here, L₁ and L₂ each independently represent a hydrogen atom, an alkyl group, a cycloalkyl group, an aryl group, or a group obtained by a combination thereof (for example, a group obtained by combining an alkyl group and an aryl group).

M represents a single bond or a divalent linking group.

Q represents an alkyl group which may include a heteroatom, a cycloalkyl group which may include a heteroatom, an aryl group which may include a heteroatom, an amino group, an ammonium group, a mercapto group, a cyano group, an aldehyde group or a group obtained by a combination thereof (for example, a group obtained by combining an alkyl group and a cycloalkyl group).

In the alkyl group and the cycloalkyl group, for example, one of the methylene groups may be substituted with a heteroatom such as an oxygen atom, or with a group having a heteroatom such as a carbonyl group.

It is preferable that at least one of L₁ or L₂ is a hydrogen atom, and the other one is an alkyl group, a cycloalkyl group, an aryl group, or a group obtained by combining an alkylene group and an aryl group.

At least two of Q, M, or L₁ may be bonded to each other to form a ring (preferably a 5- or 6-membered ring).

From the viewpoint of fining of the resist pattern, L₂ is preferably a secondary or tertiary alkyl group, and more preferably a tertiary alkyl group. Examples of the secondary alkyl group include an isopropyl group, a cyclohexyl group, and a norbornyl group, and examples of the tertiary alkyl group include a tert-butyl group and adamantane. In these embodiments, since Tg (glass transition temperature) and activation energy are high, suppression of fogging can be achieved in addition to secured film hardness.

In Formula (Y4), Ar represents an aromatic ring group. Rn represents an alkyl group, a cycloalkyl group, or an aryl group. Rn and Ar may be bonded to each other to form a non-aromatic ring. Ar is preferably an aryl group.

As the repeating unit having a structure in which a polar group is protected by a leaving group capable of leaving by the action of an acid, a repeating unit represented by Formula (A) is preferable.

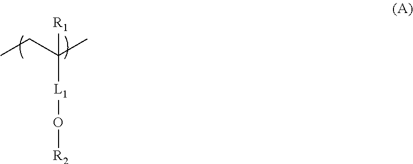

L₁ represents a divalent linking group which may have a fluorine atom or an iodine atom, R₁ represents a hydrogen atom, a fluorine atom, an iodine atom, or an alkyl group which may have a fluorine atom or an iodine atom, and R₂ represents a leaving group capable of leaving by the action of an acid may have a fluorine atom or an iodine atom. However, at least one of L₁, R₁, or R₂ has a fluorine atom or an iodine atom.

L₁ represents a divalent linking group which may have a fluorine atom or an iodine atom. Examples of the divalent linking group which may have a fluorine atom or an iodine atom include —CO—, —O—, —S—, —SO—, —SO₂—, a hydrocarbon group which may have a fluorine atom or an iodine atom, (for example, an alkylene group, a cycloalkylene group, an alkenylene group, an arylene group, and the like), and a linking group formed by connecting plural groups thereof. Among these, from the viewpoint that the effect of the present invention is more excellent, L₁ is preferably —CO—, or an arylene group or an alkylene group containing a fluorine atom or an iodine atom.

As the arylene group, a phenylene group is preferable.

The alkylene group may be linear or branched. The number of carbon atoms in the alkylene group is not particularly limited, 1 to 10 is preferable, and 1 to 3 is more preferable.

The total number of fluorine atoms and iodine atoms included in the alkylene group having a fluorine atom or an iodine atom is not particularly limited, but is preferably 2 or more, more preferably 2 to 10, and even more preferably 3 to 6, from the viewpoint that the effect of the present invention is more excellent.

R₁ represents a hydrogen atom, a fluorine atom, an iodine atom, or an alkyl group which may have a fluorine atom or an iodine atom.

The alkyl group may be linear or branched. The number of carbon atoms in the alkyl group is not particularly limited, 1 to 10 is preferable, and 1 to 3 is more preferable.

The total number of fluorine atoms and iodine atoms included in the alkyl group having a fluorine atom or an iodine atom is not particularly limited, but is preferably 1 or more, more preferably 1 to 5, and even more preferably 1 to 3, from the viewpoint that the effect of the present invention is more excellent.

R₂ represents a leaving group capable of leaving by the action of an acid and may have a fluorine atom or an iodine atom.

Among these, examples of the leaving group include groups represented by Formulae (Z1) to (Z4).

—C(Rx₁₁)(Rx₁₂)(Rx₁₃) Formula (Z1):

—C(═O)OC(Rx₁₁)(Rx₁₂)(Rx₁₃) Formula (Z2):

—C(R₁₃₆)(R₁₃₇)(OR₁₃₈) Formula (Z3):

—C(Rn₁)(H)(Ar₁) Formula (Z4):

In Formulae (Z1) and (Z2), Rx₁₁ to Rx₁₃ each independently represent an alkyl group which may have a fluorine atom or an iodine atom (linear or branched), or represent a cycloalkyl group which may have a fluorine atom or an iodine atom (monocyclic or polycyclic). In a case where all of Rx₁₁ to Rx₁₃ are alkyl groups (linear or branched), it is preferable that at least two of Rx₁₁, Rx₁₂, or Rx₁₃ are methyl groups.

Rx₁₁ to Rx₁₃ are the same as Rx₁ to Rx₃ in the above described (Y1) and (Y2) except that Rx₁₁ to Rx₁₃ may have a fluorine atom or an iodine atom, and the definition and the preferred range of the alkyl group and the cycloalkyl group are the same as Rx₁ to Rx₃.

R₁₃₆ and R₁₃₇ in Formula (Z3) each independently represent a hydrogen atom, or a monovalent organic group which may have a fluorine atom or an iodine atom. R₁₃₈ represents a monovalent organic group which may have a fluorine atom or an iodine atom. R₁₃₇ and R₁₃₈ may be bonded to each other to form a ring. Examples of the monovalent organic group which may have a fluorine atom or an iodine atom include an alkyl group which may have a fluorine atom or an iodine atom, a cycloalkyl group which may have a fluorine atom or an iodine atom, an aryl group which may have a fluorine atom or an iodine atom, an aralkyl group which may have a fluorine atom or an iodine atom, and a group obtained by a combination thereof (for example, a group obtained by combining an alkyl group and a cycloalkyl group).

The alkyl group, the cycloalkyl group, the aryl group, and the aralkyl group may include a heteroatom such as an oxygen atom, in addition to the fluorine atom and the iodine atom. That is, in the alkyl group, the cycloalkyl group, the aryl group, and the aralkyl group, for example, one of the methylene groups may be substituted with a heteroatom such as an oxygen atom, or with a group having a heteroatom such as a carbonyl group.

As Formula (Z3), a group represented by Formula (Z3-1) is preferable.

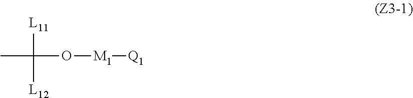

Here, L₁₁ and L₁₂ are each independently represent: a hydrogen atom; an alkyl group which may have a heteroatom selected from the group consisting of a fluorine atom, an iodine atom, and an oxygen atom; a cycloalkyl group which may have a heteroatom selected from the group consisting of a fluorine atom, an iodine atom, and an oxygen atom; an aryl group which may have a heteroatom selected from the group consisting of a fluorine atom, an iodine atom, and an oxygen atom; or a group obtained by a combination thereof (for example, a group obtained by combining an alkyl group and a cycloalkyl group each of which may have a heteroatom selected from the group consisting of a fluorine atom, an iodine atom, and an oxygen atom).
M₁ represents a single bond or a divalent linking group.
Q₁ represents: an alkyl group which may have a heteroatom selected from the group consisting of a fluorine atom, an iodine atom, and an oxygen atom; a cycloalkyl group which may have a heteroatom selected from the group consisting of a fluorine atom, an iodine atom, and an oxygen atom; an aryl group which may have a heteroatom selected from the group consisting of a fluorine atom, an iodine atom, and an oxygen atom; an amino group; an ammonium group; a mercapto group; a cyano group; an aldehyde group; or a group obtained by a combination thereof (for example, a group obtained by combining an alkyl group and a cycloalkyl group each of which may have a heteroatom selected from the group consisting of a fluorine atom, an iodine atom, and an oxygen atom).

Ar₁ in Formula (Y4) represents an aromatic ring group which may have a fluorine atom or an iodine atom. Rn₁ represents an alkyl group which may have a fluorine atom or an iodine atom, a cycloalkyl group which may have a fluorine atom or an iodine atom, or an aryl group which may have a fluorine atom or an iodine atom. Rn₁ and Ar₁ may be bonded to each other to form a non-aromatic ring.

As the repeating unit having a structure in which a polar group is protected by a leaving group capable of leaving by the action of an acid, a repeating unit represented by General Formula (AI) is also preferable.

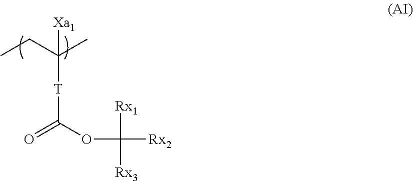

In General Formula (AI),
Xa₁ represents a hydrogen atom, or an alkyl group which may have a substituent.
T represents a single bond or a divalent linking group.
Rx₁ to Rx₃ each independently represent an alkyl group ((linear or branched) or a cycloalkyl group (monocyclic or polycyclic). In a case where all of Rx₁ to Rx₃ are alkyl groups (linear or branched), it is preferable that at least two of Rx₁, Rx₂, or Rx₃ are methyl groups.
Two of Rx₁ to Rx₃ may be bonded to each other to form a cycloalkyl group (monocyclic or polycyclic).

Examples of the alkyl group, which may have a substituent and which is represented by Xa₁, include a methyl group or a group represented by —CH₂—R₁₁. R₁₁ represents a halogen atom (such as a fluorine atom), a hydroxyl group, or a monovalent organic group, examples thereof include an alkyl group having 5 or less carbon atoms and an acyl group having 5 or less carbon atoms, and R₁₁ is preferably an alkyl group having 3 or less carbon atoms, and more preferably a methyl group. As Xa₁, a hydrogen atom, a methyl group, a trifluoromethyl group, or a hydroxymethyl group is preferable.

Examples of the divalent linking group represented by T include an alkylene group, an aromatic ring group, a —COO-Rt- group, an —O-Rt- group, and the like. In the formulae, Rt represents an alkylene group or a cycloalkylene group.
T is preferably a single bond or a —COO-Rt- group. In a case where T represents a —COO-Rt- group, Rt is preferably an alkylene group having 1 to 5 carbon atoms, and more preferably a —CH₂— group, or a —(CH₂)₂— group or a —(CH₂)₃— group.

As the alkyl group of Rx₁ to Rx₃, an alkyl group having 1 to 4 carbon atoms such as a methyl group, an ethyl group, an n-propyl group, an isopropyl group, an n-butyl group, an isobutyl group, and a t-butyl group is preferable.

As the cycloalkyl group of Rx₁ to Rx₃, a monocyclic cycloalkyl group such as a cyclopentyl group and a cyclohexyl group, or a polycyclic cycloalkyl group such as a norbornyl group, a tetracyclodecanyl group, a tetracyclododecanyl group, and an adamantyl group is preferable.

As the cycloalkyl group formed by the bonding of two of Rx₁ to Rx₃ to each other, a monocyclic cycloalkyl group such as a cyclopentyl group and a cyclohexyl group is preferable, and a polycyclic cycloalkyl group such as a norbornyl group, a tetracyclodecanyl group, a tetracyclododecanyl group, and an adamantyl group is also preferable. Among these, a monocyclic cycloalkyl group having 5 to 6 carbon atoms is preferable.

In the cycloalkyl group formed by the bonding of two of Rx₁ to Rx₃ to each other, for example, one of the methylene groups constituting the ring may be substituted with a heteroatom such as an oxygen atom, or with a group having a heteroatom such as a carbonyl group.

An embodiment of the repeating unit represented by General Formula (AI), for example, in which Rx₁ is a methyl group or an ethyl group, and Rx₂ and Rx₃ are bonded to each other to form the above described cycloalkyl group, is preferable.

In a case where each of the above groups has a substituent, examples of the substituent include an alkyl group (having 1 to 4 carbon atoms), a halogen atom, a hydroxyl group, an alkoxy group (having 1 to 4 carbon atoms), a carboxyl group, an alkoxycarbonyl group (having 2 to 6 carbon atoms), and the like. The number of carbon atoms in the substituent is preferably 8 or less.

The repeating unit represented by General Formula (AI) is preferably an acid-decomposable tertiary alkyl (meth)acrylate ester-based repeating unit (a repeating unit in which Xa₁ represents a hydrogen atom or a methyl group, and T represents a single bond).

A content of the repeating unit having a structure in which a polar group is protected by a leaving group capable of leaving by the action of an acid is preferably 15% to 80% by mol, more preferably 20% to 70% by mol, and even more preferably 25% to 60% by mol, with respect to a total repeating unit in the resin (A).

(Repeating Unit Containing Acid Group)

The resin (A) may include a repeating unit containing an acid group.

The acid group is preferably the above described acid group having a pKa of 13 or less.

The repeating unit containing an acid group may have a fluorine atom or an iodine atom.

The repeating unit containing an acid group is preferably a repeating unit represented by Formula (B).

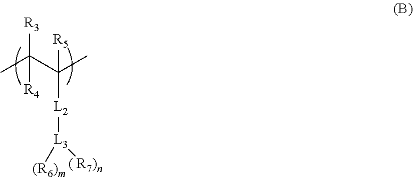

R₃ represents a hydrogen atom, or a monovalent organic group which may have a fluorine atom or an iodine atom.

The monovalent organic group which may have a fluorine atom or an iodine atom is preferably a group represented by -L₄-R₈. L₄ represents a single bond or an ester group. R₈ represents an alkyl group which may have a fluorine atom or an iodine atom, a cycloalkyl group which may have a fluorine atom or an iodine atom, an aryl group which may have a fluorine atom or an iodine atom, or a group obtained by a combination thereof.

R₄ and R₅ each independently represent a hydrogen atom, a fluorine atom, an iodine atom, or an alkyl group which may have a fluorine atom or an iodine atom.

L₂ represents a single bond or an ester group.
L₃ represents a (n+m+1)-valent aromatic hydrocarbon ring group or a (n+m+1)-valent alicyclic hydrocarbon ring group. Examples of the aromatic hydrocarbon ring group include a benzene ring group and a naphthalene ring group. The alicyclic hydrocarbon ring group may be monocyclic or polycyclic, and an example thereof includes a cycloalkyl ring group.
R₆ represents a hydroxyl group or a fluorinated alcohol group (preferably, a hexafluoroisopropanol group). In a case where R₆ is a hydroxyl group, L₃ is preferably a (n+m+1)-valent aromatic hydrocarbon ring group.
R₇ represents a halogen atom. Examples of the halogen atom include a fluorine atom, a chlorine atom, a bromine atom, and an iodine atom.
m represents an integer of 1 or more. m is preferably an integer of 1 to 3, and more preferably an integer of 1 or 2.
n represents 0 or an integer of 1 or more. n is preferably an integer of 1 to 4.
(n+m+l) is preferably an integer of 1 to 5.

The repeating unit containing an acid group is preferably a repeating unit represented by General Formula (I).

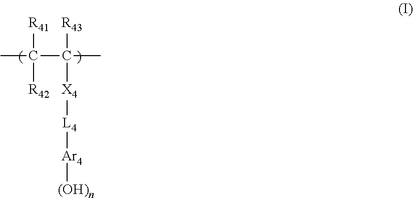

In General Formula (I),
R₄₁, R₄₂, and R₄₃ each independently represent a hydrogen atom, an alkyl group, a cycloalkyl group, a halogen atom, a cyano group, or an alkoxycarbonyl group. R₄₂ may be bonded to Ar₄ to form a ring, in which in this case, R₄₂ represents a single bond or an alkylene group.
X₄ represents a single bond, —COO—, or —CONR₆₄—, and R₆₄ represents a hydrogen atom or an alkyl group.
L₄ represents a single bond or an alkylene group.
Ar₄ represents a (n+1)-valent aromatic ring group, and represents an (n+2)-valent aromatic ring group in a case of being bonded to R₄₂ to form a ring.
n represents an integer of 1 to 5.

The alkyl groups for R₄₁, R₄₂, and R₄₃ in General Formula (I) are preferably alkyl groups having 20 or less carbon atoms, such as a methyl group, an ethyl group, a propyl group, an isopropyl group, an n-butyl group, a sec-butyl group, a hexyl group, a 2-ethylhexyl group, an octyl group, and a dodecyl group, more preferably an alkyl group having 8 or less carbon atoms, and even more preferably an alkyl group having 3 or less carbon atoms.

The cycloalkyl group for R₄₁, R₄₂, and R₄₃ in General Formula (I) may be monocyclic or polycyclic. Among these, a monocyclic cycloalkyl group having 3 to 8 carbon atoms, such as a cyclopropyl group, a cyclopentyl group, and a cyclohexyl group is preferable.

Examples of the halogen atom for R₄₁, R₄₂, and R₄₃ in General Formula (I) include a fluorine atom, a chlorine atom, a bromine atom, and an iodine atom, and a fluorine atom is preferable.

The alkyl group included in the alkoxycarbonyl group for R₄₁, R₄₂, and R₄₃ in General Formula (I) is preferably the same as the alkyl group for R₄₁, R₄₂, and R₄₃.

The preferable substituent in each of the above groups includes, for example, an alkyl group, a cycloalkyl group, an aryl group, an amino group, an amide group, a ureide group, a urethane group, a hydroxyl group, a carboxyl group, a halogen atom, an alkoxy group, a thioether group, an acyl group, an acyloxy group, an alkoxycarbonyl group, a cyano group, and a nitro group. The number of carbon atoms in the substituent is preferably 8 or less.

Ar₄ represents an (n+1)-valent aromatic ring group. The divalent aromatic ring group in a case where n is 1 may have a substituent, for example, an arylene group having 6 to 18 carbon atoms such as a phenylene group, a tolylene group, a naphthylene group, and an anthracenylene group, or an aromatic ring group containing a hetero ring such as a thiophene ring, a furan ring, a pyrrole ring, a benzothiophene ring, a benzofuran ring, a benzopyrrole ring, a triazine ring, an imidazole ring, a benzimidazole ring, a triazole ring, a thiadiazole ring, and a thiazole ring is preferable.

Specific examples of the (n+1)-valent aromatic ring group in a case where n is an integer of 2 or more include groups formed by removing an (n−1) number of any hydrogen atoms from the above described specific examples of the divalent aromatic ring group.

The (n+1)-valent aromatic ring group may further have a substituent.

Examples of the substituent which the above described alkyl group, cycloalkyl group, alkoxycarbonyl group, alkylene group, and (n+1)-valent aromatic ring group may have include alkyl groups exemplified for R₄₁, R₄₂, and R₄₃ in General Formula (I); alkoxy groups such as a methoxy group, an ethoxy group, a hydroxyethoxy group, a propoxy group, a hydroxypropoxy group, and a butoxy group; and aryl groups such as a phenyl group.

Examples of the alkyl group for R₆₄ (R₆₄ represents a hydrogen atom or an alkyl group) in the —CONR₆₄— represented by X₄ include alkyl groups having 20 or less carbon atoms, such as a methyl group, an ethyl group, a propyl group, an isopropyl group, an n-butyl group, a sec-butyl group, a hexyl group, a 2-ethylhexyl group, an octyl group, and a dodecyl group, and an alkyl group having 8 or less carbon atoms is preferable.

X₄ is preferably a single bond, —COO—, or —CONH—, and more preferably a single bond or —COO—.

The alkylene group of L4 is preferably an alkylene group having 1 to 8 carbon atoms, such as a methylene group, an ethylene group, a propylene group, a butylene group, a hexylene group, or an octylene group.

Ar₄ is preferably an aromatic ring group having 6 to 18 carbon atoms, and more preferably a benzene ring group, a naphthalene ring group, or a biphenylene ring group.

The repeating unit represented by General Formula (1) is preferably provided with a hydroxystyrene structure. That is, Ar₄ is preferably a benzene ring group.

The repeating unit represented by General Formula (I) is preferably a repeating unit represented by the following General Formula (1).

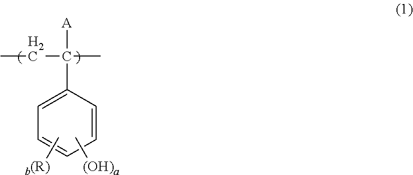

In General Formula (1),
A represents a hydrogen atom, an alkyl group, a cycloalkyl group, a halogen atom, or a cyano group.
R represents a halogen atom, an alkyl group, a cycloalkyl group, an aryl group, an alkenyl group, an aralkyl group, an alkoxy group, an alkylcarbonyloxy group, an alkylsulfonyloxy group, an alkyloxycarbonyl group, or an aryloxycarbonyl group, and a plurality of R's may be the same as or different from one another. A plurality of R's may form a ring together with one another. R is preferably a hydrogen atom.
a represents an integer of 1 to 3.
b represents an integer of 0 to (3-a).

Specific examples of the repeating unit represented by General Formula (I) are shown below, but the present invention is not limited thereto. In Formulae, a represents 1 or 2.

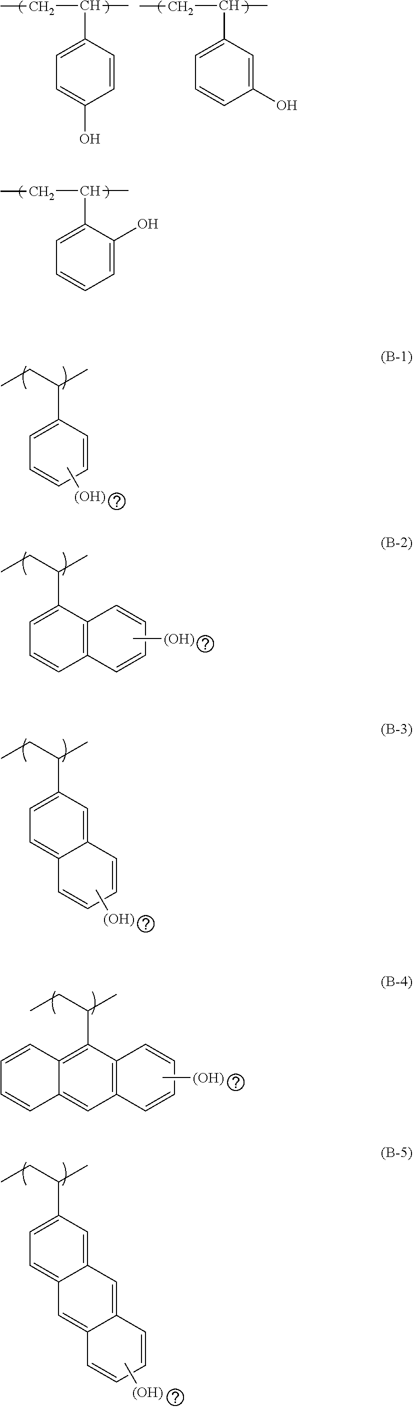

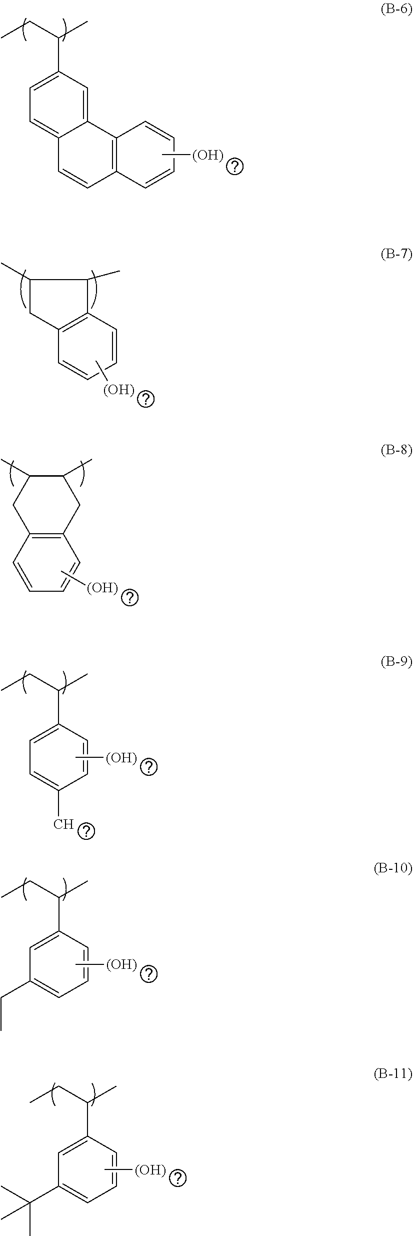

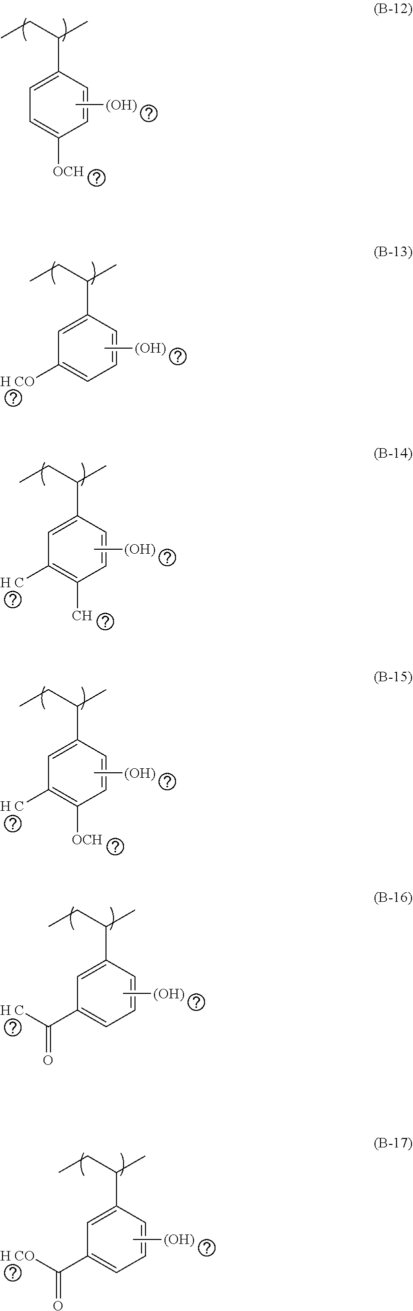

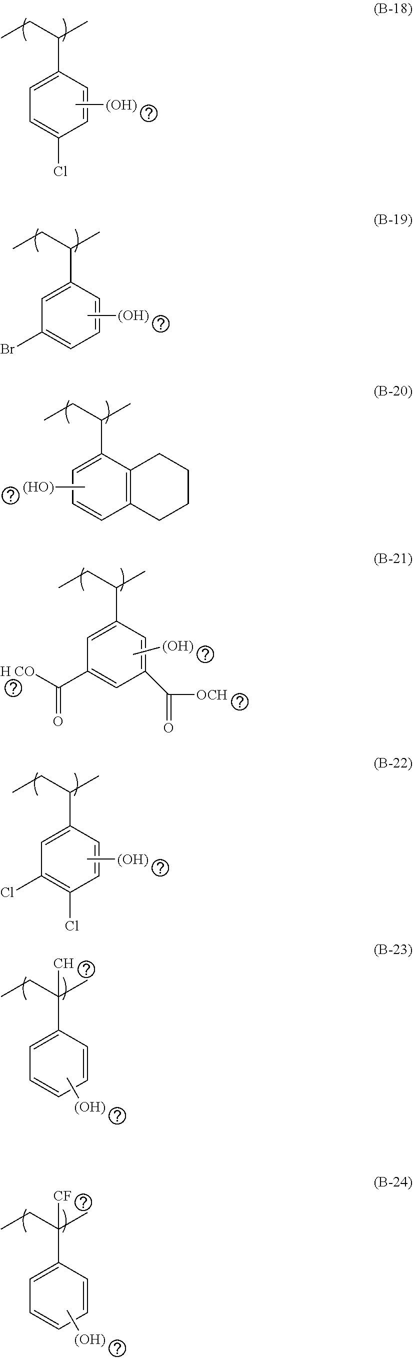

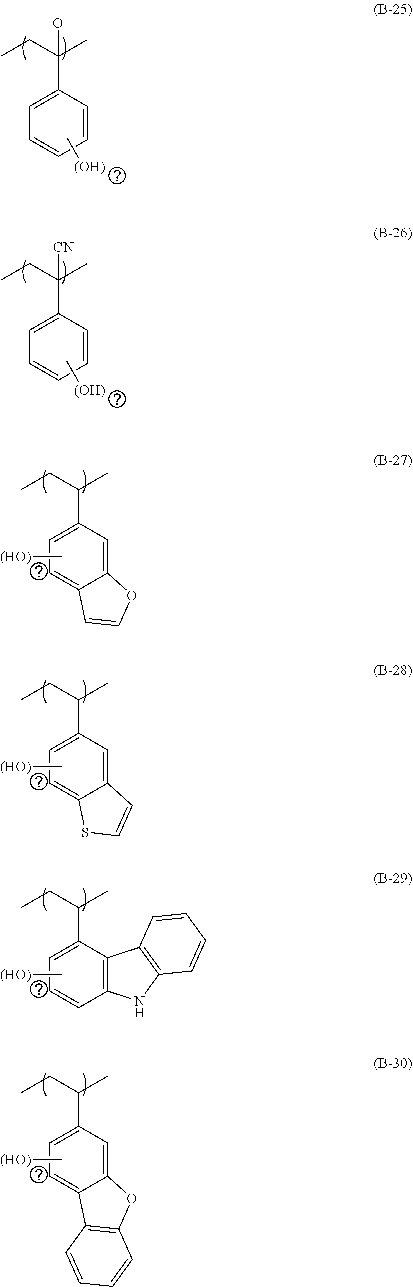

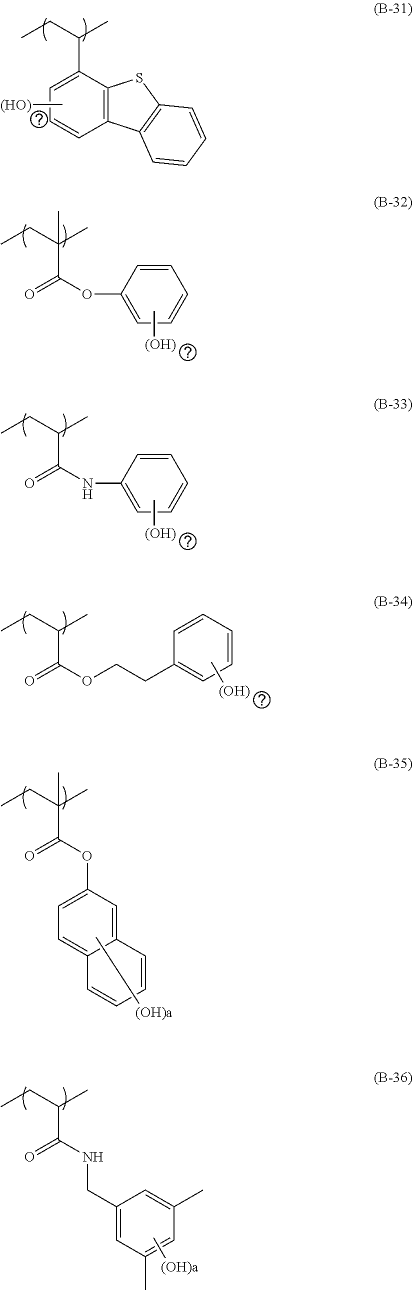

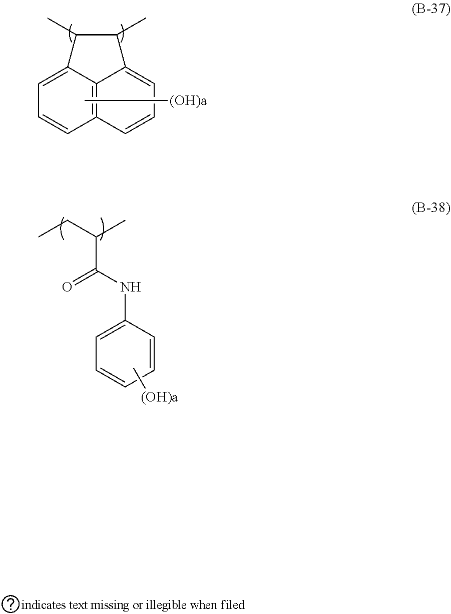

Among the above repeating units, the following repeating units specifically described are preferable. In Formulae, R represents a hydrogen atom or a methyl group, and a represents 2 or 3.

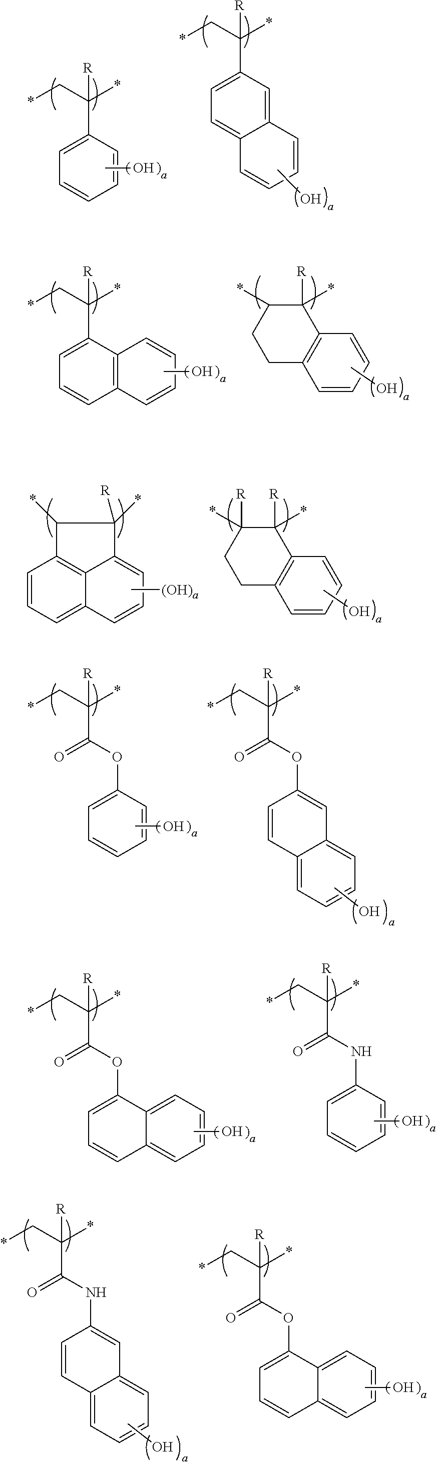

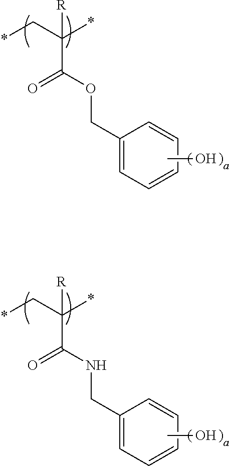

A content of the repeating unit containing an acid group is preferably 10% to 70% by mol, more preferably 15% to 65% by mol, and even more preferably 20% to 60% by mol, with respect to a total repeating unit in the resin (A).

(Repeating Unit Containing Fluorine Atom or Iodine Atom)

The resin (A) may include a repeating unit having a fluorine atom or an iodine atom, in addition to the above described (repeating unit having a structure in which a polar group is protected by a leaving group capable of leaving by the action of an acid) and (repeating unit containing an acid group).

That is, the repeating unit having a fluorine atom or an iodine atom includes neither a structure in which a polar group is protected by a leaving group capable of leaving by the action of an acid nor an acid group.

The repeating unit having a fluorine atom or an iodine atom is preferably a repeating unit represented by Formula (C).

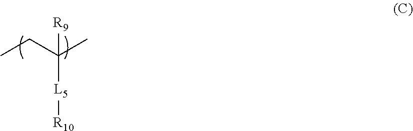

L₅ represents a single bond or an ester group.

R₉ represents a hydrogen atom, or an alkyl group which may have a fluorine atom or an iodine atom.

R₁₀ represents a hydrogen atom, an alkyl group which may have a fluorine atom or an iodine atom, a cycloalkyl group which may have a fluorine atom or an iodine atom, an aryl group which may have a fluorine atom or an iodine atom, or a group obtained by a combination thereof.

A content of the repeating unit having a fluorine atom or an iodine atom is preferably 0% to 50% by mol, more preferably 5% to 45% by mol, and even more preferably 10% to 40% by mol, with respect to a total repeating unit in the resin (A).

As described above, from the viewpoint that (the repeating unit having a structure in which a polar group is protected by a leaving group capable of leaving by the action of an acid) and (the repeating unit containing an acid group) are not included in the repeating unit having a fluorine atom or an iodine atom, the content of the above described repeating units having a fluorine atom or an iodine atom also intends to a content of repeating units having a fluorine atom or an iodine atom in which (the repeating unit having a structure in which a polar group is protected by a leaving group capable of leaving by the action of an acid) and (the repeating unit containing an acid group) are excluded.

As described above, the repeating unit having a structure in which a polar group is protected by a leaving group capable of leaving by the action of an acid may have a fluorine atom or an iodine atom, and the repeating unit containing an acid group may have a fluorine atom or an iodine atom.

In the repeating units of the resin (A), a total content of the repeating units including at least one of a fluorine atom or an iodine atom is preferably 20% to 100% by mol, and more preferably 30% to 100% by mol, and even more preferably 40% to 100% by mol, with respect to a total repeating unit in the resin (A).

Examples of the repeating units including at least one of a fluorine atom or an iodine atom include a repeating unit having a fluorine atom or an iodine atom and having a structure in which a polar group is protected by a leaving group capable of leaving by the action of an acid, a repeating unit having a fluorine atom or an iodine atom and having an acid group, and a repeating unit having a fluorine atom or an iodine atom.

(Repeating Unit Containing Lactone Group)

The resin (A) may further include a repeating unit containing a lactone group.

Any group having a lactone structure can be used as the lactone group, but the lactone structure is preferably a 5- to 7-membered lactone structure, and more preferably a structure in which another ring structure is fused to a 5- to 7-membered lactone structure in a form that forms a bicyclo structure or a Spiro structure. The resin (A) preferably includes a repeating unit which contains a group having a lactone structure represented by any one of General Formulae (LC1-1) to (LC1-17). In addition, a group having a lactone structure may be directly bonded to a main chain. The lactone structure is preferably a lactone structure represented by General Formula (LC1-1), General Formula (LC1-4), General Formula (LC1-5), General Formula (LC1-6), General Formula (LC1-13), or General Formula (LC1-14).

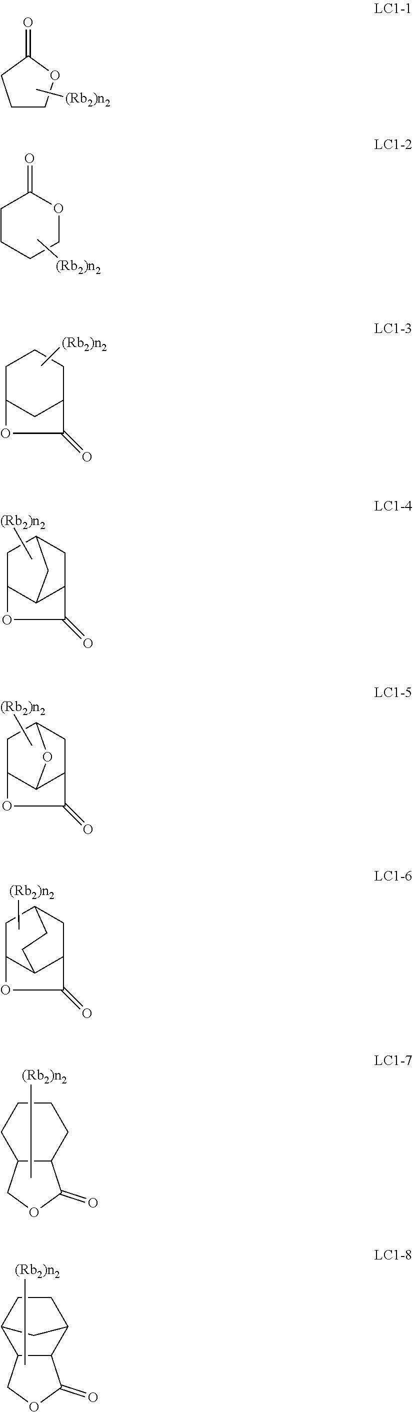

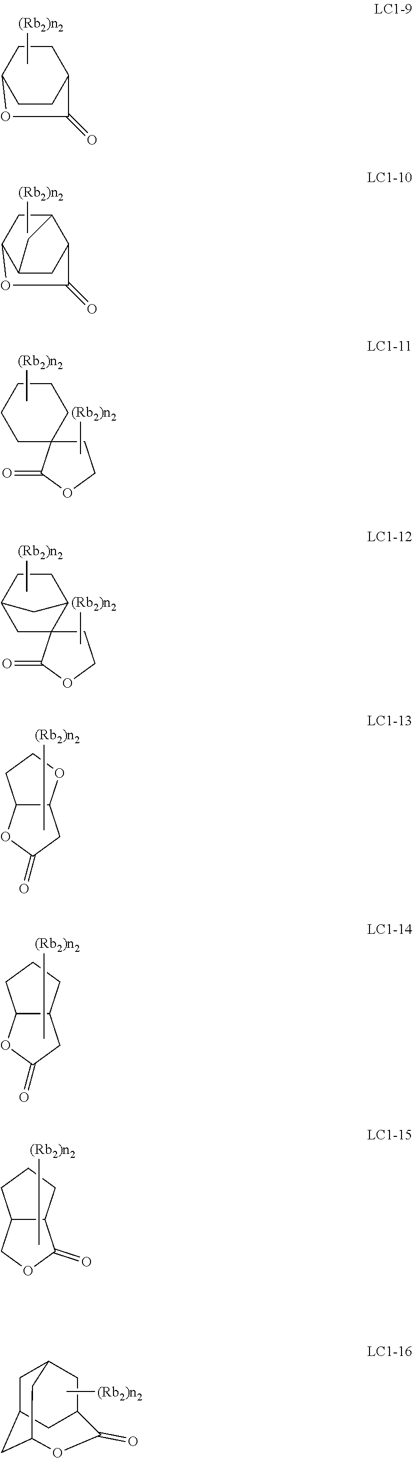

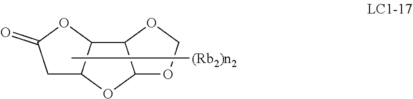

The lactone structure moiety may have a substituent (Rb₂). Preferred examples of the substituent (Rb₂) include an alkyl group having 1 to 8 carbon atoms, a cycloalkyl group having 4 to 7 carbon atoms, an alkoxy group having 1 to 8 carbon atoms, an alkoxycarbonyl group having 1 to 8 carbon atoms, a carboxyl group, a halogen atom, a hydroxyl group, a cyano group, and an acid-decomposable group. n² represents an integer of 0 to 4. In a case where n² is 2 or more, a plurality of Rb₂'s may be different from one another or the plurality of Rb₂'s may be bonded to each other to form a ring.

Examples of the repeating unit which contains a group having a lactone structure represented by any one of General Formulae (LC1-1) to (LC1-17) include a repeating unit represented by General Formula (AI), and the like.

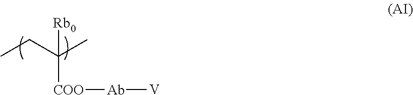

In General Formula (AI), Rb₀ represents a hydrogen atom, a halogen atom, or an alkyl group having 1 to 4 carbon atoms.

The substituent which the alkyl group of Rb₀ may have is preferably a hydroxyl group and a halogen atom.

Examples of the halogen atom of Rb₀ include a fluorine atom, a chlorine atom, a bromine atom, and an iodine atom. Rb₀ is preferably a hydrogen atom or a methyl group.

Ab represents a single bond, an alkylene group, a divalent linking group having a monocyclic or polycyclic alicyclic hydrocarbon structure, an ether group, an ester group, a carbonyl group, a carboxyl group, or a divalent group obtained by a combination thereof. In particular, Ab is preferably a single bond or a linking group represented by -Ab₁-CO₂—. Ab₁ is a linear or branched alkylene group or a monocyclic or polycyclic cycloalkylene group, and preferably a methylene group, an ethylene group, a cyclohexylene group, an adamantylene group, or a norbornylene group.

V represents a group formed by removing one optional hydrogen atom from the lactone structure represented by any one of General Formulae (LC1-1) to (LC1-17).

In the repeating unit which contains a group having a lactone structure, optical isomers are typically present, but any of the optical isomers may be used. In addition, one optical isomer may be used alone, or a mixture of a plurality of the optical isomers may be used. In a case where one optical isomer is mainly used, the optical purity (ee) thereof is preferably 90 or more, and more preferably 95 or more.

Specific examples of the repeating unit which contains a group having a lactone structure are shown below, but the present invention is not limited thereto.

(In the Formula Rx is H, CH₃, CH₂OH, or CF₃)

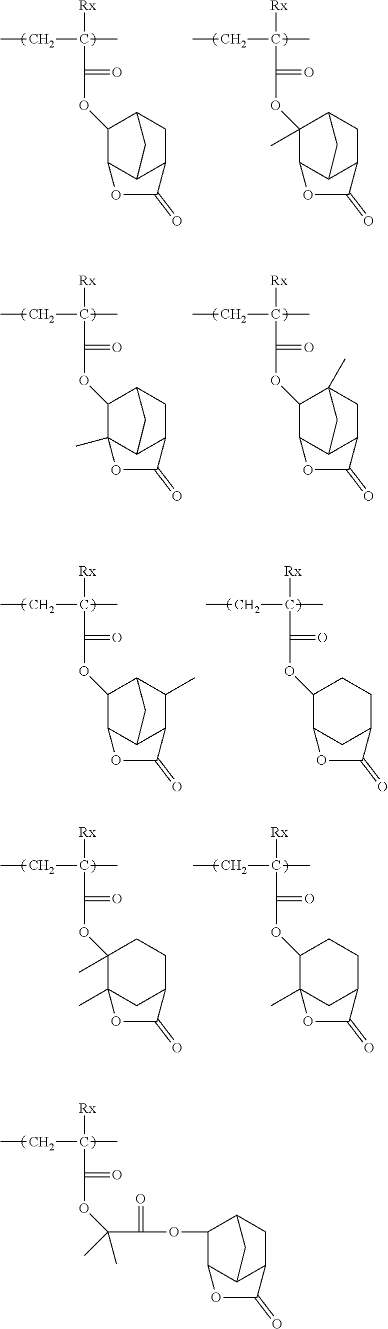

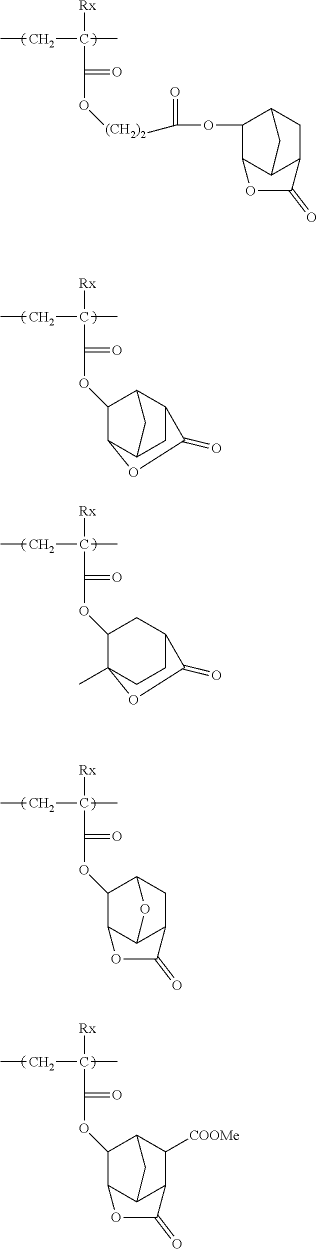

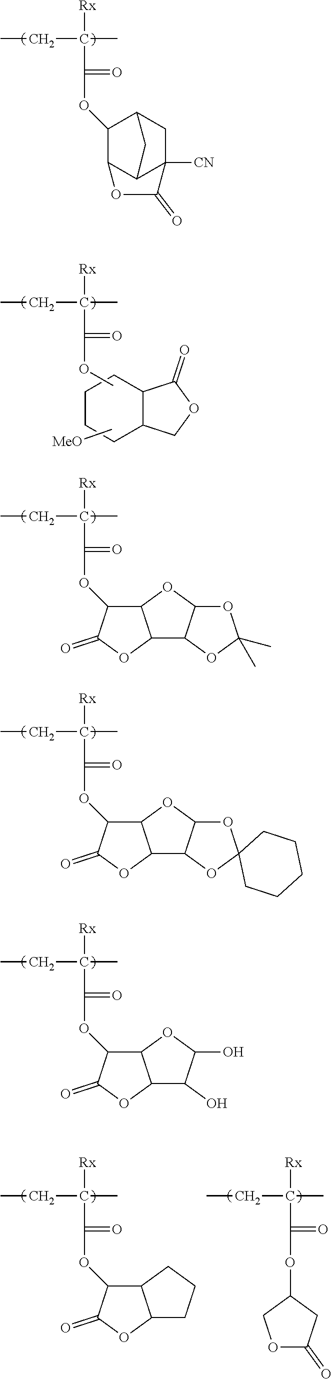

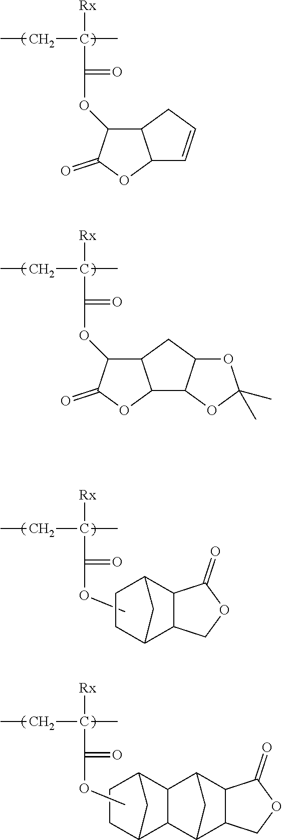

A content of the repeating unit which contains a lactone group is preferably 1 to 30% by mol, more preferably 5 to 25% by mol, and even more preferably 5 to 20% by mol, with respect to a total repeating unit in the resin (A).

(Repeating Unit Containing Photoacid Generating Group)

As a repeating unit other than the above described repeating units, the resin (A) may include a repeating unit containing a group (hereinafter, referred to as a photoacid generating group) which generates an acid upon irradiation with actinic rays or radiation can also be included.

In this case, it can be considered that the repeating unit containing a photoacid generating group corresponds to a compound (referred to as a “photoacid generator”) that generates an acid upon irradiation with actinic rays or radiation, which will be described later.

Examples of such the repeating unit include a repeating unit represented by General Formula (4).

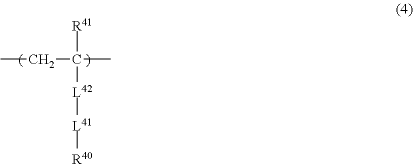

R⁴¹ represents a hydrogen atom or a methyl group. L⁴¹ represents a single bond or a divalent linking group. L⁴² represents a divalent linking group. R⁴⁰ represents a structural moiety which decomposes to generate an acid in a side chain upon irradiation with actinic rays or radiation.

Specific examples of the repeating unit represented by General Formula (4) are shown below, but the present invention is not limited thereto.

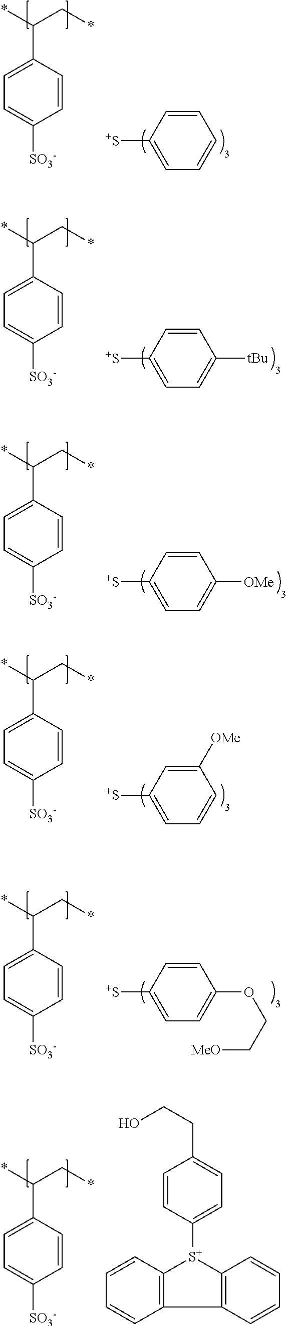

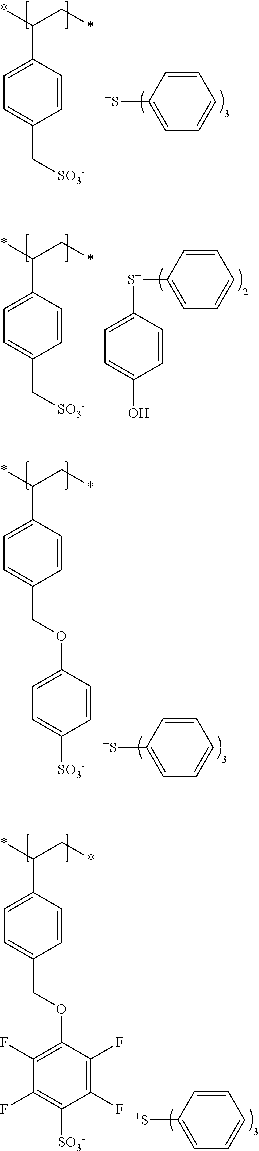

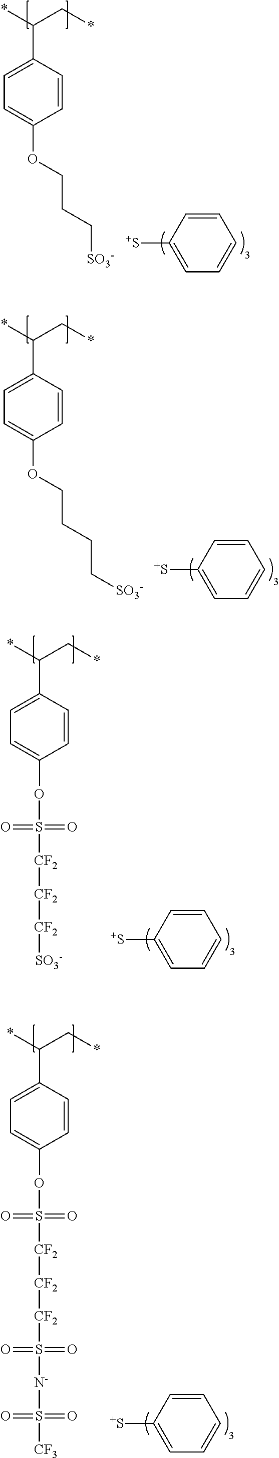

Other examples of the repeating unit represented by General Formula (4) include the repeating units described in paragraphs [0094] to [0105] of JP2014-041327A.

In a case where the resin (A) includes the repeating unit containing a photoacid generating group, a content of the repeating unit which contains a photoacid generating group is preferably 1% to 40% by mole, more preferably 5% to 35% by mole, and even more preferably 5% to 30% by mole, with respect to a total repeating unit in the resin (A).

(Repeating Unit Represented by General Formula (V-1) or General Formula (V-2))

The resin (A) may have a repeating unit represented by General Formula (V-1) or General Formula (V-2).

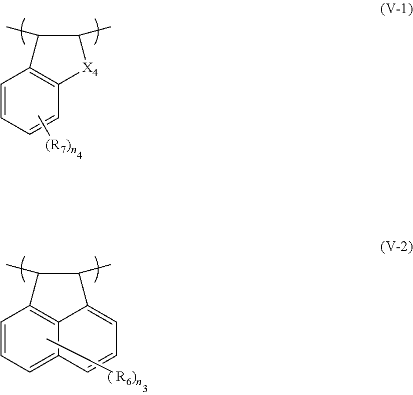

In Formulae,

R₆ and R₇ each independently represent a hydrogen atom, a hydroxyl group, a linear, branched or cyclic alkyl group having 1 to 10 carbon atoms, an alkoxy group or an acyloxy group, a cyano group, a nitro group, an amino group, a halogen atom, an ester group (—OCOR or —COOR: R is a fluorinated alkyl group or an alkyl group having 1 to 6 carbon atoms) or a carboxyl group.

n₃ represents an integer of 0 to 6.

n₄ represents an integer of 0 to 4.

X₄ is a methylene group, an oxygen atom, or a sulfur atom.

Specific examples of the repeating unit represented by General Formula (V-1) or (V-2) are shown below, but the present invention is not limited thereto.

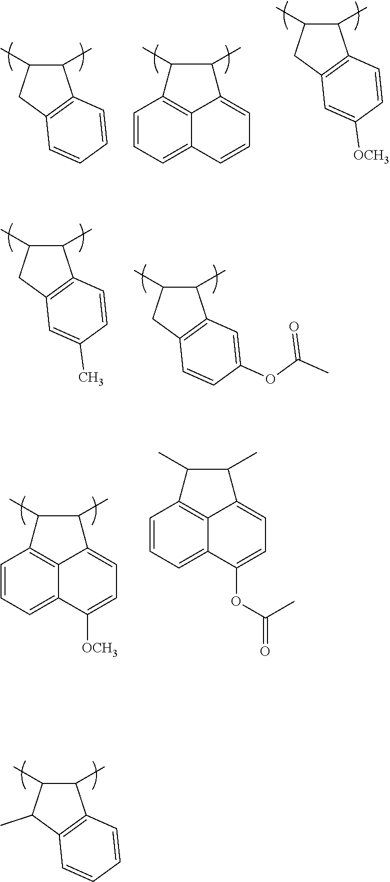

The resin (A) preferably has a high glass transition temperature (Tg) from the viewpoint of suppressing excessive diffusion of the generated acid or resist pattern collapse during development. The Tg is preferably higher than 90° C., more preferably higher than 100° C., even more preferably higher than 110° C., and particularly preferably higher than 125° C. The Tg is preferably 400° C. or lower and more preferably 350° C. or lower, from the viewpoint of good dissolution rate in developer.

In the present specification, the glass transition temperature (Tg) of the resin (A) is calculated by the following method. First, the Tg of a homopolymer consisting only of each repeating unit included in the resin (A) is calculated by the Bicerano method. Hereinafter, the calculated Tg is referred to as a “Tg of repeating unit”. Next, a mass ratio (%) of each repeating unit with respect to a total repeating unit in the resin (A) is calculated. Next, the product of Tg of each repeating unit and the mass ratio of the repeating unit is calculated, respectively, and the calculated resultants are summed to obtain Tg (° C.) of the resin (A).

The Bicerano method is described in Prediction of polymer properties, Marcel Dekker Inc, New York (1993), or the like. In addition, calculation of Tg by the Bicerano method can be performed using a software for estimating physical properties of a polymer, MDL Polymer (MDL Information Systems, Inc.).

In order to raise the Tg of the resin (A) to higher than 90° C., it is preferable to lower the mobility of the main chain of the resin (A). Examples of a method for lowering the mobility of the main chain of the resin (A) include the following (a) to (e) methods.

(a) Introduction of a bulky substituent into the main chain.

(b) Introduction of a plurality of substituents into the main chain.

(c) Introduction of a substituent causing an interaction between the resins (A) into the vicinity of the main chain.

(d) Formation of the main chain in a cyclic structure.

(e) Linking of a cyclic structure into the main chain.

The resin (A) preferably includes a repeating unit in which the homopolymer exhibits a Tg of 130° C. or higher.

In addition, kinds of the repeating units in which the homopolymer exhibits a Tg of 130° C. or higher are not particularly limited, and may be any of repeating units in which the homopolymer exhibits a Tg of 130° C. or higher, as calculated by the Bicerano method. Depending on kinds of functional groups in the repeating units represented by each of Formula (A) to Formula (E) which will be described later, it is determined that the repeating unit corresponds to a repeating unit in which the homopolymer exhibits a Tg of 130° C. or higher.

A specific example of an accomplishment unit of (a) may include a method of introducing the repeating unit represented by Formula (A) into the resin (A).

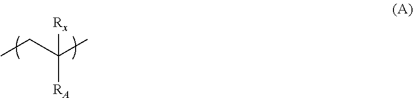

In Formula (A), R_{A} represents a group having a polycyclic structure. Rₓ represents a hydrogen atom, a methyl group, or an ethyl group. The group having a polycyclic structure is a group having a plurality of ring structures, and the plurality of ring structures may or may not be condensed.

Specific examples of the repeating unit represented by Formula (A) include the following repeating units.

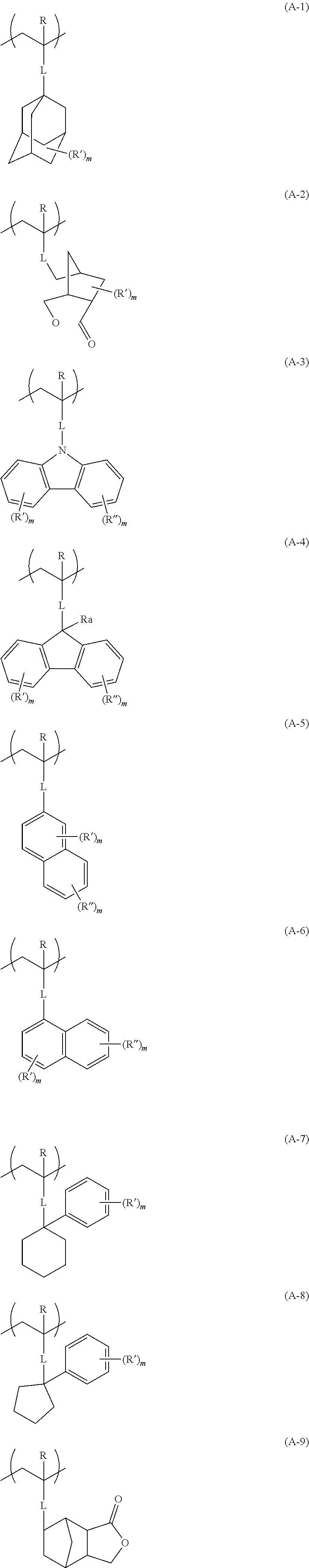

In the formulae, R represents a hydrogen atom, a methyl group, or an ethyl group.

Ra represents a hydrogen atom, an alkyl group, a cycloalkyl group, an aryl group, an aralkyl group, an alkenyl group, a hydroxyl group, an alkoxy group, an acyloxy group, a cyano group, a nitro group, an amino group, a halogen atom, an ester group (—OCOR′″ or —COOR′″: R′″ represents a fluorinated alkyl group or an alkyl group having 1 to 20 carbon atoms), or a carboxyl group. The alkyl group, the cycloalkyl group, the aryl group, the aralkyl group, and the alkenyl group each may have a substituent. In addition, the hydrogen atom bonded to a carbon atom in the group represented by Ra may be substituted with a fluorine atom or an iodine atom.

Furthermore, R′ and R″ each independently represent an alkyl group, a cycloalkyl group, an aryl group, an aralkyl group, an alkenyl group, a hydroxyl group, an alkoxy group, an acyloxy group, a cyano group, a nitro group, an amino group, a halogen atom, an ester group (—OCOR′″ or —COOR′″: R′″ represents a fluorinated alkyl group or an alkyl group having 1 to 20 carbon atoms), or a carboxyl group. The alkyl group, the cycloalkyl group, the aryl group, the aralkyl group, and the alkenyl group each may have a substituent. In addition, a hydrogen atom bonded to a carbon atom in the group represented by each of R′ and R″ may be substituted with a fluorine atom or an iodine atom.

L represents a single bond or a divalent linking group. Examples of the divalent linking group include —COO—, —CO—, —O—, —S—, —SO—, —SO₂—, an alkylene group, a cycloalkylene group, an alkenylene group, and a linking group formed by connecting plural groups thereof.

m and n each independently represent an integer of 0 or more. The upper limits of m and n are not particularly limited, but are 2 or less in many cases, and 1 or less in more cases.

A specific example of an accomplishment unit of (b) may include a method of introducing the repeating unit represented by Formula (B) into the resin (A).

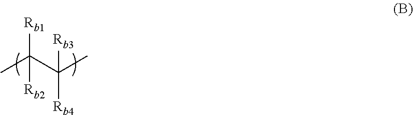

In Formula (B), R_{b1} to R_{b4} each independently represent a hydrogen atom or an organic group, and at least two or more of R_{b1}, . . . , or R_{b4} are organic groups.

Furthermore, in a case where at least one of the organic groups is a group in which a ring structure is directly linked to the main chain in the repeating unit, kinds of the other organic groups are not particularly limited.

In addition, in a case where all the organic groups are not a group in which a ring structure is directly linked to the main chain in the repeating unit, at least two or more of the organic groups are substituents having the number of the constituent atoms excluding hydrogen atoms of 3 or more.

Specific examples of the repeating unit represented by Formula (B) include the following repeating units.

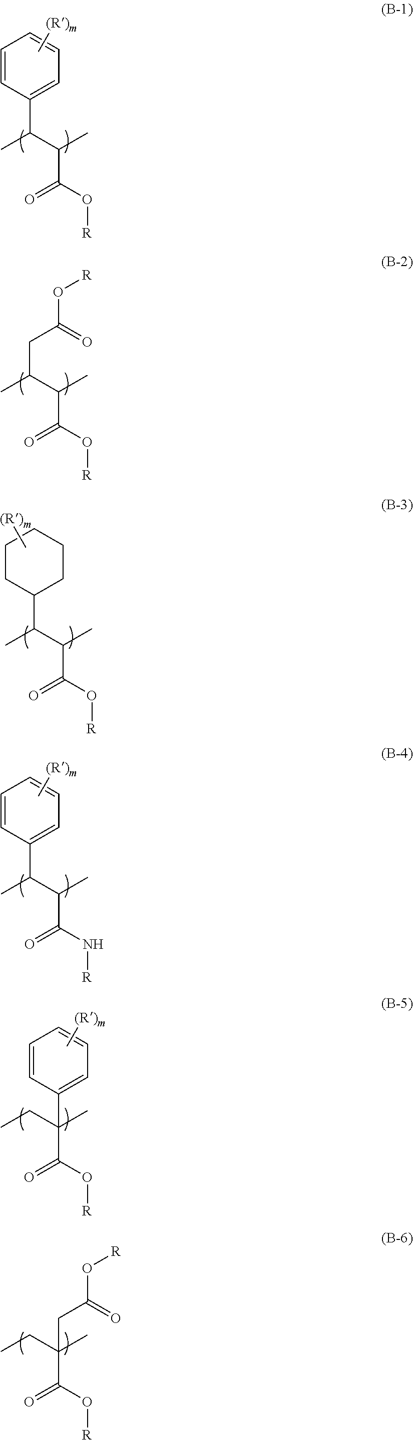

In Formulae, R′s each independently represent a hydrogen atom or an organic group. Examples of the organic group include an organic group such as an alkyl group, a cycloalkyl group, an aryl group, an aralkyl group, and an alkenyl group, each of which may have a substituent.

R″s each independently represent an alkyl group, a cycloalkyl group, an aryl group, an aralkyl group, an alkenyl group, a hydroxyl group, an alkoxy group, an acyloxy group, a cyano group, a nitro group, an amino group, a halogen atom, an ester group (—OCOR″ or —COOR″: R″ represents a fluorinated alkyl group or an alkyl group having 1 to 20 carbon atoms), or a carboxyl group. The alkyl group, the cycloalkyl group, the aryl group, the aralkyl group, and the alkenyl group each may have a substituent. In addition, the hydrogen atom bonded to a carbon atom in the group represented by R′ may be substituted with a fluorine atom or an iodine atom.

m represents an integer of 0 or more. The upper limit of m is not particularly limited, but is preferably 2 or less in many cases, and 1 or less in more cases.

A specific example of an accomplishment unit of (c) may include a method of introducing the repeating unit represented by Formula (C) into the resin (A).

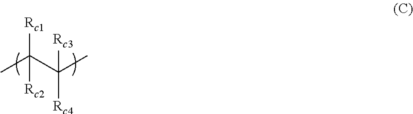

In Formula (C), R_{c1} to R_{c4} each independently represent a hydrogen atom or an organic group, and at least one of R_{c1}, . . . , or, R_{c4} is a group having hydrogen-bonding hydrogen atoms with the number of atoms of 3 or less from the main chain carbon. Among those, it is preferable that the group has hydrogen-bonding hydrogen atoms with the number of atoms of 2 or less (on a side closer to the vicinity of the main chain) to cause an interaction between the main chains of the resin (A).

Specific examples of the repeating unit represented by Formula (C) include the following repeating units.

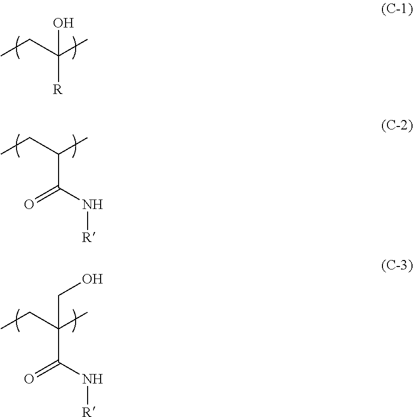

In Formulae, R represents an organic group. Examples of the organic group include an alkyl group, a cycloalkyl group, an aryl group, an aralkyl group, an alkenyl group, an ester group (—OCOR or —COOR: R represents a fluorinated alkyl group or an alkyl group having 1 to 20 carbon atoms), and the like, each of which may have a substituent.

R′ represents a hydrogen atom or an organic group. Examples of the organic group include an organic group such as an alkyl group, a cycloalkyl group, an aryl group, an aralkyl group, and an alkenyl group. In addition, a hydrogen atom in the organic group may be substituted with a fluorine atom or an iodine atom.

A specific example of an accomplishment unit of (d) may include a method of introducing the repeating unit represented by Formula (D) into the resin (A).

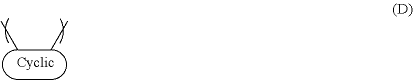

In Formula (D), “Cyclic” is a group which forms a main chain with a cyclic structure. The number of ring-constituting atoms is not particularly limited.

Specific examples of the repeating unit represented by Formula (D) include the following repeating units.

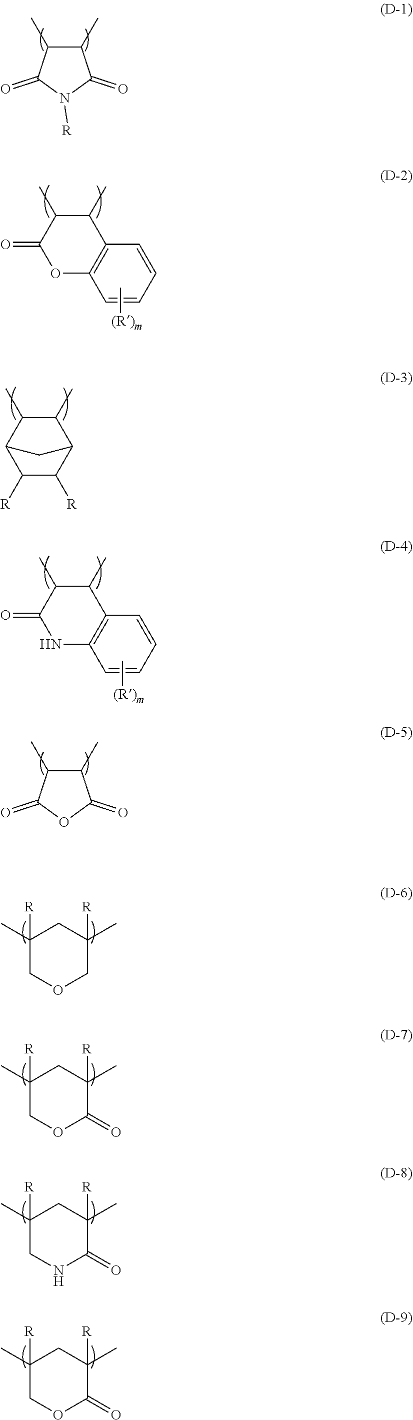

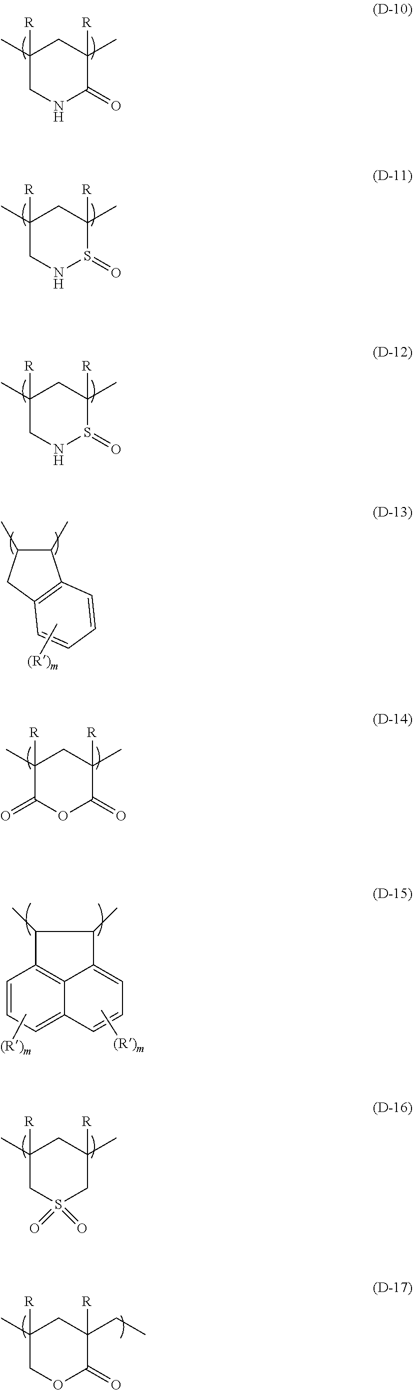

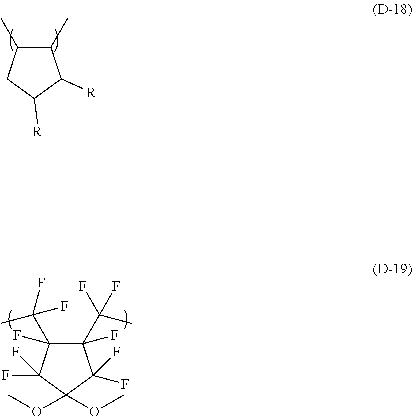

In Formulae, R′s each independently represent a hydrogen atom, an alkyl group, a cycloalkyl group, an aryl group, an aralkyl group, an alkenyl group, a hydroxyl group, an alkoxy group, an acyloxy group, a cyano group, a nitro group, an amino group, a halogen atom, an ester group (—OCOR″ or —COOR″: R″ represents a fluorinated alkyl group or an alkyl group having 1 to 20 carbon atoms), or a carboxyl group. The alkyl group, the cycloalkyl group, the aryl group, the aralkyl group, and the alkenyl group each may have a substituent. In addition, the hydrogen atom bonded to a carbon atom in the group represented by R may be substituted with a fluorine atom or an iodine atom.

In Formulae, R″s each independently represent an alkyl group, a cycloalkyl group, an aryl group, an aralkyl group, an alkenyl group, a hydroxyl group, an alkoxy group, an acyloxy group, a cyano group, a nitro group, an amino group, a halogen atom, an ester group (—OCOR″ or —COOR″: R″ represents a fluorinated alkyl group or an alkyl group having 1 to 20 carbon atoms), or a carboxyl group. The alkyl group, the cycloalkyl group, the aryl group, the aralkyl group, and the alkenyl group may each have a substituent. In addition, the hydrogen atom bonded to a carbon atom in the group represented by R′ may be substituted with a fluorine atom or an iodine atom.

m represents an integer of 0 or more. The upper limit of m is not particularly limited, but is preferably 2 or less in many cases, and 1 or less in more cases.

A specific example of an accomplishment unit of (e) may include a method of introducing the repeating unit represented by Formula (E) into the resin (A).

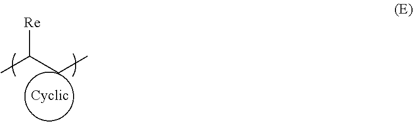

In Formula (E), Re′s each independently represent a hydrogen atom or an organic group. Examples of the organic group include an alkyl group, a cycloalkyl group, an aryl group, an aralkyl group, an alkenyl group, and the like, which may have a substituent.

“Cyclic” is a cyclic group including a carbon atom of the main chain. The number of atoms included in the cyclic group is not particularly limited.

Specific examples of the repeating unit represented by Formula (E) include the following repeating units.

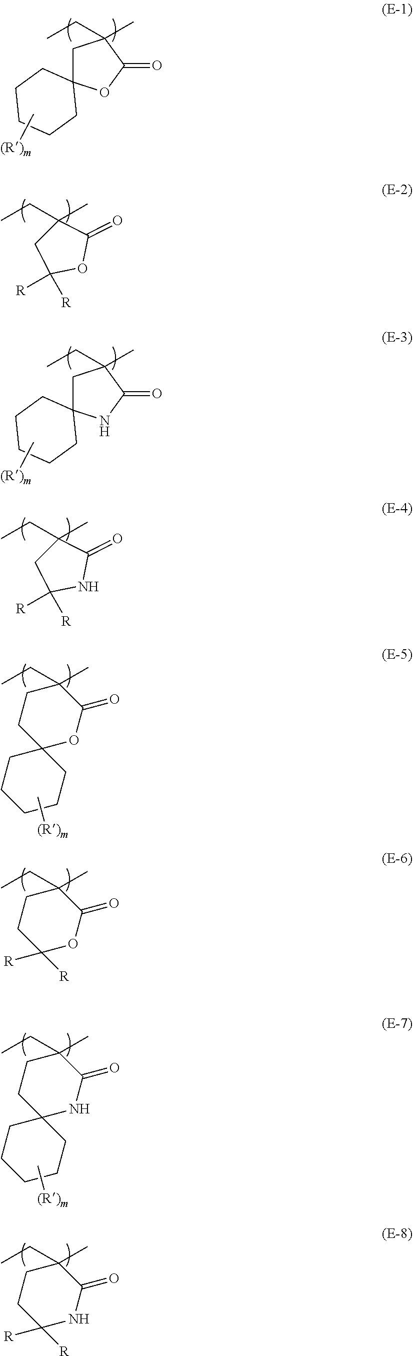

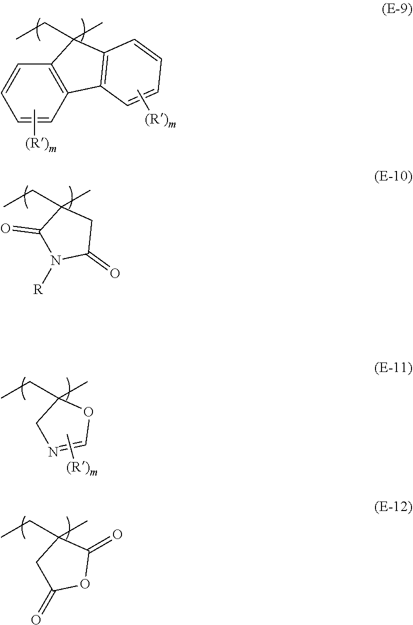

In Formulae, R′s each independently represent a hydrogen atom, an alkyl group, a cycloalkyl group, an aryl group, an aralkyl group, an alkenyl group, a hydroxyl group, an alkoxy group, an acyloxy group, a cyano group, a nitro group, an amino group, a halogen atom, an ester group (—OCOR″ or —COOR″: R″ represents a fluorinated alkyl group or an alkyl group having 1 to 20 carbon atoms), or a carboxyl group. The alkyl group, the cycloalkyl group, the aryl group, the aralkyl group, and the alkenyl group each may have a substituent. In addition, the hydrogen atom bonded to a carbon atom in the group represented by R may be substituted with a fluorine atom or an iodine atom.

In Formulae, R″s each independently represent a hydrogen atom, an alkyl group, a cycloalkyl group, an aryl group, an aralkyl group, an alkenyl group, a hydroxyl group, an alkoxy group, an acyloxy group, a cyano group, a nitro group, an amino group, a halogen atom, an ester group (—OCOR″ or —COOR″: R″ represents a fluorinated alkyl group or an alkyl group having 1 to 20 carbon atoms), or a carboxyl group. The alkyl group, the cycloalkyl group, the aryl group, the aralkyl group, and the alkenyl group each may have a substituent. In addition, the hydrogen atom bonded to a carbon atom in the group represented by R′ may be substituted with a fluorine atom or an iodine atom.
m represents an integer of 0 or more. The upper limit of m is not particularly limited, but is preferably 2 or less in many cases, and 1 or less in more cases.

Furthermore, in Formula (E-2), Formula (E-4), Formula (E-6), and Formula (E-8), two R′s may be bonded to each other to form a ring.

The resin (A) can be synthesized by a conventional method (for example, radical polymerization).

The weight-average molecular weight of the resin (A) as a value in terms of polystyrene by a GPC method is preferably 1,000 to 200,000, more preferably 3,000 to 20,000, and even more preferably 5,000 to 15,000. By setting the weight-average molecular weight of the resin (A) to 1,000 to 200,000, it is possible to prevent the deterioration of heat resistance and dry etching resistance, and further prevent the deterioration of film forming properties due to deteriorated developability or increased viscosity.

The dispersity (molecular weight distribution) of the resin (A) is typically 1 to 5, preferably 1 to 3, more preferably 1.2 to 3.0, and even more preferably 1.2 to 2.0. As the dispersity is smaller, the resolution and the resist shape are excellent, the side wall of the resist pattern is smooth, and the roughness is excellent.

A content of the resin (A) in the photosensitive composition is not particularly limited, but is preferably 50% to 99.9% by mass, more preferably 60% to 99.0% by mass with respect to the total solid content.

The resin (A) may be used singly or in combination of two or more kinds thereof. In a case where two or more kinds of resins (A) are used in combination, the total amount thereof is preferably within the above range.

<(B) Photoacid Generator>

The photosensitive composition may include a photoacid generator. The photoacid generator is a compound which generates an acid in a case of being exposed to light.

The photoacid generator may be in a form of a low molecular compound or in a form introduced into a part of a polymer. Furthermore, the form of a low molecular compound and the form introduced into a part of a polymer may also be used in combination.

In a case where the photoacid generator is in the form of a low molecular compound, the molecular weight thereof is preferably 3000 or less, more preferably 2000 or less, and even more preferably 1000 or less.

In a case where the photoacid generator is in the form of introduced in a part of a polymer, the photoacid generator may be introduced in a part of the resin (A) or introduced in a resin other than the resin (A).

In the present invention, the photoacid generator is preferably in the form of a low molecular compound.

The photoacid generator is not particularly limited as long as the photoacid generator is a known photoacid generator, but it is preferable to a compound which generates an organic acid upon exposure, and more preferable to a photoacid generator having a fluorine atom or an iodine atom in the molecule.

Examples of the organic acid include sulfonic acid (such as aliphatic sulfonic acid, aromatic sulfonic acid, and camphorsulfonic acid), carboxylic acid (such as aliphatic carboxylic acid, aromatic carboxylic acid, and aralkyl carboxylic acid), and carbonylsulfonylimidic acid, bis(alkyisulfonyl)imidic acid, tris(alkylsulfonyl)methide acid, and the like.

The volume of the acid generated from the photoacid generator is not particularly limited, but is preferably 240 Å³ or more, and more preferably 270 Å³ or more, even more preferably, 305 Å³ or more, particularly preferably 350 Å³ or more, and most preferably 400 Å³ or more, from the viewpoint of suppressing diffusion of the acid generated by exposure toward unexposed portions and improving the resolution. From the viewpoint of sensitivity or solubility in a coating solvent, the volume of the acid generated from the photoacid generator is preferably 1500 Å³ or less, more preferably 1000 Å³ or less, and even more preferably 700 Å³ or less.

The value of the volume is determined using “WinMOPAC” manufactured by Fujitsu Ltd. With reference to the calculation of the value of the volume, first, the chemical structure of the acid according to each example is input, and next, using this structure as the initial structure, the most stable conformation of each acid is determined by molecular force field calculation using a molecular mechanics (MM) 3 method. Then, with respect to the most stable conformation, molecular orbital calculation is performed using a parameterized model number (PM) 3 method, whereby the “accessible volume” of each acid can be calculated.

The structure of the acid generated from the photoacid generator is not particularly limited, but it is preferable that the interaction between the acid generated from the photoacid generator and the resin (A) is strong, from the viewpoint of suppressing the diffusion of the acid and improving the resolution. For this reason, in a case where the acid generated from the photoacid generator is an organic acid, it is preferable to have, for example, an acid which further generates a polar group, in addition to an organic acid group such as a sulfonic acid group, a carboxylic acid group, a carbonylsulfonylimidic acid group, a bissulfonylimidic acid group, and a trissulfonylmethide acid group.

Examples of the polar group include an ether group, an ester group, an amide group, an acyl group, a sulfo group, a sulfonyloxy group, a sulfonamide group, a thioether group, a thioester group, a urea group, a carbonate group, a carbamate group, a hydroxyl group, and a mercapto group.

The number of polar groups included in the generated acid is not particularly limited, and is preferably 1 or more, more preferably 2 or more. From the viewpoint of suppressing excessive development, the number of polar groups is preferably less than 6, and more preferably less than 4.

As the photoacid generator, the following photoacid generators which generate acids are preferable. In some of the examples, the calculated value of the volume is added (unit Å³).

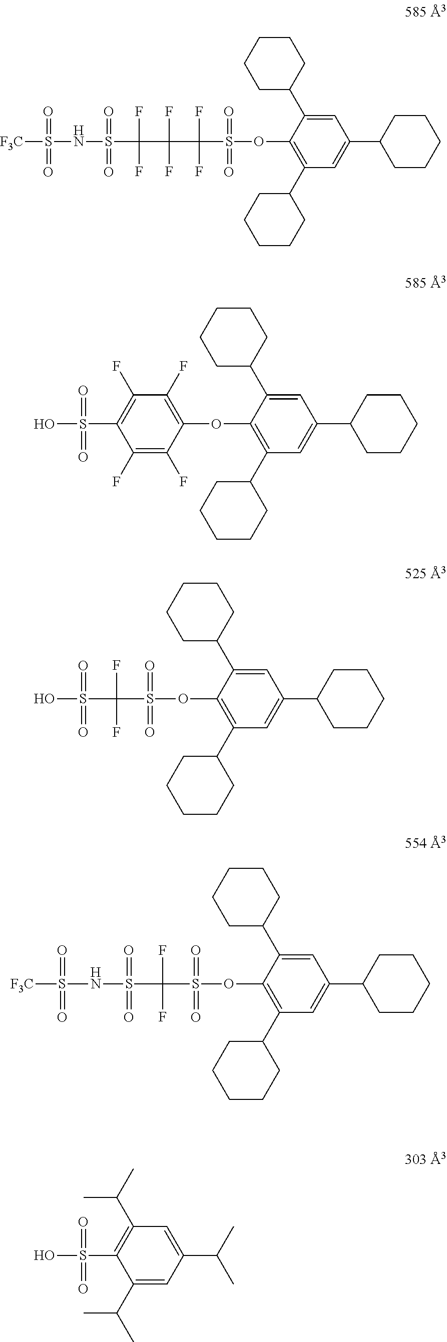

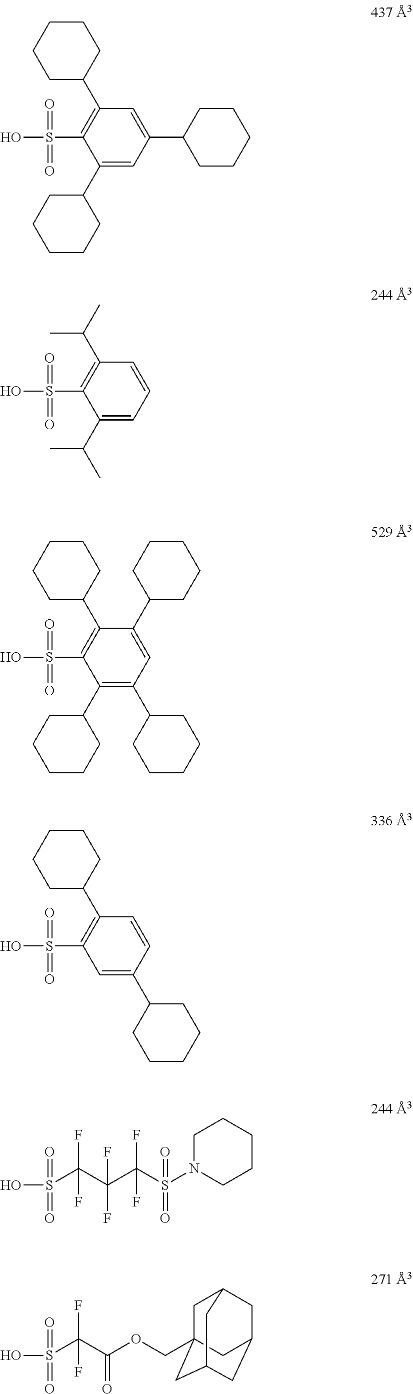 [SMILES: O=S(=O)(O)c1c(C2CCCCC2)cc(C2CCCCC2)cc1C1CCCCC1 ; CC(C)c1cccc(C(C)C)c1S(=O)(=O)O ; O=S(=O)(O)c1c(C2CCCCC2)c(C2CCCCC2)cc(C2CCCCC2)c1C1CCCCC1 ; O=S(=O)(O)c1cc(C2CCCCC2)ccc1C1CCCCC1 ; O=S(=O)(O)C(F)(F)C(F)(F)C(F)(F)S(=O)(=O)N1CCCCC1 ; O=C(OCC12CC3CC(CC(C3)C1)C2)C(F)(F)S(=O)(=O)O]

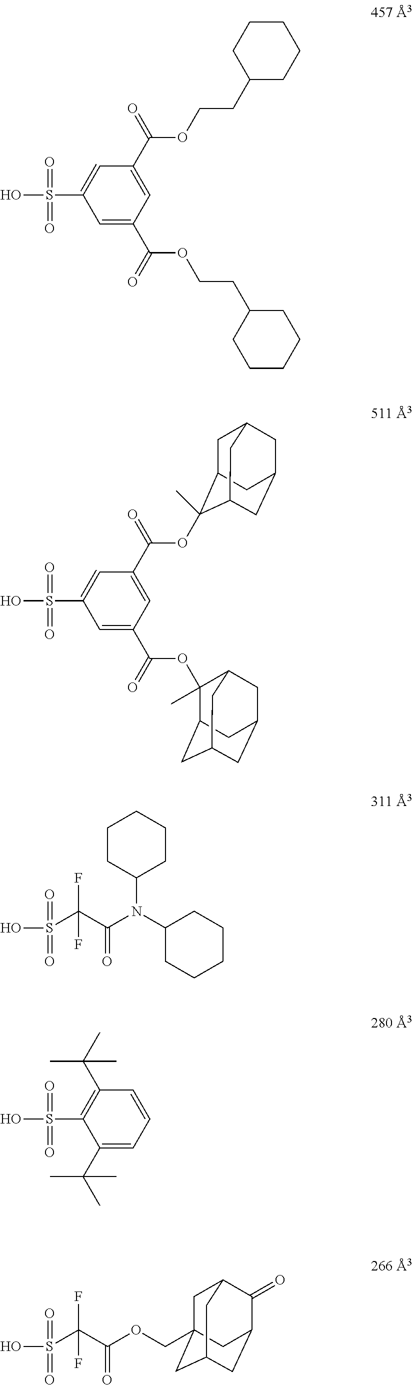 [SMILES: O=C(OCCC1CCCCC1)c1cc(C(=O)OCCC2CCCCC2)cc(S(=O)(=O)O)c1 ; CC1(OC(=O)c2cc(C(=O)OC3(C)C4CC5CC(C4)CC3C5)cc(S(=O)(=O)O)c2)C2CC3CC(C2)CC1C3 ; O=C(N(C1CCCCC1)C1CCCCC1)C(F)(F)S(=O)(=O)O ; CC(C)(C)c1cccc(C(C)(C)C)c1S(=O)(=O)O ; O=C1C2CC3CC1CC(COC(=O)C(F)(F)S(=O)(=O)O)(C3)C2]

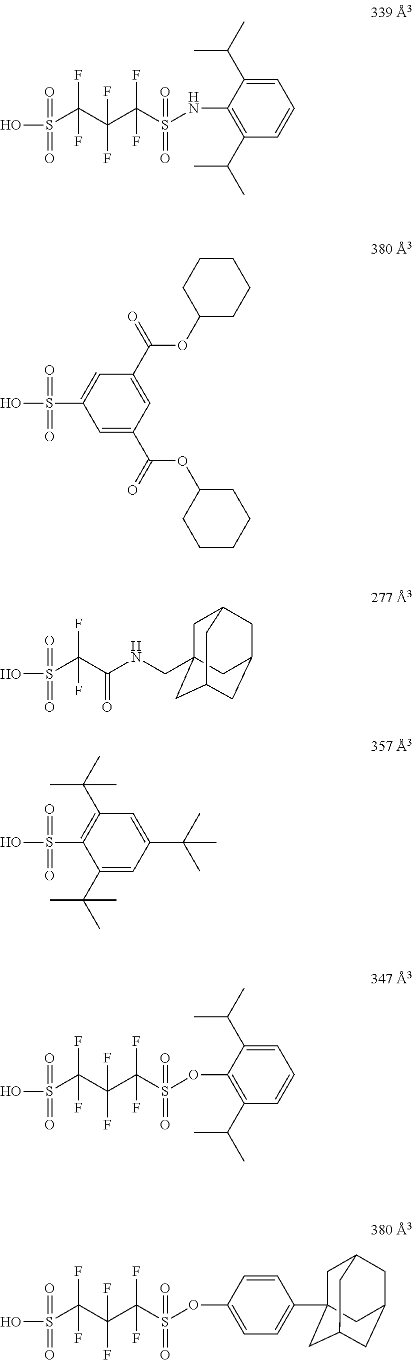 [SMILES: CC(C)c1cccc(C(C)C)c1NS(=O)(=O)C(F)(F)C(F)(F)C(F)(F)S(=O)(=O)O ; O=C(OC1CCCCC1)c1cc(C(=O)OC2CCCCC2)cc(S(=O)(=O)O)c1 ; O=C(NCC12CC3CC(CC(C3)C1)C2)C(F)(F)S(=O)(=O)O ; CC(C)(C)c1cc(C(C)(C)C)c(S(=O)(=O)O)c(C(C)(C)C)c1 ; CC(C)c1cccc(C(C)C)c1OS(=O)(=O)C(F)(F)C(F)(F)C(F)(F)S(=O)(=O)O ; O=S(=O)(O)C(F)(F)C(F)(F)C(F)(F)S(=O)(=O)Oc1ccc(C23CC4CC(CC(C4)C2)C3)cc1]

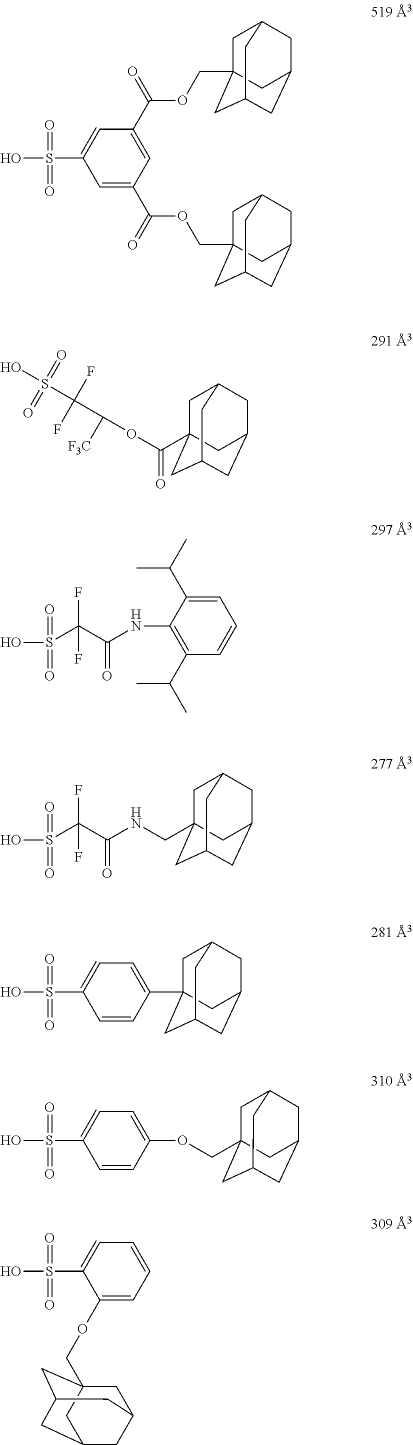

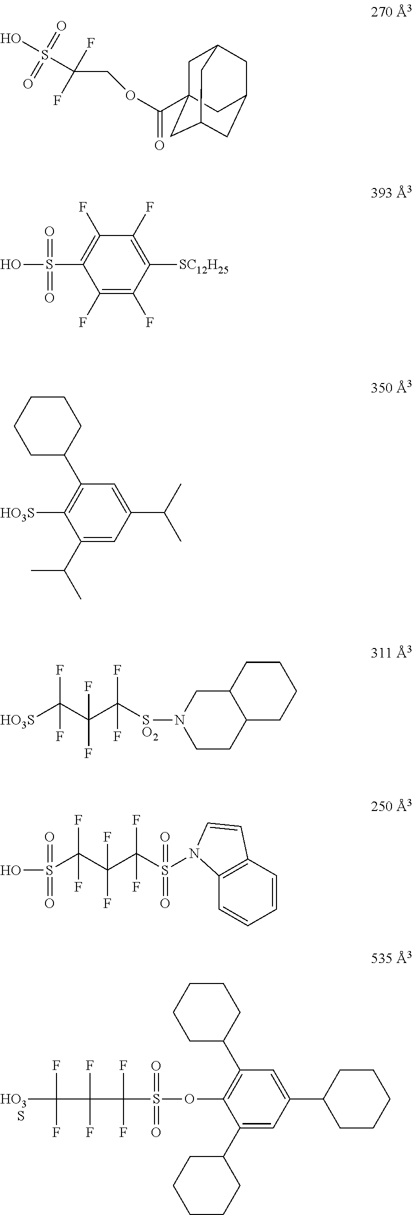

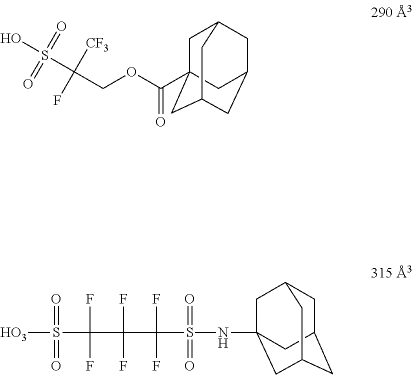

Particularly, the photoacid generator is preferably a photoacid generator consisting of a cationic moiety and an anionic moiety, from the viewpoint that the effect of the present invention is more excellent.

More specifically, the photoacid generator is preferably a compound represented by General Formula (ZI) or General Formula (ZII).

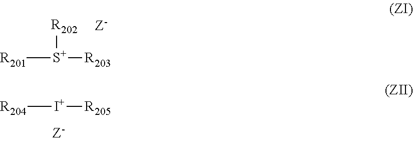

In General Formula (ZI),
R₂₀₁, R₂₀₂, and R₂₀₃ each independently represent an organic group.
The number of carbon atoms in the organic group as R₂₀₁, R₂₀₂, and R₂₀₃ each is preferably 1 to 30, and more preferably 1 to 20.
In addition, two of R₂₀₁ to R₂₀₃ may combine with each other to form a ring structure, and the formed ring may include an oxygen atom, a sulfur atom, an ester linkage, an amide linkage, or a carbonyl group. Examples of a group formed by combining any two of R₂₀₁ to R₂₀₃ include alkylene groups (such as a butylene group or a pentylene group).
Z⁻ represents a non-nucleophilic anion (anion whose capability of inducing a nucleophilic reaction is markedly low).

Examples of a non-nucleophilic anion include a sulfonate anion (such as an aliphatic sulfonate anion, an aromatic sulfonate anion, and a camphorsulfonate anion), a carboxylate anion (such as an aliphatic carboxylate anion, an aromatic carboxylate anion, and an aralkyl carboxylate anion), a sulfonylimide anion, a bis(alkylsulfonyl)imide anion, a tris(alkylsulfonyl)methyl anion, and the like.

The aliphatic moiety in the aliphatic sulfonate anion and the aliphatic carboxylate anion may be an alkyl group or a cycloalkyl group, and is preferably a linear or branched alkyl group having 1 to 30 carbon atoms or a cycloalkyl group having 3 to 30 carbon atoms.

The aromatic ring group in the aromatic sulfonate anion and the aromatic carboxylate anion is preferably an aryl group having 6 to 14 carbon atoms, and examples thereof include a phenyl group, a tolyl group, and a naphthyl group.

Specific examples of the substituent which the alkyl group, the cycloalkyl group, and the aryl group may have include a nitro group, a halogen atom such as a fluorine atom, a carboxyl group, a hydroxyl group, an amino group, a cyano group, an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms), an alkylthio group (preferably having 1 to 15 carbon atoms), an alkylsulfonyl group (preferably having 1 to 15 carbon atoms), an alkyliminosulfonyl group (preferably having 1 to 15 carbon atoms), an aryloxysulfonyl group (preferably having 6 to 20 carbon atoms), an alkylaryloxysulfonyl group (preferably having 7 to 20 carbon atoms), a cycloalkylaryloxysulfonyl group (preferably having 10 to 20 carbon atoms), an alkyloxyalkyloxy group (preferably having 5 to 20 carbon atoms), a cycloalkylalkyloxyalkyloxy group (preferably having 8 to 20 carbon atoms) and the like.

The aralkyl group in the aralkyl carboxylate anion is preferably an aralkyl group having 7 to 12 carbon atoms, and examples thereof include a benzyl group, a phenethyl group, a naphthylmethyl group, a naphthylethyl group, a naphthylbutyl group, and the like.

Examples of the sulfonylimide anion include a saccharin anion.

The alkyl group in the bis(alkylsulfonyl)imide anion and the tris(alkylsulfonyl)methide anion is preferably an alkyl group having 1 to 5 carbon atoms. Examples of the substituent which alkyl groups may have include halogen atoms, an alkyl group substituted with a halogen atom, an alkoxy group, an alkylthio group, an alkyloxysulfonyl group, an aryloxysulfonyl group, a cycloalkylaryloxysulfonyl group, and the like, and a fluorine atom and an alkyl group substituted with a fluorine atom are preferable.

In addition, the alkyl groups in the bis(alkylsulfonyl)imide anion may be bonded to each other to form a ring structure. As a result, acid strength increases.

Examples of other non-nucleophilic anions include phosphorus fluoride (for example, PF₆), boron fluoride (for example, BF₄⁻), and antimony fluoride (for example, SbF₆⁻).

The non-nucleophilic anion is preferably an aliphatic sulfonate anion substituted at the at least α-position of sulfonic acid with a fluorine atom, an aromatic sulfonate anion substituted with a fluorine atom, or a group having a fluorine atom, a bis(alkylsulfonyl)imide anion in which an alkyl group is substituted with a fluorine atom, or a tris(alkylsulfonyl)methide anion in which an alkyl group is substituted with a fluorine atom. Among these, a perfluorinated aliphatic sulfonate anion (preferably having 4 to 8 carbon atoms), or a benzenesulfonate anion having a fluorine atom is more preferable, and a nonafluorobutane sulfonate anion, a perfluorooctane sulfonate anion, a pentafluorobenzene sulfonate anion, or a 3,5-bis(trifluoromethyl)benzene sulfonate anion is even more preferable.

From the viewpoint of acid strength, it is preferable that the pKa of generated acid is −1 or less so as to ensure a sensitivity enhancement.

In addition, an anion represented by General Formula (AN1) is also preferable as the non-nucleophilic anion.

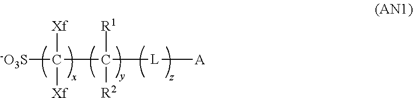

In Formulae,
Xf's each independently represent a fluorine atom, or an alkyl group substituted with at least one fluorine atom,
R¹ and R² each independently represent a hydrogen atom, a fluorine atom, or an alkyl group, and in a case where a plurality of R¹'s or R²'s are present, R¹'s and R²'s may be the same as or different from each other.
L represents a divalent linking group, and in a case where a plurality of L's are present, the plurality of L's may be the same as or different from each other,
A represents a cyclic organic group.
x represents an integer of 1 to 20, y represents an integer of 0 to 10, and z represents an integer of 0 to 10.

General Formula (AN1) will be described in more detail.

The alkyl group in the alkyl group substituted with a fluorine atom for Xf preferably has 1 to 10 carbon atoms, and more preferably has 1 to 4 carbon atoms. Furthermore, the alkyl group substituted with a fluorine atom for Xf is preferably a perfluoroalkyl group.
Xf is preferably a fluorine atom or a perfluoroalkyl group having 1 to 4 carbon atoms. Specific examples of Xf include a fluorine atom, CF₃, C₂F₅, C₃F₇, C₄F₉, CH₂CF₃, CH₂CH₂CF₃, CH₂C₂F₅, CH₂CH₂C₂F₅, CH₂C₃F₇, CH₂CH₂C₃F₇, CH₂C₄F₉, and CH₂CH₂C₄F₉. Among these, a fluorine atom and CF₃ are preferable. Particularly, both Xf's are preferably fluorine atoms.

The alkyl group for R¹ or R² may have a substituent (preferably a fluorine atom) and preferably has 1 to 4 carbon atoms. As the substituent, a perfluoroalkyl group having 1 to 4 carbon atoms is preferable. Specific examples of the alkyl group having a substituent for R¹ and R² include CF₃, C₂F₅, C₃F₇, C₄F₉, C₅Fᵢᵢ, C₆F₁₃, C₇F₁₅, CₛF₁₇, CH₂CF₃, CH₂CH₂CF₃, CH₂C₂F₅, CH₂CH₂C₂F₅, CH₂C₃F₇, CH₂CH₂C₃F₇, CH₂C₄F₉, and CH₂CH₂C₄F₉, and the like, and among these, CF₃ is preferable.
R¹ or R² is preferably a fluorine atom or CF3.
x is preferably an integer of 1 to 10, more preferably 1 to 5.
y is preferably an integer of 0 to 4, and more preferably 0.
z is preferably an integer of 0 to 5, more preferably an integer of 0 to 3.

The divalent linking group for L is not particularly limited, and examples thereof include —COO—, —CO—, —O—, —S—, —SO—, —SO₂—, an alkylene group, a cycloalkylene group, an alkenylene group, and a linking group formed by connecting plural groups thereof, with the linking group having 12 or less carbon atoms in the total number of carbon atoms being preferable. Among these, —COO—, —OCO—, —CO—, or —O— is preferable, and —COO— or —OCO— is more preferable.

The cyclic organic group of A is not particularly limited as long as the cyclic organic group has a cyclic structure, and examples thereof include an alicyclic group, an aromatic ring group, and a heterocyclic group (including not only those having aromaticity but also those having no aromaticity).

The alicyclic group may be monocyclic or polycyclic, and is preferably a monocyclic cycloalkyl group such as a cyclopentyl group, a cyclohexyl group, and a cyclooctyl group, or a polycyclic cycloalkyl group such as a norbornyl group, a tricyclodecanyl group, a tetracyclodecanyl group, a tetracyclododecanyl group, and an adamantyl group. Among these, an alicyclic group having a bulky structure containing 7 or more carbon atoms, such as a norbornyl group, a tricyclodecanyl group, a tetracyclodecanyl group, a tetracyclododecanyl group, and an adamantyl group, is preferable, from the viewpoint that diffusion into a film during a post-exposure heating step can be suppressed and a mask error enhancement factor (MEEF) is improved.

Examples of the aromatic ring group include groups derived from a benzene ring, a naphthalene ring, a phenanthrene ring, an anthracene ring, and the like.

Examples of the heterocyclic group include groups derived from a furan ring, a thiophene ring, a benzofuran ring, a benzothiophene ring, a dibenzofuran ring, a dibenzothiophene ring, a pyridine ring, and the like. Among these, a group derived from a furan ring, a thiophene ring, or a pyridine ring is preferable.

In addition, the cyclic organic group includes a lactone structure, and specific examples thereof include the lactone structures represented by General Formulae (LC1-1) to (LC1-17) described above.

The cyclic organic group may have a substituent. Examples of the substituent include an alkyl group (may be any of linear or branched, and preferably having 1 to 12 carbon atoms), and a cycloalkyl group (may be monocyclic, polycyclic or spirocyclic in a case of polycyclic, and preferably having 3 to 20 carbon atoms), an aryl group (preferably having 6 to 14 carbon atoms), a hydroxyl group, an alkoxy group, an ester group, an amide group, a urethane group, a ureide group, a thioether group, a sulfonamide group, a sulfonic acid ester group, and the like. The carbon constituting the cyclic organic group (the carbon contributing to ring formation) may be carbonyl carbon.

Examples of the organic groups for R₂₀₁, R₂₀₂, and R₂₀₃ include an aryl group, an alkyl group, a cycloalkyl group, and the like.

At least one of R₂₀₁, R₂₀₂, or R₂₀₃ is preferably an aryl group, and more preferably those three are aryl groups. The aryl groups include not only a phenyl group, a naphthyl group, and the like but also heteroaryl groups, such as an indole residue and a pyrrole residue.

The alkyl group for R₂₀₁ to R₂₀₃ is preferably a linear or branched alkyl group having 1 to 10 carbon atoms, and more preferably a methyl group, an ethyl group, an n-propyl group, an i-propyl group, or an n-butyl group.

The cycloalkyl group for R₂₀₁ to R₂₀₃ is preferably a cycloalkyl group having 3 to 10 carbon atoms, and more preferably a cyclopropyl group, a cyclobutyl group, a cyclopentyl group, a cyclohexyl group, or a cycloheptyl group.

Examples of the substituents which those groups may have include a nitro group, a halogen atom such as a fluorine atom, a carboxyl group, a hydroxyl group, an amino group, a cyano group, an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms), and the like.

In General Formula (ZII),
R₂₀₄ and R₂₀₅ each independently represent an aryl group, an alkyl group, or a cycloalkyl group.

The aryl group, alkyl group and cycloalkyl group for R₂₀₄ and R₂₀₅ are the same as the groups described as the aryl group, alkyl group, and cycloalkyl group for R₂₀₁ to R₂₀₃ in General Formula (ZI).

Examples of the substituent which the aryl group, alkyl group and cycloalkyl group for R₂₀₄ and R₂₀₅ may have include the substituents which the aryl group, alkyl group and cycloalkyl group for R₂₀₁ to R₂₀₃ in the aforementioned compound (ZI) may have.

Z⁻ represents a non-nucleophilic anion, and examples thereof include the same the non-nucleophilic anions as those of Z⁻ in General Formula (ZI).

Examples of the photoacid generator include photoacid generators described in paragraphs [0368] to [0377] of JP2014-041328A, and paragraphs [0240] to [0262] of JP2013-228681A ([0339] of the corresponding US2015/004533A), the contents of which are incorporated in the present specification. In addition, specific preferred examples of the photoacid generator include, but not limited to, the following compounds.

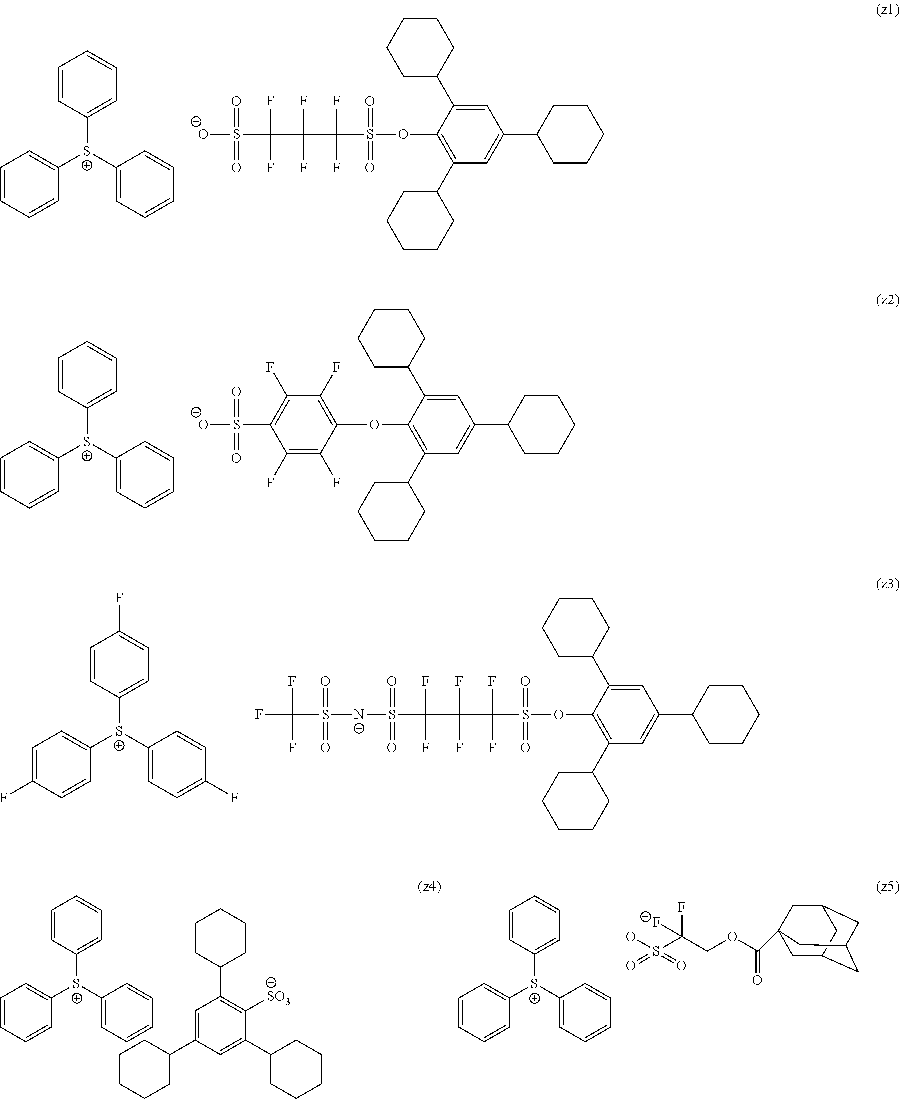

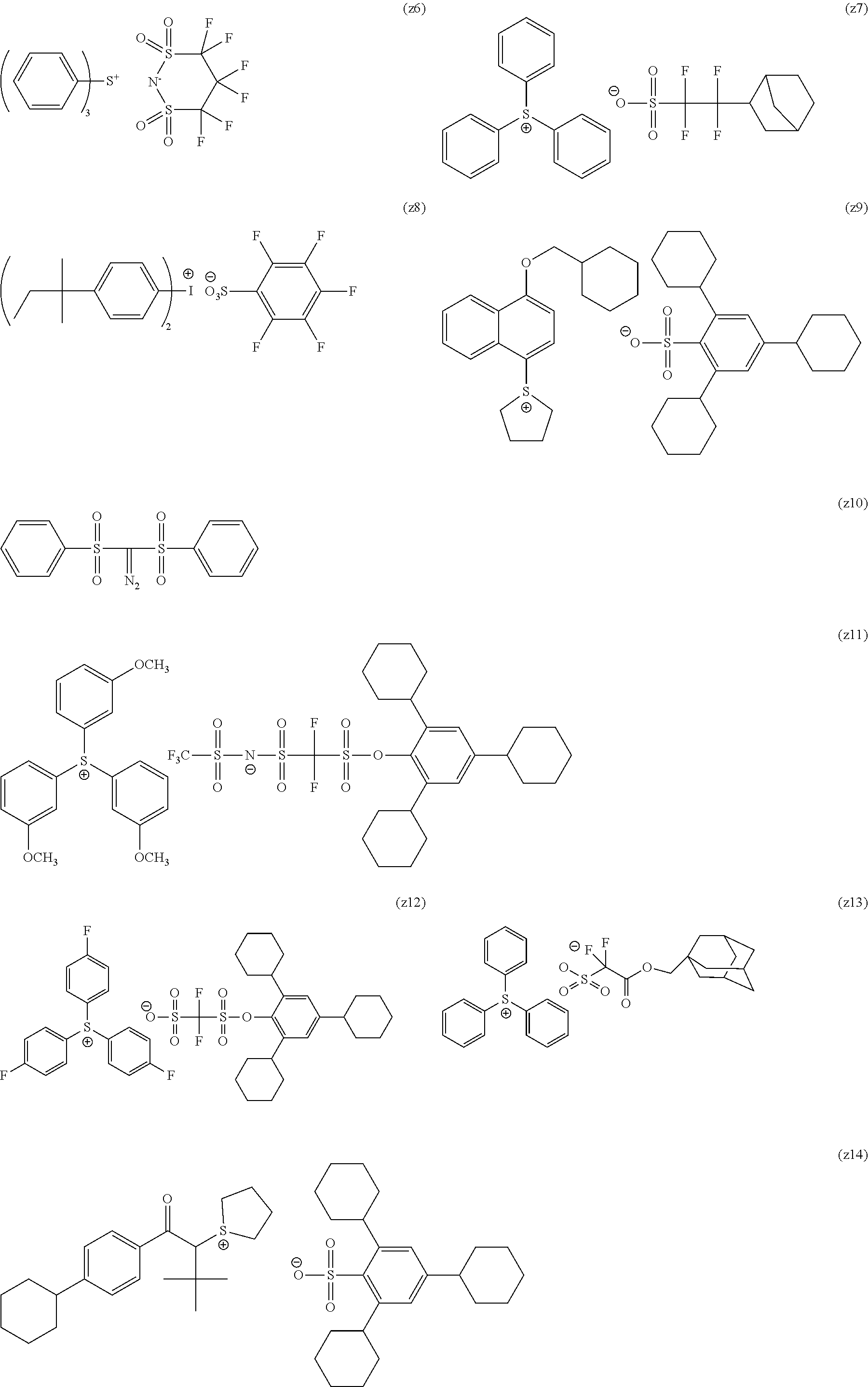

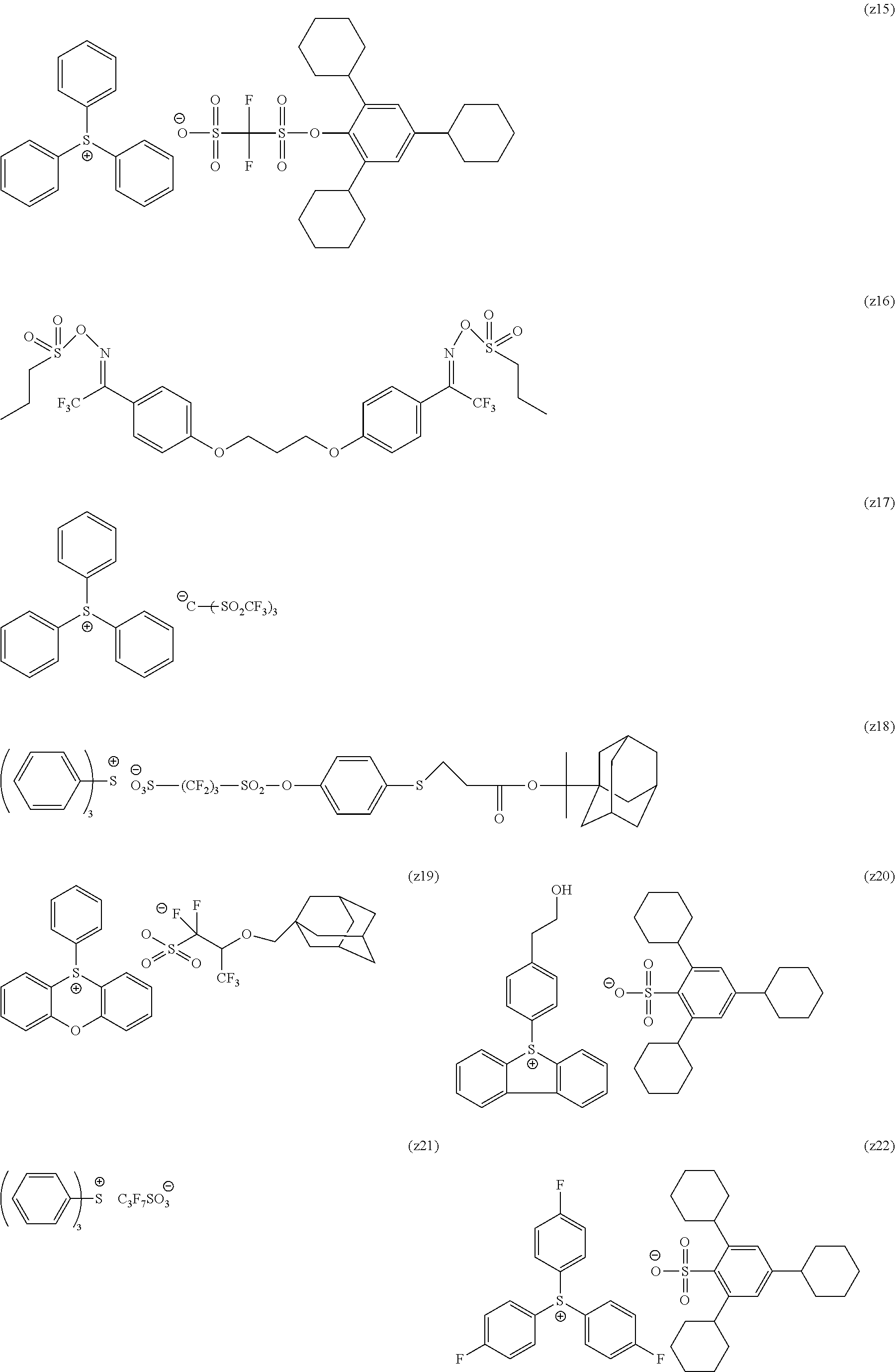

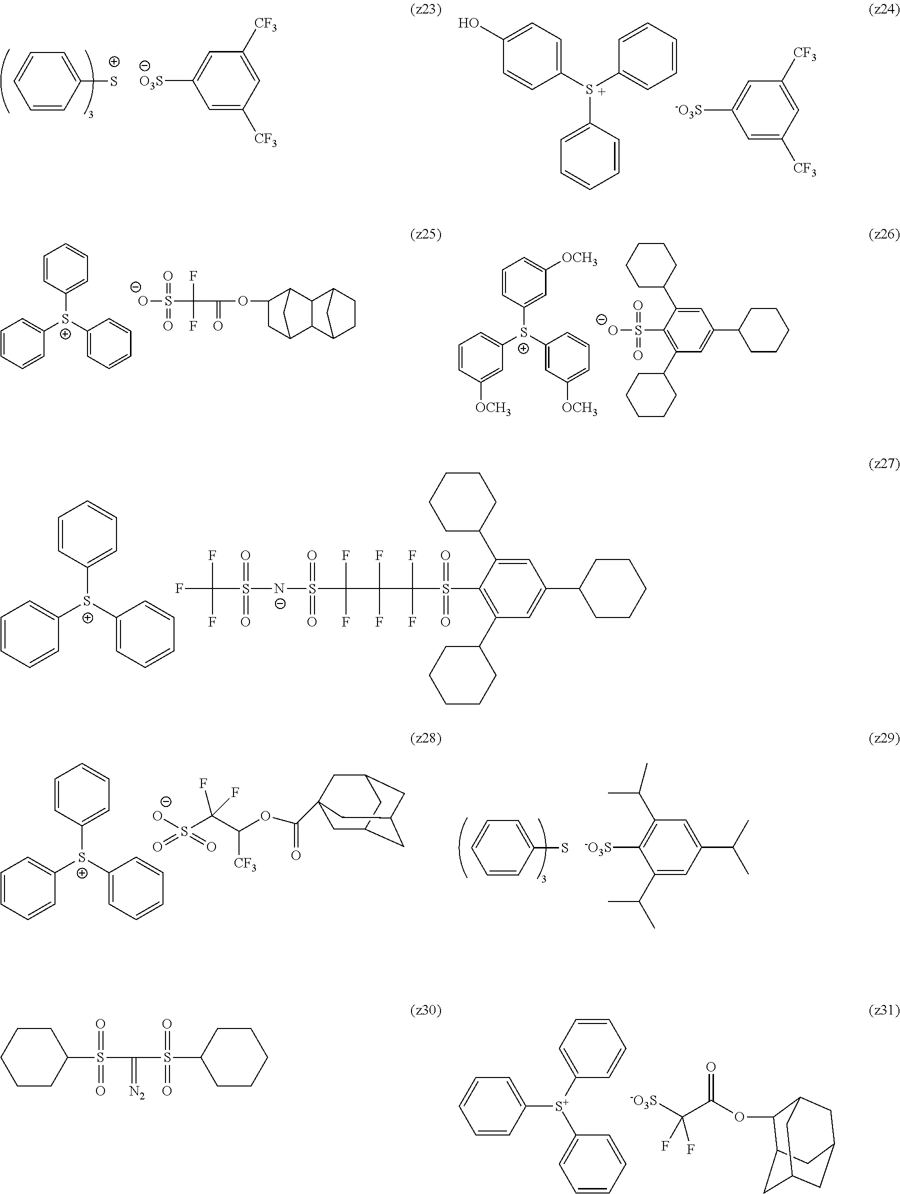

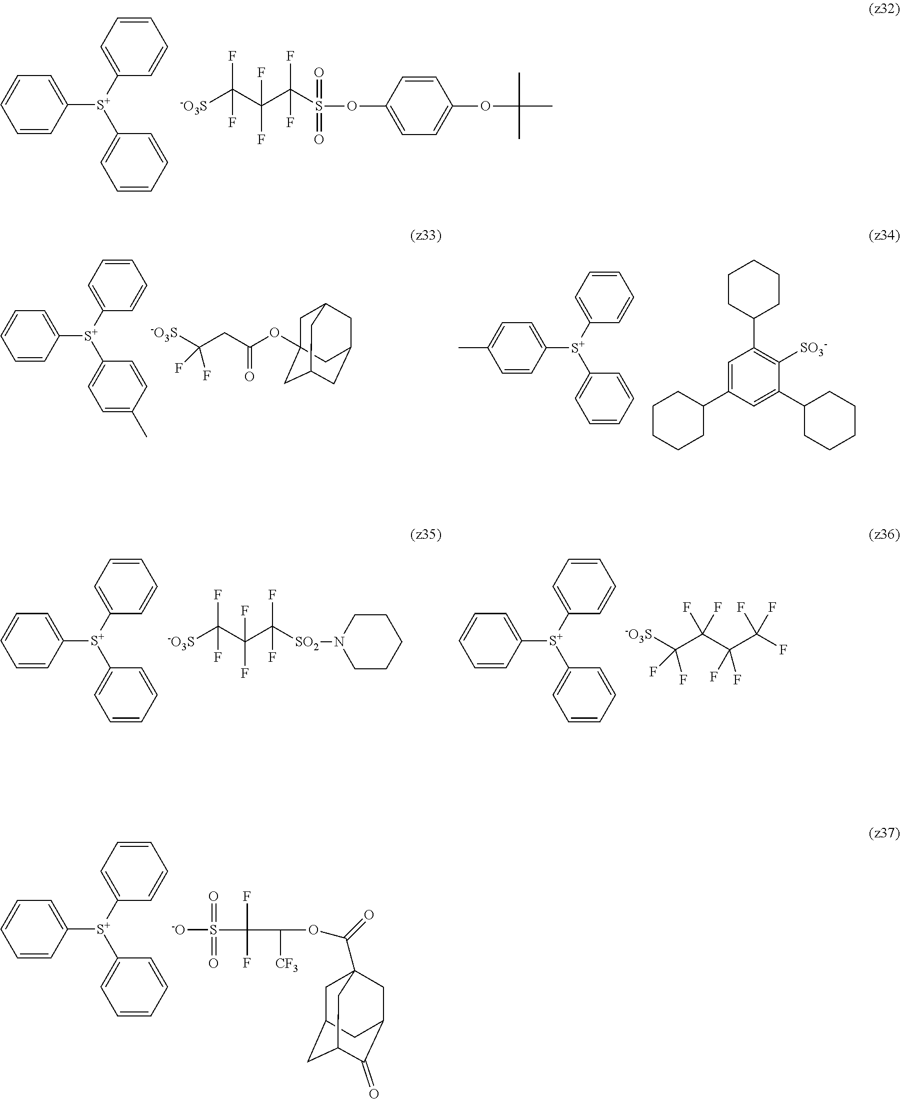

The content of the photoacid generator in the photosensitive composition is not particularly limited, but from the viewpoint that the effect of the present invention is more excellent, is preferably 5% to 50% by mass, more preferably 10% to 40% by mass, even more preferably 10 to 35% by mass, and particularly preferably more than 10% by mass and less than 35% by mass, with respect to the total solid content of the composition.

The photoacid generator may be used singly or in combination of two or more kinds thereof. In a case where two or more kinds of the photoacid generator are used in combination, the total amount thereof is preferably within the above range.

<(C) Solvent>

The photosensitive composition may include a solvent.

The solvent preferably includes at least one of (M1) propylene glycol monoalkyl ether carboxylate or (M2) at least one selected from the group consisting of propylene glycol monoalkyl ether, ester lactate, acetate, alkoxy ester propionate, chained ketone, cyclic ketone, lactone, and alkylene carbonate. The solvent may further include components other than the components (M1) and (M2).

The present inventors have found that the use of such the solvent and the above described resin in combination improves coatability of the composition, and also makes it possible to form a resist pattern having less development defects. The reason therefor is not necessarily clear, but the present inventors consider that the solvent has a good balance with the solubility, the boiling point, and the viscosity of the above described resin, thus contributing to suppress the non-uniform film thickness of a composition film, generation of a precipitate during spin coating, or the like.

As the component (M1), at least one selected from the group consisting of propylene glycol monomethyl ether acetate (PGMEA), propylene glycol monomethyl ether propionate, and propylene glycol monoethyl ether acetate is preferable, and propylene glycol monomethyl ether acetate is more preferable.

As the component (M2), the following is preferable.

As the propylene glycol monoalkyl ether, propylene glycol monomethyl ether (PGME) or propylene glycol monoethyl ether is preferable.

As the ester lactate, ethyl lactate, butyl lactate, or propyl lactate is preferable.

As the ester acetate, methyl acetate, ethyl acetate, butyl acetate, isobutyl acetate, propyl acetate, isoamyl acetate, methyl formate, ethyl formate, butyl formate, propyl formate, or 3-methoxybutyl acetate is preferable.

Butyl butyrate is also preferable.

As the alkoxy ester propionate, 3-methoxymethyl propionate (MMP) or ethyl 3-ethoxypropionate (EEP) is preferable.

As the chained ketone, 1-octanone, 2-octanone, 1-nonanone, 2-nonanone, acetone, 2-heptanone, 4-heptanone, 1-hexanone, 2-hexanone, diisobutyl ketone, phenylacetone, methyl ethyl ketone, methyl isobutyl ketone, acetyl acetone, acetonyl acetone, ionone, diacetonyl alcohol, acetyl carbinol, acetophenone, methyl naphthyl ketone, or methyl amyl ketone is preferable.

As the cyclic ketone, methylcyclohexanone, isophorone, or cyclohexanone is preferable.

As the lactone, γ-butyrolactone is preferable.

As the alkylene carbonate, propylene carbonate is preferable.

As the component (M2), propylene glycol monomethyl ether, ethyl lactate, ethyl 3-ethoxypropionate, methyl amyl ketone, cyclohexanone, butyl acetate, pentyl acetate, γ-butyrolactone, or propylene carbonate is more preferable.

In addition to the components, an ester-based solvent having 7 or more carbon atoms (preferably 7 to 14 carbon atoms, more preferably 7 to 12 carbon atoms, and even more preferably 7 to 10 carbon atoms), and 2 or less heteroatoms is preferably used.

Preferred examples of the ester-based solvent having 7 or more carbon atoms and 2 or less heteroatoms include amyl acetate, 2-methylbutyl acetate, 1-methylbutyl acetate, hexyl acetate, pentyl propionate, hexyl propionate, butyl propionate, isobutyl isobutyrate, heptyl propionate, butyl butanoate, and the like, with isoamyl acetate being preferable.

As the component (M2), a component having a flash point (hereinafter, also referred to as fp) of 37° C. or higher is preferably used. Such the component (M2) is preferably propylene glycol monomethyl ether (fp: 47° C.), ethyl lactate (fp: 53° C.), ethyl 3-ethoxypropionate (fp: 49° C.), methyl amyl ketone (fp: 42° C.), cyclohexanone (fp: 44° C.), pentyl acetate (fp: 45° C.), methyl 2-hydroxyisobutyrate (fp: 45° C.), γ-butyrolactone (fp: 101° C.), or propylene carbonate (fp: 132° C.). Among these, propylene glycol monoethyl ether, ethyl lactate, pentyl acetate, or cyclohexanone is more preferable, and propylene glycol monoethyl ether or ethyl lactate is even more preferable.

In addition, the “flash point” as used herein means a value described in the reagent catalog of Tokyo Chemical Industry Co., Ltd. or Sigma-Aldrich Co. LLC.

The solvent preferably includes the component (M1). It is more preferable that the solvent consists of substantially only the component (M1) or is a mixed solvent of the component (M1) and other components. In the latter case, the solvent even more preferably includes both the component (M1) and the component (M2).

The mass ratio (M1/M2) of the component (M1) to the component (M2) is preferably within the range of “100/0” to “15/85”, more preferably within the range of “100/0” to “40/60”, and even more preferably within the range of “100/0” to “60/40”. That is, it is preferable that the solvent consists of only the component (M1), or includes both the component (M1) and the component (M2) and the mass ratio thereof is as follows. That is, in the latter case, the mass ratio of the component (M1) to the component (M2) is preferably 15/85 or more, more preferably 40/60 or more, and even more preferably 60/40 or more. In a case where such a configuration is adopted and used, the number of development defects can be further reduced.

Furthermore, in a case where the solvent includes both the component (M1) and the component (M2), the mass ratio of the component (M1) to the component (M2) is, for example, set to 99/1 or less.

As described above, the solvent may further include components other than the components (M1) and (M2). In this case, the content of the component other than the components (M1) and (M2) is preferably within the range of 5% to 30% by mass with respect to the total amount of the solvent.

The content of the solvent in the photosensitive composition is preferably adjusted such that the concentration of solid contents is 0.5% to 30% by mass, and more preferably adjusted such that the concentration of the solid contents is 1% to 20% by mass, from the viewpoint of further improving the coatability of the photosensitive composition.

<(D) Acid Diffusion Control Agent>

The photosensitive composition may further include an acid diffusion control agent. The acid diffusion control agent acts as a quencher that traps an acid generated from a photoacid generator, and functions to control diffusion development of the acid in the resist film.

The acid diffusion control agent may be, for example, a basic compound.

The basic compound is preferably a compound having structures represented by General Formula (A) to General Formula (E).

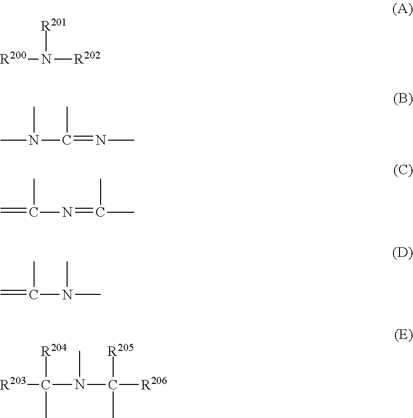

In General Formulae (A) and (E), R²⁰³, R²⁰¹, and R²⁰² may be the same as or different from each other, and each represent a hydrogen atom, an alkyl group (preferably having 1 to 20 carbon atoms), a cycloalkyl group (preferably having 3 to 20 carbon atoms), or an aryl group (preferably having 6 to 20 carbon atoms), in which R²⁰¹ and R²⁰² may be bonded to each other to form a ring.

With respect to the alkyl group, the alkyl group having a substituent is preferably an aminoalkyl group having 1 to 20 carbon atoms, a hydroxyalkyl group having 1 to 20 carbon atoms, or a cyanoalkyl group having 1 to 20 carbon atoms.

R²⁰³, R²⁰⁴, R²⁰⁵, and R²⁰⁶ may be the same as or different from each other, and each represent an alkyl group having 1 to 20 carbon atoms.

The alkyl group in General Formulae (A) and (E) is more preferably unsubstituted.

Examples of the basic compound preferably include guanidine, aminopyrrolidine, pyrazole, pyrazoline, piperazine, aminomorpholine, aminoalkylmorpholine, and piperidine. Among these, examples thereof more preferably include a compound having an imidazole structure, a diazabicyclo structure, an onium hydroxide structure, an onium carboxylate structure, a trialkylamine structure, an aniline structure, or a pyridine structure; an alkylamine derivative having a hydroxyl group and/or an ether bond; and an aniline derivative having a hydroxyl group and/or an ether bond.

Examples of the compound having an imidazole structure include imidazole, 2,4,5-triphenylimidazole, benzimidazole, and the like. Examples of the compound having a diazabicyclo structure include 1,4-diazabicyclo[2,2,2]octane, 1,5-diazabicyclo[4,3,0]non-5-ene, 1,8-diazabicyclo[5,4,0]undec-7-ene, and the like. Examples of the compound having an onium hydroxide structure include triarylsulfonium hydroxide, phenacylsulfonium hydroxide, sulfonium hydroxide having a 2-oxoalkyl group, and the like. Specific examples thereof include triphenylsulfonium hydroxide, tris(t-butylphenyl)sulfonium hydroxide, bis(t-butylphenyl)iodonium hydroxide, phenacylthiophenium hydroxide, 2-oxopropylthiophenium hydroxide, and the like. The compound having an onium carboxylate structure is one in which the anionic moiety of the compound having an onium hydroxide structure has been converted into a carboxylate, and examples thereof include acetate, adamantane-1-carboxylate, perfluoroalkyl carboxylate, and the like. Examples of the compound having a trialkylamine structure include tri(n-butyl)amine, tri(n-octyl)amine, and the like. Examples of the compound having an aniline structure include 2,6-diisopropylaniline, N,N-dimethylaniline, N,N-dibutylaniline, N,N-dihexylaniline, and the like. Examples of the alkylamine derivative having a hydroxyl group and/or an ether bond include ethanolamine, diethanolamine, triethanolamine, tris(methoxyethoxyethyl)amine, and the like. Examples of the aniline derivative having a hydroxyl group and/or an ether bond include N,N-bis(hydroxyethyl)aniline, and the like.

Examples of the basic compound preferably include an amine compound having a phenoxy group and an ammonium salt compound having a phenoxy group.

As the amine compound, a primary, secondary, or tertiary amine compound can be used, and an amine compound in which at least one alkyl group is bonded to a nitrogen atom is preferable. The amine compound is more preferably a tertiary amine compound. In the amine compound, as long as at least one alkyl group (preferably having 1 to 20 carbon atoms) is bonded to a nitrogen atom, a cycloalkyl group (preferably having 3 to 20 carbon atoms) or an aryl group (preferably having 6 to 12 carbon atoms) may be bonded to the nitrogen atom, in addition to the alkyl group.

In addition, the amine compound preferably has an oxyalkylene group. The number of the oxyalkylene groups within the molecule is preferably 1 or more, more preferably 3 to 9, and even more preferably 4 to 6. Among the oxyalkylene groups, an oxyethylene group (—CH₂CH₂O—) or an oxypropylene group (—CH(CH₃)CH₂O— or CH₂CH₂CH₂O—) is preferable, and an oxyethylene group is more preferable.

As the ammonium salt compound, a primary, secondary, tertiary, or quaternary ammonium salt compound can be used, and an ammonium salt compound having at least one alkyl group bonded to a nitrogen atom is preferable. In the ammonium salt compound, as long as at least one alkyl group (preferably having 1 to 20 carbon atoms) is bonded to a nitrogen atom, a cycloalkyl group (preferably having 3 to 20 carbon atoms) or an aryl group (preferably having 6 to 12 carbon atoms) may be bonded to the nitrogen atom, in addition to the alkyl group.

The ammonium salt compound preferably has an oxyalkylene group. The number of the oxyalkylene groups within the molecule is preferably 1 or more, more preferably 3 to 9, and even more preferably 4 to 6. Among the oxyalkylene groups, an oxyethylene group (—CH₂CH₂O—) or an oxypropylene group (—CH(CH₃)CH₂O— or —CH₂CH₂CH₂O—) is preferable, and an oxyethylene group is more preferable.

Examples of the anion of the ammonium salt compound include halogen atoms, sulfonate, borate, phosphate, and the like, and among these, halogen atoms and sulfonate are preferable. As the halogen atom, chloride, bromide, or iodide is preferable. As the sulfonate, an organic sulfonate having 1 to 20 carbon atoms is preferable. Examples of the organic sulfonate include aryl sulfonate and alkyl sulfonate having 1 to 20 carbon atoms. The alkyl group of the alkyl sulfonate may have a substituent, and examples of the substituent include a fluorine atom, a chlorine atom, a bromine atom, an alkoxy group, an acyl group, and an aromatic ring group. Specific examples of the alkyl sulfonate include methane sulfonate, ethane sulfonate, butane sulfonate, hexane sulfonate, octane sulfonate, benzyl sulfonate, trifluoromethane sulfonate, pentafluoroethane sulfonate, and nonafluorobutane sulfonate. Examples of the aryl group of the aryl sulfonate include a benzene ring group, a naphthalene ring group, and an anthracene ring group. As the substituent which the benzene ring group, the naphthalene ring group, or the anthracene ring group may have, a linear or branched alkyl group having 1 to 6 carbon atoms, or a cycloalkyl group having 3 to 6 carbon atoms is preferable. Specific examples of the linear or branched alkyl group and the cycloalkyl group include a methyl group, an ethyl group, a n-propyl group, an isopropyl group, a n-butyl group, an i-butyl group, a t-butyl group, a n-hexyl group, and a cyclohexyl group. Other examples of the substituent include an alkoxy group having 1 to 6 carbon atoms, a halogen atom, a cyano group, a nitro group, an acyl group, and an acyloxy group.

The amine compound having a phenoxy group and the ammonium salt compound having a phenoxy group are those having a phenoxy group at the terminal of the alkyl group of the amine compound or ammonium salt compound opposed to the nitrogen atom.

Examples of the substituent of the phenoxy group include an alkyl group, an alkoxy group, a halogen atom, a cyano group, a nitro group, a carboxyl group, a carboxylic ester group, a sulfonic ester group, an aryl group, an aralkyl group, an acyloxy group, and an aryloxy group. The substitution position of the substituent may be any of 2- to 6-positions. The number of substituents may be any of 1 to 5.

It is preferable that at least one oxyalkylene group exists between the phenoxy group and the nitrogen atom. The number of the oxyalkylene groups within the molecule is preferably 1 or more, more preferably 3 to 9, and even more preferably 4 to 6. Among the oxyalkylene groups, an oxyethylene group (—CH₂CH₂O—) or an oxypropylene group (—CH(CH₃)CH₂O— or —CH₂CH₂CH₂O—) is preferable, and an oxyethylene group is more preferable.

The amine compound having a phenoxy group can be obtained by heating a primary or secondary amine having a phenoxy group and haloalkyl ether to react with each other, adding an aqueous solution of a strong base (such as sodium hydroxide, potassium hydroxide, or tetraalkylammonium) to the reaction system, and then extracting the obtained reaction product with an organic solvent (such as ethyl acetate or chloroform).

In addition, the amine compound having a phenoxy group can be obtained by heating a primary or secondary amine and haloalkyl ether having a phenoxy group at a terminal thereof to react with each other, adding an aqueous solution of a strong base to the reaction system, and then extracting the obtained reaction product with an organic solvent.

[Compound (PA) which has proton-accepting functional group and generates compound of which proton acceptor properties are reduced or lost, or which is changed from having proton acceptor properties to being acidity, by decomposing upon irradiation with actinic rays or radiation]

The photosensitive composition may further include, as a basic compound, a compound (hereinafter, also referred to as a compound (PA)) which has a proton-accepting functional group and generates a compound of which proton acceptor properties are reduced or lost, or which is changed from having proton acceptor properties to being acidity, by decomposing upon irradiation with actinic rays or radiation.

The proton-accepting functional group refers to a functional group having an electron or a group which is capable of electrostatically interacting with a proton, and for example, means a functional group with a macrocyclic structure, such as a cyclic polyether, or a functional group containing a nitrogen atom having an unshared electron pair not contributing to it-conjugation. The nitrogen atom having an unshared electron pair not contributing to it-conjugation is, for example, a nitrogen atom having a partial structure represented by the following General Formulae.

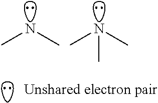

Preferred examples of the partial structure of the proton-accepting functional group include a crown ether structure, an azacrown ether structure, primary to tertiary amine structures, a pyridine structure, an imidazole structure, a pyrazine structure, and the like.

The compound (PA) decomposes upon irradiation with actinic rays or radiation to generate a compound of which proton acceptor properties are reduced or lost, or which is changed from having proton accepting properties to being acidic. Here, the expression “a compound of which proton acceptor properties are reduced or lost, or which is changed from having proton accepting properties to being acidic” means “a compound having a change of proton acceptor properties due to the proton being added to the proton-accepting functional group”. Specifically, the expression means “a decrease in the equilibrium constant at chemical equilibrium in a case where a proton adduct is generated from the compound (PA) having the proton-accepting functional group and the proton”.

Specific examples of the compound (PA) include compounds described in paragraphs [0421] to [0428] of JP2014-41328A, and paragraphs [0108] to [0116] of JP2014-134686A, the contents of which are incorporated in the present specification.

Specific examples of the acid diffusion control agent are shown below, but the present invention is not limited thereto.

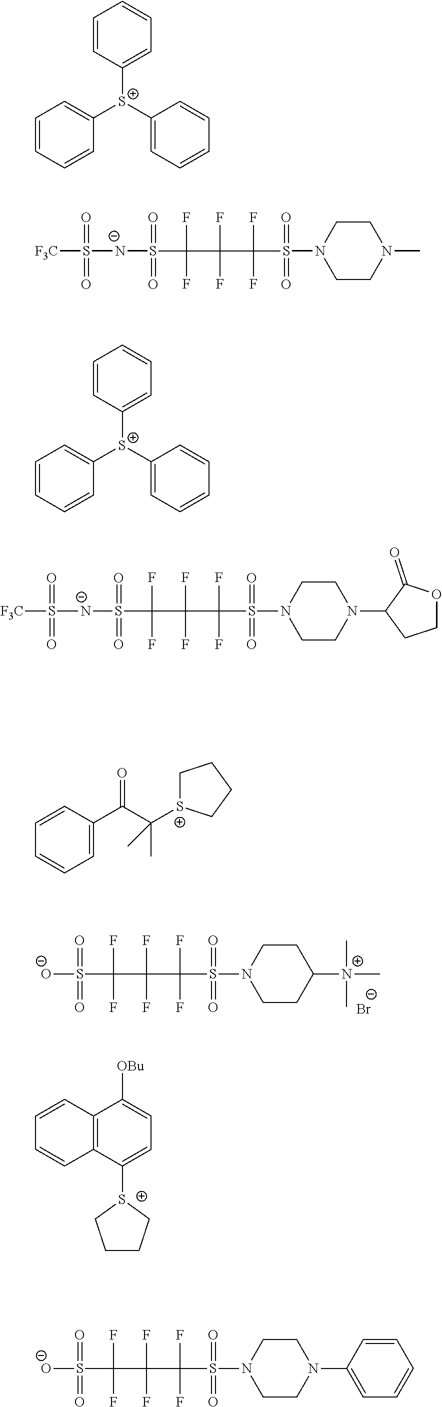

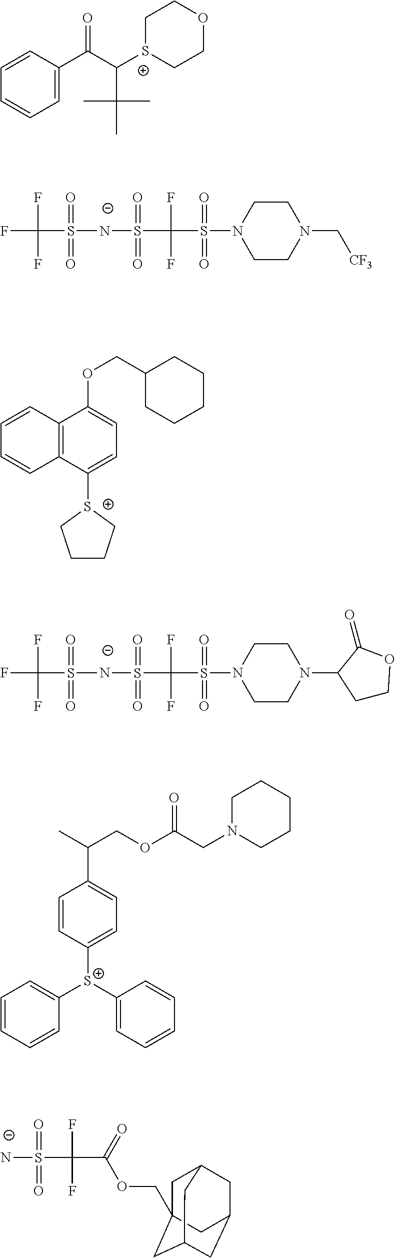 [SMILES: CC(C)(C)C(C(=O)c1ccccc1)[S+]1CCOCC1 ; O=S(=O)([N-]S(=O)(=O)C(F)(F)S(=O)(=O)N1CCN(CC(F)(F)F)CC1)C(F)(F)F ; c1ccc2c([S+]3CCCC3)ccc(OCC3CCCCC3)c2c1 ; O=C1OCCC1N1CCN(S(=O)(=O)C(F)(F)S(=O)(=O)[N-]S(=O)(=O)C(F)(F)F)CC1 ; CC(COC(=O)CN1CCCCC1)c1ccc([S+](c2ccccc2)c2ccccc2)cc1 ; [NH-]S(=O)(=O)C(F)(F)C(=O)OCC12CC3CC(CC(C3)C1)C2]

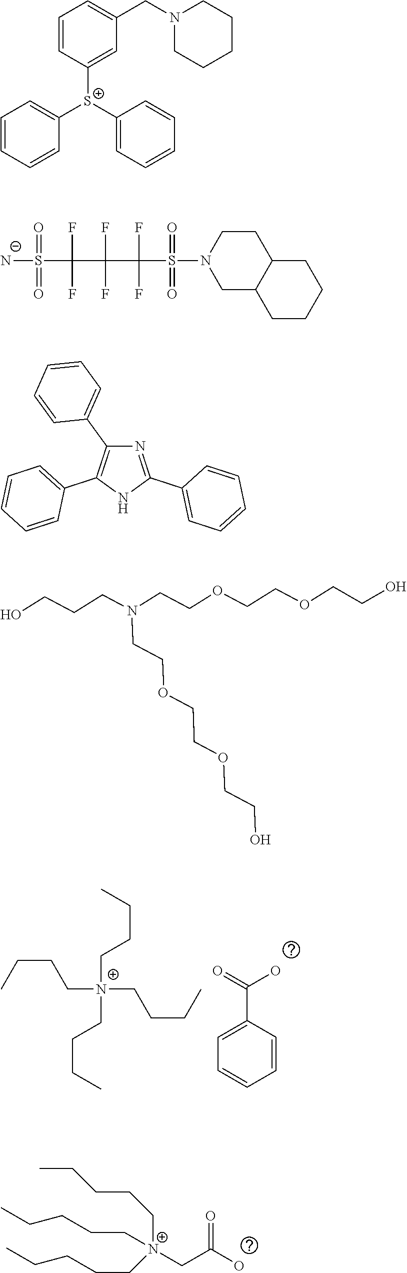

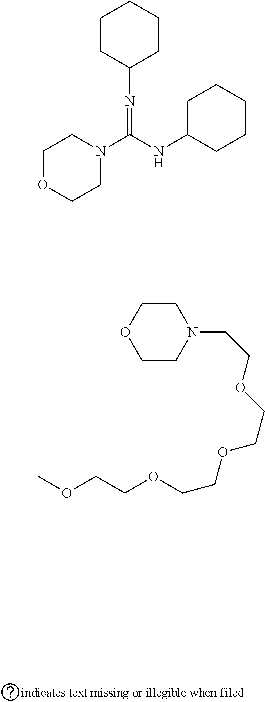 [SMILES: C1CCC(N=C(NC2CCCCC2)N2CCOCC2)CC1 ; COCCOCCOCCOCCN1CCOCC1]

In a case where the photosensitive composition includes an acid diffusion control agent, the content of the acid diffusion control agent in the photosensitive composition is preferably 0.001% to 10% by mass and more preferably 0.01% to 5% by mass, with respect to the total solid content of the composition.

The acid diffusion control agent may be used singly or in combination of two or more kinds thereof. In a case where two or more acid diffusion control agents are used in combination, the total amount thereof is preferably within the above range.

The use proportion between the photoacid generator to the acid diffusion control agent in the photosensitive composition is preferably the photoacid generator/acid diffusion control agent (molar ratio)=2.5 to 300. The molar ratio is preferably 2.5 or more from the viewpoint of sensitivity and resolution, and is preferably 300 or less from the viewpoint of suppressing the reduction in resolution due to thickening of the resist pattern over time until post-exposure heating process. The photoacid generator/acid diffusion control agent (molar ratio) is more preferably 5.0 to 200, and even more preferably 7.0 to 150.

Examples of the acid diffusion control agent include the compounds (amine compounds, amide group-containing compounds, urea compounds, nitrogen-containing heterocyclic compounds, and the like) described in paragraphs [0140] to [0144] of JP2013-11833A.

<(E) Hydrophobic Resin>

The photosensitive composition may have a hydrophobic resin different from the resin (A), in addition to the resin (A).

It is preferable that the hydrophobic resin is designed to be unevenly distributed to a surface of a resist film, but in contrast to a surfactant, the hydrophobic resin is not necessarily required to have a hydrophilic group in the molecule, and may not contribute to uniform mixing of polar/nonpolar substances.

Examples of the effect of addition of the hydrophobic resin include control of a static or dynamic contact angle of the resist film surface for water, and suppression of out gas, and the like.

From the viewpoint of uneven distribution to the film surface layer, it is preferable that the hydrophobic resin includes one or more kinds of any of “a fluorine atom”, “a silicon atom”, and “a CH₃ partial structure included in the side chain moiety of the resin”, and it is more preferable that the hydrophobic resin includes two or more kinds thereof. Furthermore, it is preferable that the hydrophobic resin includes a hydrocarbon group having 5 or more carbon atoms. These groups may be included in the main chain of the resin or may be substituted at the side chain.

In a case where the hydrophobic resin includes a fluorine atom and/or a silicon atom, the fluorine atom and/or the silicon atom in the hydrophobic resin may be included in the main chain of the resin or may be included in the side chain of the resin.

In a case where the hydrophobic resin includes a fluorine atom, as the partial structure including a fluorine atom, an alkyl group having a fluorine atom, a cycloalkyl group having a fluorine atom, or an aryl group having a fluorine atom is preferable.

The alkyl group having a fluorine atom (preferably having 1 to 10 carbon atoms, and more preferably 1 to 4 carbon atoms) is a linear or branched alkyl group which has at least one hydrogen atom substituted with a fluorine atom, and may further have a substituent other than the fluorine atom.

The cycloalkyl group having a fluorine atom is a monocyclic or polycyclic cycloalkyl group which has at least one hydrogen atom substituted with a fluorine atom, and may further have a substituent other than the fluorine atom.

Examples of the aryl group having a fluorine atom include an aryl group, such as a phenyl group and a naphthyl group, in which at least one hydrogen atom included in the aryl group is substituted with a fluorine atom.

Examples of a repeating unit having a fluorine atom or a silicon atom include the repeating units described in paragraph [0519] of US2012/0251948A1.

In addition, as described above, it is also preferable that the hydrophobic resin has a CH₃ partial structure in the side chain moiety thereof.

Here, the CH₃ partial structure which the hydrophobic resin has in the side chain moiety thereof are intended to include CH₃ partial structure which an ethyl group, a propyl group, and the like have, respectively.

On the other hand, a methyl group (for example, an a-methyl group of a repeating unit having a methacrylic acid structure) which is directly bonded to a main chain of the hydrophobic resin has little contribution to uneven distribution of the hydrophobic resin on the surface due to the effect of the main chain, and thus is not included in the CH3 partial structure according to the present invention.

With regard to the hydrophobic resin, reference can be made to the description in paragraphs [0348] to [0415] of JP2014-010245A, the contents of which are incorporated in the present specification.

As the hydrophobic resin, resins described in JP2011-248019A, JP2010-175859A, and JP2012-032544A can also be preferably used.

In a case where the photosensitive composition includes the hydrophobic resin, the content of the hydrophobic resin is preferably 0.01% to 20% by mass, and more preferably 0.1% to 15% by mass, with respect to the total solid content of the composition.

The hydrophobic resin may be used singly or in combination of two or more kinds thereof. In a case where two or more kinds of hydrophobic resins are used in combination, the total amount thereof is preferably within the above range.

<Surfactant (F)>

The photosensitive composition may include a surfactant (F). By including the surfactant, it is possible to form a resist pattern which has more excellent adhesiveness and has fewer development defects.

As the surfactant, a fluorine-based and/or a silicon-based surfactant is preferable.

Examples of the fluorine-based and/or the silicon-based surfactant include the surfactants described in paragraph [0276] of US2008/0248425A. In addition, EFTOP EF301 or EF303 (manufactured by Shin-Akita Kasei K.K.); FLORAD FC430, 431, or 4430 (manufactured by Sumitomo 3M Inc.); MEGAFACE F171, F173, F176, F189, F 113, F110, F177, F120, or R08 (manufactured by DIC Corporation); SURFLON S-382, SC101, 102, 103, 104, 105, or 106 (manufactured by Asahi Glass Co., Ltd.); TROYSOL S-366 (manufactured by Troy Chemical Corp.); GF-300 and GF-150 (manufactured by Toagosei Chemical Industry Co., Ltd.); SURFLON S-393 (manufactured by Seimi Chemical Co., Ltd.); EFTOP EF121, EF122A, EF122B, RF122C, EF I25M, EF135M, EF351, EF352, EF801, EF802, or EF601 (manufactured by JEMCO Inc.); PF636, PF656, PF6320, or PF6520 (manufactured by OMNOVA Solutions Inc.); KH-20 (manufactured by Asahi Kasei Corporation); and FTX-2040 208G, 218G, 230G, 204D, 208D, 212D, 218D, or 222D (manufactured by NEOS COMPANY LIMITED). Polysiloxane Polymer KP-341 (manufactured by Shin-Etsu Chemical Co., Ltd.) can also be used as the silicon-based surfactant.

Furthermore, in addition to the known surfactants as described above, a surfactant may be synthesized using a fluoroaliphatic compound which is produced by a telomerization method (also referred to as a telomer method) or an oligomerization method (also referred to as an oligomer method). Specifically, a polymer containing a fluoroaliphatic group derived from the fluoroaliphatic compound may also be used as the surfactant. The fluoroaliphatic compound can be synthesized by the method described in JP2002-090991 A.

In addition, surfactants other than the fluorine-based surfactant and/or the silicon-based surfactants described in paragraph [0280] of US2008/0248425A may be used.

In a case where the photosensitive composition includes a surfactant, the content thereof is preferably 0.0001% to 2% by mass, and more preferably 0.0005% to 1% by mass, with respect to the total solid content of the composition.

The surfactant may be used singly or in combination of two or more kinds thereof.

In a case where two or more kinds of the surfactants are used in combination, the total amount thereof is preferably within the above range.

<Other Additives (G)>

The photosensitive composition may further include a compound (for example, a phenol compound having a molecular weight of 1000 or less, or an alicyclic or aliphatic compound including a carboxyl group) promoting solubility in a dissolution inhibiting compound, a dye, a plasticizer, a photosensitizer, a light absorber, and/or a developer.

The photosensitive composition may further include a dissolution inhibiting compound. Here, the “dissolution inhibiting compound” is a compound having a molecular weight of 3000 or less, which decreases the solubility in an organic-based developer by being decomposed due to the action of an acid.

<Procedure of Steps>

Examples of the method of forming a resist film on a substrate using the photosensitive composition include a method of applying the photosensitive composition on a substrate.

In addition, it is preferable that the photosensitive composition before being applied is filtered through a filter, as necessary. A pore size of the filter is preferably 0.1 μm or less, more preferably 0.05 μm or less, and even more preferably 0.03 μm or less. The filter is preferably formed of polytetrafluoroethylene, polyethylene, or nylon.

The photosensitive composition can be applied to a substrate (example: silicon/silicon dioxide coating) which is used in the manufacture of integrated circuit elements, by using a suitable application method such as a spinner, a coater, or the like. As an application method, spin coating using a spinner is preferable. A rotation speed in a case of spin coating using a spinner is preferably 1000 rpm to 4000 rpm.

After applying the photosensitive composition, the substrate may be dried to form a resist film. As necessary, various base films (inorganic film, organic film, anti-reflection film) may be formed on an underlayer of the resist film.

An example of a drying method includes a method of drying by heating. Bakibng can be performed by units provided in a typical exposure machine and/or developing machine, and may be performed using a hot plate, or the like.

The heating temperature is preferably 80° C. to 150° C., and more preferably 80° C. to 140° C.

The heating time is preferably 30 to 1000 seconds, and more preferably 60 to 800 seconds.

A film thickness of the resist film is not particularly limited, but is preferably 10 to 80 nm and more preferably 15 to 70 nm, from the viewpoint of forming a high-precision fine resist pattern.

A top coat may be formed on an upper layer of the resist film using a top coat composition.

It is preferable that the top coat composition is not mixed with the resist film and can be applied uniformly to the resist film.

In addition, it is preferable to dry the resist film before forming the top coat. Next, the top coat composition is applied on the obtained resist film in the same unit as in the method of forming the resist film described above, and is dried, so that the top coat layer can be formed.

The film thickness of the top coat is preferably 10 to 200 nm, more preferably 20 to 100 nm.

Kinds of the top coat are not particularly limited, and a conventionally known top coat can be formed by a conventionally known method. For example, the top coat can be formed based on the description in paragraphs [0072] to [0082] of JP2014-059543A.

For example, a top coat including a basic compound described in JP2013-061648A is preferably formed on the resist film. Specific examples of the basic compound which may be included in the top coat include a basic compound which may be included in the photosensitive composition described later.

[Step 2]

Step 2 is a step of exposing the resist film to light.

Examples of an exposing method include a method of irradiating the formed resist film with actinic rays or radiation through a predetermined mask. More specifically, as shown in FIG. 2, there is a method of irradiating a predetermined region of the resist film 12 with actinic rays or radiation through a mask 14 as shown by arrows.

Kinds of actinic rays or radiation used for exposure is not particularly limited, but light of 250 nm or less is preferable, and examples thereof include KrF excimer laser light (248 nm), ArF excimer laser light (193 nm), F₂ excimer laser light (157 nm), EUV Light (13.5 nm), an electron beam, and the like.

Among these, EUV light is preferable.

After exposure, it is preferable to perform baking (heating) before development. The reaction at an exposed portion is expedited by baking and sensitivity and a resist pattern profile are more improved.

The heating temperature is preferably 80° C. to 150° C., and more preferably 80° C. to 140° C.

The heating time is preferably 10 to 1000 seconds, and more preferably 10 to 180 seconds.

Heating can be performed by units provided in a typical exposure machine and/or developing machine, and may be performed using a hot plate, or the like.

This step is also called post-exposure bake.

[Step 3]

Step 3 is a step of developing the exposed resist film to form a resist pattern. For example, in a case where the resist film is a so-called positive tone, as shown in FIG. 3, the exposed portion of the resist film is removed by development, and a resist pattern 16 is formed on the substrate 10.

Examples of a development method include a method of dipping a substrate in a bath filled with a developer for a predetermined time (a dip method), a method in which development is performed by heaping a developer up onto the surface of a substrate by surface tension, and then leaving it to stand for a certain period of time (a puddle method), a method of spraying a developer on a substrate surface (a spray method), and a method of continuously ejecting a developer on a substrate spinning at a constant speed while scanning a developer ejecting nozzle at a constant rate (a dynamic dispense method).

Furthermore, after the step of performing the development, a step of stopping the development may be carried out while replacing the solvent with another solvent.

The development time is preferably 10 to 300 seconds, and more preferably 20 to 120 seconds.

The developer temperature is preferably 0° C. to 50° C., and more preferably 15° C. to 35° C.

The developer may be either an alkaline developer or a developer including an organic solvent (hereinafter, also referred to as an organic-based developer).

It is preferable to use an aqueous alkaline solution containing an alkali as the alkaline developer. Kinds of the aqueous alkaline solutions are not particularly limited, but examples thereof include aqueous alkaline solutions including a quaternary ammonium salt represented by tetramethylammonium hydroxide, an inorganic alkali, primary amine, secondary amine, tertiary amine, alcoholamine, cyclic amine, or the like. Among these, an aqueous solution of a quaternary ammonium salt represented by tetramethylammonium hydroxide (TMAH) is preferable as the alkaline developer.

The alkali concentration of the alkaline developer is typically 0.1% to 20% by mass. In addition, a pH of the alkaline developer is typically 10.0 to 15.0.

As the organic developer, a developer including at least one organic solvent selected from the group consisting of a ketone-based solvent, an ester-based solvent, an alcohol-based solvent, an amide-based solvent, an ether-based solvent, and hydrocarbon-based solvents is preferable.

The organic developer may include a plurality of the above described solvents, or may include a solvent other than the above described solvents or water. The moisture content in the total developer is preferably less than 50% by mass, more preferably less than 20% by mass, even more preferably less than 10% by mass, and particularly preferably, moisture is not substantially included.

The content of the organic solvent is preferably 50% to 100% by mass, more preferably 80% to 100% by mass, and even more preferably 90% to 100% by mass, with respect to the total amount of the organic-based developer.

The developer may include a known surfactant, as necessary.

In a case where the developer includes a surfactant, the content of the surfactant is typically 0.001% to 5% by mass, preferably 0.005% to 2% by mass, and more preferably 0.01% to 0.5% by mass, with respect to the total amount of the developer.

[Step 4]

Step 4 is a step of applying a pattern reversal film forming composition such that the resist pattern is coated and thereby forming a pattern reversal film. More specifically, as shown in FIG. 4, by performing this step, a pattern reversal film 18 is formed such that the resist pattern 16 is coated.

Hereinafter, firstly, a pattern reversal film forming composition will be described in detail, and then the procedure of the step will be described in detail.

<Composition for Forming Pattern Reversal Film>

Material included in the pattern reversal film forming composition is not particularly limited, but the pattern reversal film forming composition preferably includes polysiloxane.

Examples of the polysiloxane include a product of a hydrolysis and/or condensation reaction of a silane compound containing a tetraalkoxysilane represented by Formula (1) and an alkoxysilane represented by Formula (2).

Si(OR₁)₄ (1)

(In Formula, R₁ each independently represents an alkyl group having 1 to 4 carbon atoms.)

XₙSi(OR₂)₄₋ₙ (2)

(In Formula, X each independently represents a hydrocarbon group having 1 to 9 carbon atoms, R₂ each independently represents an alkyl group having 1 to 4 carbon atoms, and n represents an integer of 1 to 3.)

In Formula (1), examples of R₁ include a methyl group, an ethyl group, an n-propyl group, an isopropyl group, an n-butyl group, an isobutyl group, and a tert-butyl group, and a methyl group or an ethyl group is preferable.

Examples of the tetraalkoxysilane represented by Formula (1) include tetramethoxysilane, tetraethoxysilane, tetra-n-propoxysilane, tetraisopropoxysilane, and the like.

Among these, tetramethoxysilane or tetraethoxysilane is preferable.

The tetraalkoxysilane represented by Formula (1) may be used singly or in combination of two or more kinds thereof.

X in Formula (2) is not particularly limited, but preferred examples thereof include: an alkyl group such as a methyl group, an ethyl group, and a propyl group; an alkenyl group such as a vinyl group, an ally group, a 1-propenyl group, and an i-propenyl group; an alkynyl group such as a propynyl group and an ethynyl group; an aryl group such as a phenyl group and a tolyl group; and an aralkyl group such as a benzyl group and a phenylethyl group. Among these, a methyl group, an ethyl group, or a phenyl group is preferable.

In addition, examples of R₂ include a methyl group, an ethyl group, an n-propyl group, an isopropyl group, an n-butyl group, an isobutyl group, and a tert-butyl group, and a methyl group or an ethyl group is preferable.

Examples of the alkoxysilane represented by Formula (2) include a methyltrialkoxysilane such as methyltrimethoxysilane, methyltriethoxysilane, methyltri-n-propoxysilane, methyltriisopropoxysilane, methyltri-n-butoxysilane, methyltriisobutoxysilane, and methyltri-tert-butoxysilane; an ethyltrialkoxysilane such as ethyltrimethoxysilane, ethyltriethoxysilane, ethyltri-n-propoxysilane, ethyltriisopropoxysilane, ethyltri-n-butoxysilane, ethyltriisobutoxysilane, and ethyltri-tert-butoxysilane; a phenyltrialkoxysilane such as phenyltrimethoxysilane, phenyltriethoxysilane, phenyltri-n-propoxysilane, phenyltriisopropoxysilane, phenyltri-n-butoxysilane, phenyltriisobutoxysilane, and phenyltri-tert-butoxysilane; a dimethyldialkoxysilane such as dimethyldimethoxysilane, dimethyldiethoxysilane, dimethyldi-n-propoxysilane, dimethyldiisopropoxysilane, dimethyldi-n-butoxysilane, dimethyldiisobutoxysilane, and dimethyldi-tert-butoxysilane; a diethyldialkoxysilane such as diethyldimethoxysilane, diethyldiethoxysilane, diethyldi-n-propoxysilane, diethyldiisopropoxysilane, diethyldi-n-butoxysilane, diethyldiisobutoxysilane, and diethyldi-tert-butoxysilane; and a diphenyldialkoxysilane such as diphenyldimethoxysilane, diphenyldiethoxysilane, diphenyldi-n-propoxysilane, diphenyldiisopropoxysilane, diphenyldi-n-butoxysilane, diphenyldiisobutoxysilane, and diphenyldi-tert-butoxysilane.

Among these, methyltrimethoxysilane, methyltriethoxysilane, phenyltrimethoxysilane, or phenyltriethoxysilane is preferable.

The alkoxysilane represented by Formula (2) may be used singly or in combination of two or more kinds thereof.

In the hydrolysis and/or the condensation reaction of the silane compound containing the tetraalkoxysilane represented by Formula (1) and the alkoxysilane represented by Formula (2), the proportion of the tetraalkoxysilane represented by Formula (1) is preferably 1% to 50% by mol, more preferably 10% to 50% by mol, and further preferably 30% to 50% by mol, with respect to the number of moles of the total silane compound.

The silane compound containing the tetraalkoxysilane represented by Expression (1) and the alkoxysilane represented by Formula (2) is dissolved in a solvent, water and a catalyst are added to the resultant solution at room temperature, and then the obtained solution is mixed to be hydrolyzed and/or condensed at a typical temperature of 0° C. to 100° C., and as a result, polysiloxane can be manufactured.

Examples of the catalyst used for the hydrolysis and condensation reaction include an organic acid, an inorganic acid, an organic base, an inorganic base, and an organic chelate compound. Among these, an acid catalyst is preferable. Examples of the acid catalyst include an inorganic acid such as hydrochloric acid, nitric acid, and phosphoric acid, and an organic acid, for example, a carboxylic acid such as formic acid, oxalic acid, fumaric acid, maleic acid, glacial acetic acid, acetic anhydride, propionic acid, and n-butyric acid.

As the solvent used in the above reaction, a solvent generally used in synthesizing polysiloxane can be used, and for example, an organic solvent used in a pattern reversal film forming composition described later can be used. Accordingly, the prepared polysiloxane-containing solution can be used as it is for the preparation of the pattern reversal film forming composition.

The above described polysiloxane preferably has a structural unit represented by Formula (3) and a structural unit represented by Formula (4).

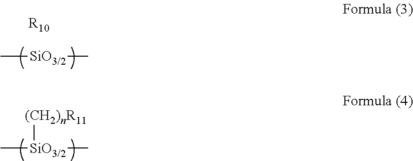

In Formula (3), R₁₀ represents an alkyl group having 1 to 8 carbon atoms.

Examples of the alkyl group represented by R₁₀ include a methyl group, an ethyl group, a n-propyl group, an isopropyl group, a n-butyl group, an isobutyl group, a tert-butyl group, a pentyl group, a heptyl group, a hexyl group, an octyl group, a cyclohexyl group, and the like, and a methyl group or an ethyl group is preferable.

In formula (4), R₁₁ represents an acryloyloxy group or a methacryloyloxy group. n represents an integer of 2 to 4.

In the polysiloxane, the proportion of the structural unit represented by Formula (3) to the structural unit represented by Formula (4) is preferably 50/50 to 99/1 in molar ratio, and more preferably 70/30 to 95/5.

In addition, the structural unit represented by Formula (1) and the structural unit represented by Formula (2) may form any structure of a random copolymer, a block copolymer, and an alternating copolymer.

The content of polysiloxane in the pattern reversal film forming composition is preferably 1 to 30% by mass and more preferably 5 to 20% by mass, with respect to the total mass of the pattern reversal film forming composition.

The pattern reversal film forming composition may include an organic solvent.

As the organic solvent, alcohols having 4 to 10 carbon atoms or ethers having 4 to 10 carbon atoms are preferable. The organic solvent may further include a resist solvent as long as intermixing with the resist pattern does not occur.

Examples of the alcohols having 4 to 10 carbon atoms include butanol, pentanol, cyclopentanol, hexanol, cyclohexanol, 4-methyl-2-pentanol, and the like.

Examples of the ethers having 4 to 10 carbon atoms include propylene glycol-n-propyl ether, propylene glycol-n-butyl ether, propylene glycol phenyl ether, dipropylene glycol-n-propyl ether, dipropylene glycol-n-butyl ether, dipropylene glycol dimethyl ether, tripropylene glycol methyl ether, and the like.

Examples of the resist solvent include methyl lactate, ethyl lactate, acetone, propylene glycol monomethyl ether acetate, propylene glycol monomethyl ether, and the like.

The pattern reversal film forming composition may include, as desired, a pH adjuster (an organic acid such as a maleic acid), a condensation accelerator (a quaternary ammonium salt such as benzyltriethylammonium chloride), a surfactant, a photoacid generator (an onium salt compound such as a sulfonium salt and an iodonium salt), and various additives such as a quencher (a tertiary amine reacting with an acid).

The surfactant is an additive for improving the coatability of the pattern reversal film forming composition. Examples of the surfactant include known surfactants such as nonionic surfactants and fluorine-based surfactants.

In a case where the pattern reversal film forming composition includes a surfactant, the content of the surfactant in the pattern reversal film forming composition is preferably 0.5% by mass or less, more preferably 0.2% by mass or less, even more preferably 0.1% by mass or less, with respect to the total mass of the pattern reversal film forming composition. The lower limit is preferably 0.01% by mass or more.

Specific examples of the above described surfactant include nonionic surfactants of polyoxyethylene alkyl ethers such as polyoxyethylene lauryl ether, polyoxyethylene stearyl ether, polyoxyethylene cetyl ether, and polyoxyethylene oleyl ether; polyoxyethylene alkylallyl ethers such as polyoxyethylene octylphenol ether and polyoxyethylene nonylphenol ether; polyoxyethylene-polyoxypropylene block copolymers; sorbitan fatty acid esters such as sorbitan monolaurate, sorbitan monopalmitate, sorbitan monostearate, sorbitan monooleate, sorbitan trioleate, and sorbitan tristearate; polyoxyethylene sorbitan fatty acid esters such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; and fluorine-based surfactants such as EFTOP EF301, EF303, and EF352, (manufactured by MITSUBISHI Materials Electronic Chemicals Co., Ltd. (manufactured by former JEMCO Inc.)), MEGAFACE F171, F173, and R-30 (manufactured by DIC Corporation), Fluorad FC430 and FC431 (manufactured by Sumitomo 3M Ltd.), AsahiGuard AG710, Surflon S-382, SC101, SC102, SC103, SC104, SC105, and SC106 (manufactured by Asahi Glass Co., Ltd.); and organosiloxane polymer KP341 (manufactured by Shin-Etsu Chemical Co., Ltd.).

The surfactant may be used singly or in combination of two or more kinds thereof.

<Procedure of Steps>

Examples of the method of applying a pattern reversal film forming composition include a method of applying a pattern reversal film forming composition on a substrate in which a resist pattern is formed on a surface thereof by using a spinner, a coater, or the like. Thereafter, it is preferable to hold the resultant at room temperature or bake at a temperature higher than room temperature and lower than 180° C. to form a pattern reversal film.

The baking temperature is preferably 80° C. to 180° C., and more preferably 80° C. to 150° C. The baking time is preferably 10 to 300 seconds, and more preferably 30 to 180 seconds.

The thickness of the pattern reversal film is not particularly limited as long as the resist pattern can be coated, but is preferably 10 to 1000 nm, and more preferably 50 to 500 nm.

[Step 5]

Step 5 is a step of performing etch-back on the pattern reversal film and exposing a surface of the resist pattern to light. More specifically, as shown in FIG. 5, the pattern reversal film 18 is subjected to etch-back, whereby a surface of the resist pattern 16 is exposed.

The method of performing etch-back is not particularly limited, and examples thereof include dry etching using a fluorine-based gas such as CF₄, wet etching using an organic solvent or an aqueous solution of an organic acid or organic base, a CMP (chemical mechanical polishing) method, and the like.

[Step 6]

Step 6 is a step of removing the resist pattern to form the reversed pattern. More specifically, as shown in FIG. 6, the resist pattern 16 in FIG. 5 is removed to form a reversed pattern 20 on the substrate 10.

As the method of removing the resist pattern, a known dry etching method can be used, and an example thereof includes O₂ etching.

A known dry etching apparatus can be used for removing the resist pattern, and processing conditions can be adjusted appropriately.

[Other Steps]

The method of forming a reversed pattern according to the embodiment of the present invention may include steps other than the above Steps 1 to 6.

For example, a step of performing a rinse treatment on the resist pattern (a rinsing step) may be included between Step 3 and Step 4.

The rinsing step is a step of washing (rinsing) the resist pattern with a rinse agent after the developing step.

In the rinse agent, it is preferable to use pure water as a rinse agent in a case of forming a positive-tone resist pattern, and it is preferable to use a rinse agent containing an organic solvent in a case of forming a negative-tone resist pattern. In addition, as the organic solvent, at least one organic solvent selected from the group consisting of a hydrocarbon-based solvent, a ketone-based solvent, an ester-based solvent, an alcohol-based solvent, an amide-based solvent, and an ether-based solvent is preferable.

The rinsing method is not particularly limited, but examples thereof include a method (a rotation jetting method) of continuously jetting the rinse agent to the substrate which is rotating at a given speed; a method (a dip method) of dipping the substrate in a tank filled with the rinse agent for a given period of time; a method (a spraying method) of spraying the rinse agent to a surface of the substrate; and the like.

The photosensitive composition, the pattern reversal film forming composition, and various materials used for the method of forming a reversed pattern (for example, a resist solvent, a developer, a rinse agent, an antireflection film forming composition, a top coat composition, and the like) preferably do not include impurities such as metals, metal salts including halogen, acids, alkalis, or the like. The content of the impurities included in these materials is preferably 1 ppm by mass or less, more preferably 1 ppb by mass or less, even more preferably 100 ppt by mass or less, and particularly preferably 10 ppt by mass or less, and it is most preferable that the impurities are not substantially included (no higher than a detection limit of a measurement device).

Examples of a method of removing impurities such as metals from the various materials include filtration using a filter. As a filter pore diameter, a pore size is preferably 10 nm or less, more preferably 5 nm or less, and even more preferably 3 nm or less. As the materials of the filter, a polytetrafluoroethylene-made filter, a polyethylene-made filter, or a nylon-made filter is preferable. Composite materials in which these materials are combined with an ion exchange medium may be used for forming the filter. As the filter, a filter which had been washed with an organic solvent in advance may be used. In a step of filtration using a filter, plural kinds of filters connected in series or in parallel may be used. In a case of using the plural kinds of filters, a combination of filters having different pore diameters and/or materials may be used. In addition, various materials may be filtered plural times, and a step of filtering plural times may be a step of circulatory filtration.

Furthermore, examples of a method of reducing impurities such as metals included in various materials include a method of selecting a raw material having a low metal content as a raw material constituting various materials, a method of performing filtering using a filter with respect to a raw material constituting various materials, a method of performing distillation under conditions as much as possible to suppress contamination such that the inside of equipment is lined with TEFLON (registered trademark), and the like. Preferred conditions in the filtration using a filter to be performed on the raw material constituting the various materials are similar to the above described conditions.

In addition to the filtration using a filter, impurities may be removed using an adsorbent material, and the filtration using a filter and the adsorbent material may be used in combination. A known adsorbent material can be used as the adsorbent material, and examples thereof include inorganic-based adsorbent materials such as silica gel and zeolite, and organic-based adsorbent materials such as activated carbon, and the like.

The reversed pattern obtained by a method of forming a reversed pattern according to the embodiment of the present invention is used as a mask to perform appropriate etching processing, ion injection, and the like, so that it is possible to manufacture semiconductor fine circuits, imprint mold structures, photomasks, and the like.

The reversed pattern formed by the above described methods can be used to form a guide pattern in Directed Self-Assembly (DSA) (for example, refer to ACS Nano Vol. 4 No. 8 Page 4815 to 4823). In addition, the reversed pattern formed by the above described methods can be used as a core material (core) of the spacer process disclosed in, for example, JP1991-270227A (JP-H3-270227) and JP2013-164509A.

A photomask manufactured using the method of forming a reversed pattern according to the embodiment of the present invention may be a light transmission type mask used with ArF excimer laser or the like or may be a light reflective type mask used in reflective lithography employing EUV light as a light source.

The present invention also relates to a method of manufacturing an electronic device, which includes the method of forming a reversed pattern according to the embodiment of the present invention described above.

The electronic device manufactured by the method of manufacturing an electronic device according to the embodiment of the present invention is suitably mounted on electric and electronic equipment (home appliances, office appliances (OA), media-related equipment, optical equipment and communication equipment, or the like).

### EXAMPLE

Hereinafter, the present invention will be described in more details with reference to Examples, but the present invention is not limited thereto.

### Synthesis Example 1: Synthesis of Polymer P-1

Cyclohexanone (194.3 g) was placed in a three-necked flask under a nitrogen stream and heated at 80° C.

Next, a solution of 15.5 g, 25.4 g, and 9.8 g of the monomers corresponding to respective repeating units (M-2/M-4/M23) of a polymer P-1, in order from the left side, and a polymerization initiator V-601 (3.17 g) (manufactured by Wako Pure Chemical Industries, Ltd.), which were dissolved in cyclohexanone (105 g), was added dropwise to the flask for 6 hours. After completion of the dropwise addition, the reaction solution was further allowed to undergo a reaction at 80° C. for 2 hours, and then was left at room temperature.

The reaction solution was left to be cooled, and then added dropwise to a mixed liquid (methanol:water=5/5 (mass ratio)) for 20 minutes, and the precipitated powder was filtered. The obtained powder was dried to obtain a polymer P-1 (31.6 g).

The compositional ratio (mass ratio) of the repeating unit determined by a nuclear magnetic resonance (NMR) method was 30/50/20. The weight-average molecular weight of the polymer P-1, in terms of standard polystyrene was 8,000, and the dispersity (Mw/Mn) thereof was 1.6.

Other polymers were synthesized by the same procedure or by a known procedure.

The monomer structures used for polymers P-1 to P-67 are shown below. The compositional ratio (mass ratio), the weight-average molecular weight (Mw), and the dispersity, in each polymer, are shown in Table 1 below. The compositional ratio corresponds to each repeating unit in order from the left.

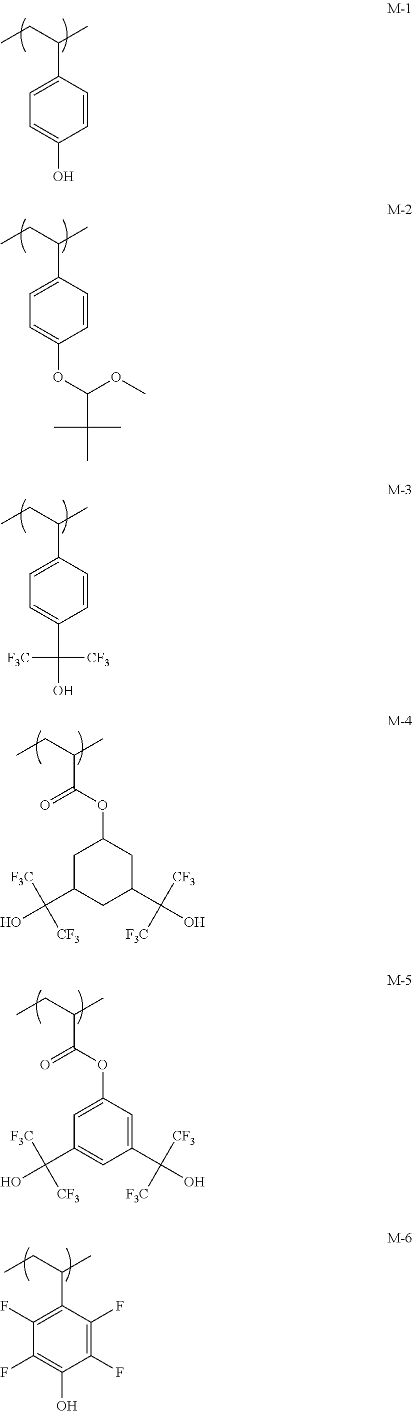

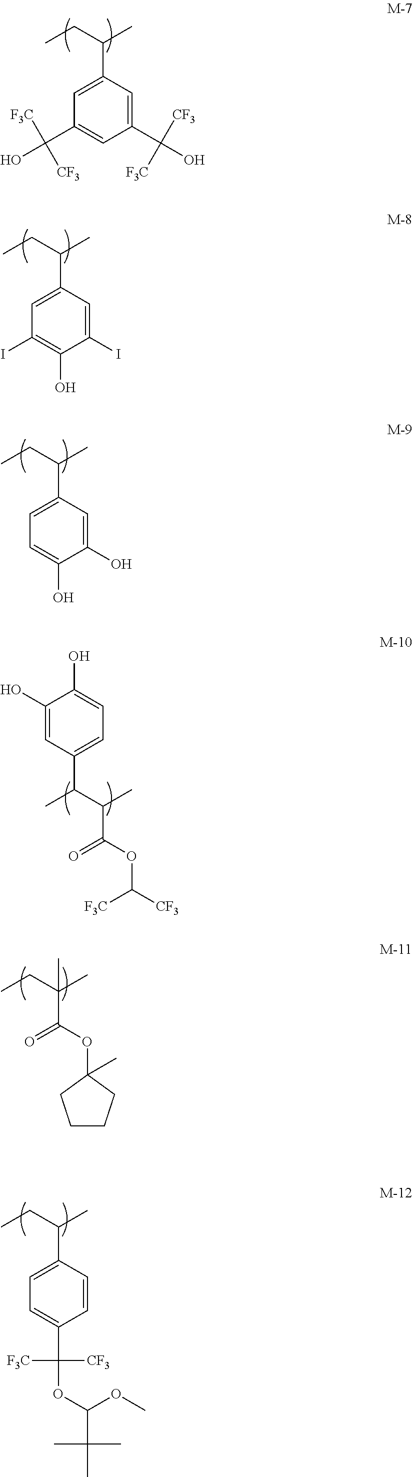

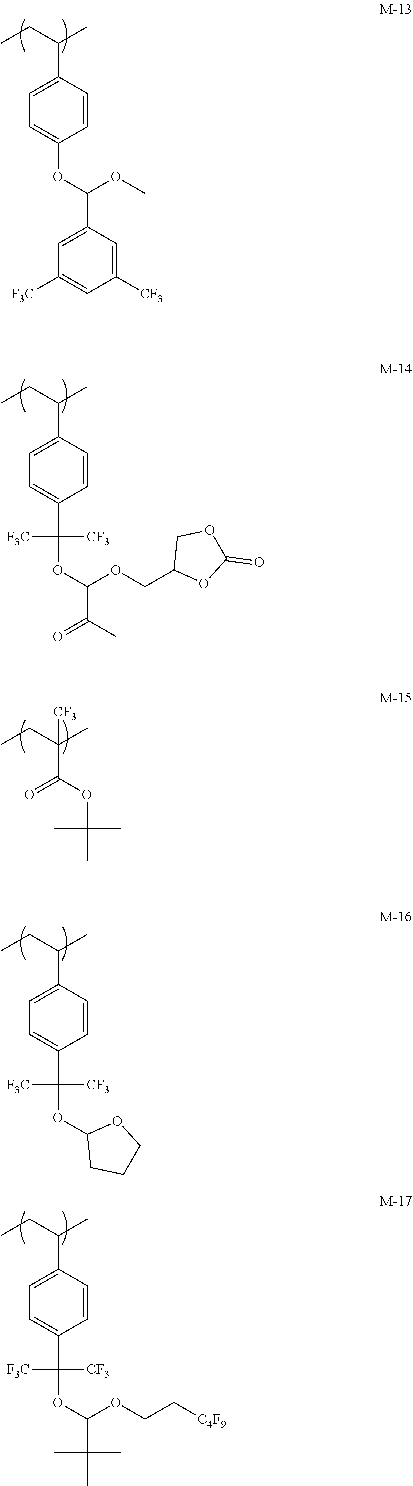

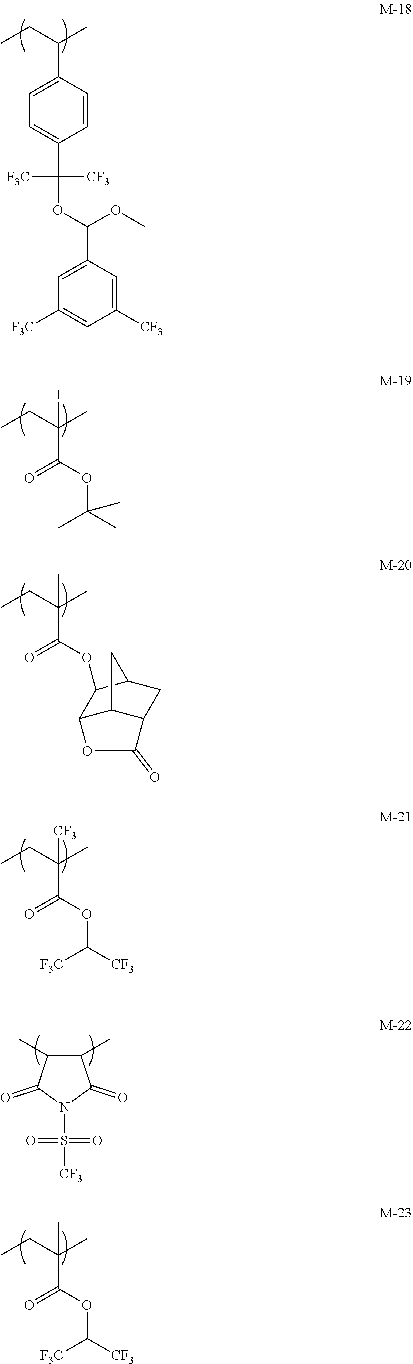

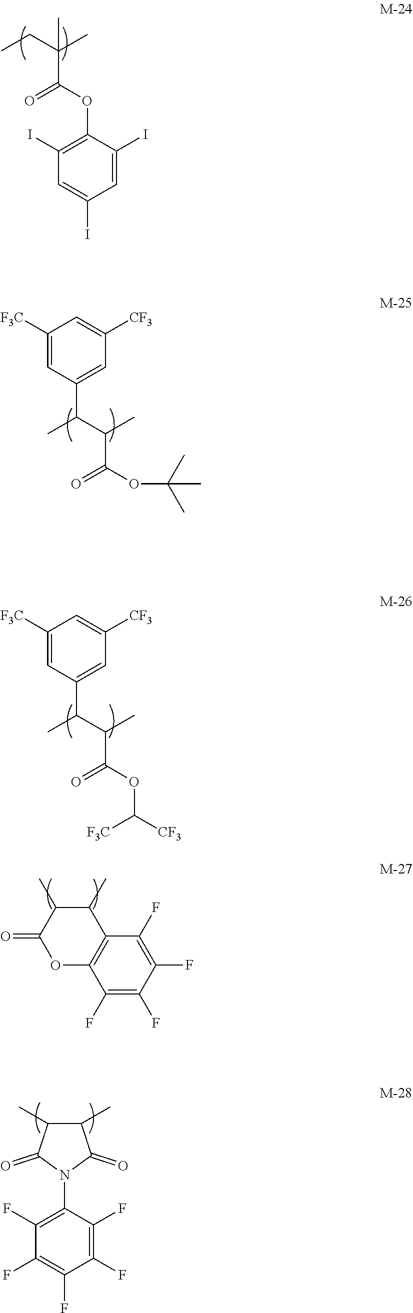

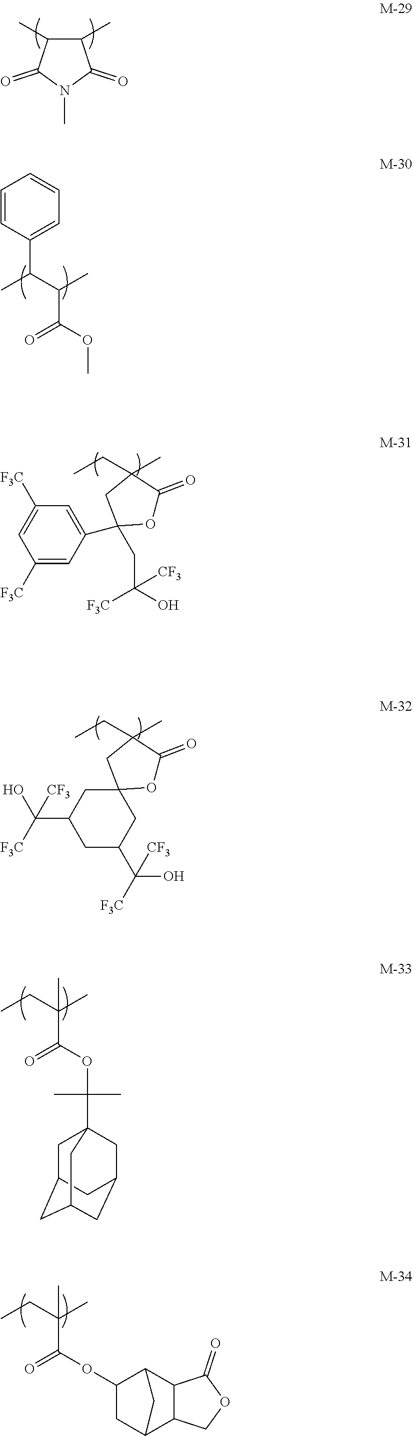

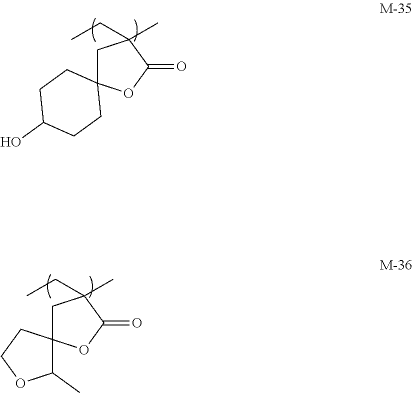

TABLE 1
Table 1 (First Table thereof)

| | | Weight- | |
|---|---|---|---|
| | | average | |
| | | molecular | |
| | | weight | Dis- |
| Polymer | Compositional ratio (mass ratio) | (Mw) | persity |
| P-1 | M-2/M-4/M-23 = 30/50/20 | 8,000 | 1.6 |
| P-2 | M-5/M-13/M-21 = 40/35/25 | 8,000 | 1.5 |
| P-3 | M-1/M-3/M-12 = 30/20/50 | 4,000 | 1.4 |
| P-4 | M-4/M-9/M-15/M-23 = 30/10/50/10 | 6,000 | 1.5 |
| P-5 | M-6/M-7/M-14/M-22 = 10/30/40/20 | 8,000 | 1.7 |
| P-6 | M-8/M-17/M-21 = 35/40/25 | 12,000 | 1.8 |
| P-7 | M-8/M-17/M-24 = 35/40/25 | 4,000 | 1.4 |
| P-8 | M-3/M-9/M-16/M-20 = 10/20/50/20 | 6,000 | 1.4 |
| P-9 | M-2/M-5/M-15 = 30/40/30 | 8,000 | 1.5 |
| P-10 | M-5/M-18 = 50/50 | 12,000 | 1.7 |
| P-11 | M-7/M-8/M-18/M-21 = 10/20/40/30 | 6,000 | 1.3 |
| P-12 | M-7/M-19/M-24 = 30/30/40 | 6,000 | 1.4 |
| P-13 | M-10/M-11 = 50/50 | 6,000 | 1.5 |
| P-14 | M-6/M-12/M-23 = 20/70/10 | 6,000 | 1.4 |
| P-15 | M-4/M-13/M-23 = 25/50/25 | 8,000 | 1.6 |
| P-16 | M-7/M-17/M-21 = 20/30/50 | 12,000 | 1.8 |
| P-17 | M-7/M-8/M-15/M-19/M-24 = 10/20/10/20/40 | 12,000 | 1.6 |
| P-18 | M-4/M-9/M-15/M-23 = 40/10/40/10 | 4,000 | 1.3 |
| P-19 | M-5/M-14 = 50/50 | 6,000 | 1.3 |
| P-20 | M-1/M-5/M-17/M-20 = 20/20/50/10 | 2,000 | 1.2 |
| P-21 | M-5/M-12/M-14/M-21 = 30/20/20/30 | 3,000 | 1.4 |
| P-22 | M-4/M-17/M-19/M-21 = 19/41/20/20 | 8,000 | 1.8 |
| P-23 | M-3/M-12/M-22 = 20/50/30 | 8,000 | 1.6 |
| P-24 | M-7/M-11/M-13/M-23 = 15/20/30/35 | 12,000 | 1.6 |
| P-25 | M-6//M-16/M-18/M-20/M-23 = 15/35/20/5/25 | 4,000 | 1.3 |
| P-26 | M-4/M-14/M-22 = 40/40/20 | 20,000 | 2.0 |
| P-27 | M-10/M-19/M-24 = 5/25/70 | 8,000 | 1.6 |
| P-28 | M-3/M-10/M-16/M-20 = 20/20/40/20 | 15,000 | 1.8 |
| P-29 | M-8/M-19/M-24 = 15/30/55 | 12,000 | 1.8 |
| P-30 | M-7/M-18/M-21 = 40/40/20 | 6,000 | 1.3 |
| P-31 | M-5/M-15/M-21 = 60/30/10 | 15,000 | 1.7 |
| P-32 | M-4/M-8/M-21 = 25/40/35 | 20,000 | 1.8 |
| P-33 | M-1/M-2/M-20 = 40/50/10 | 6,000 | 1.4 |
| P-34 | M-1/M-2/M-3 = 30/50/20 | 8,000 | 1.5 |
| P-35 | M-1/M-11 = 60/40 | 12,000 | 1.7 |
| P-36 | M-1/M-5/M-11 = 30/10/60 | 15,000 | 1.6 |
| P-37 | M-2/M-4/M-26 = 30/50/20 | 8,000 | 1.6 |
| P-38 | M-2/M-4/M-27 = 30/50/20 | 5,000 | 1.7 |
| P-39 | M-2/M-4/M-28 = 30/50/20 | 4,000 | 1.6 |
| P-40 | M-2/M-31/M-23 = 30/50/20 | 6,000 | 1.8 |
| P-41 | M-2/M-32/M-23 = 30/50/20 | 4,500 | 1.8 |
| P-42 | M-2/M-4/M-23/M-29 = 30/50/10/10 | 5,500 | 1.7 |
| P-43 | M-2/M-4/M-23/M-30 = 30/50/10/10 | 5,000 | 1.6 |
| P-44 | M-4/M-17/M-33/M-21 = 19/41/20/20 | 8,000 | 1.5 |
| P-45 | M-7/M-25/M-21 = 20/30/50 | 9,000 | 1.8 |
| P-46 | M-7/M-7/M-26 = 20/30/50 | 8,000 | 1.7 |
| P-47 | M-3/M-9/M-16/M-34 = 10/20/50/20 | 7,000 | 1.6 |
| P-48 | M-3/M-9/M-16/M-35 = 10/20/50/20 | 5,000 | 1.5 |
| P-49 | M-3/M-9/M-16/M-36 = 10/20/50/20 | 6,500 | 1.5 |

TABLE 2
Table 1 (Second Table thereof)

| | | Weight- | |
|---|---|---|---|
| | | average | |
| | | molecular | |
| | | weight | Dis- |
| Polymer | Compositional ratio (mass ratio) | (Mw) | persity |
| P-50 | M-3/M-9/M-16/M-34 = 10/20/50/20 | 7,000 | 1.6 |
| P-51 | M-3/M-9/M-16/M-35 = 10/20/50/20 | 5,000 | 1.5 |
| P-52 | M-3/M-9/M-16/M-36 = 10/20/50/20 | 6,500 | 1.5 |
| P-53 | M-1/M-2/M-4/M-20 = 20/30/40/10 | 6,000 | 1.4 |
| P-54 | M-3/M-9/M-11/M-29 = 40/15/30/15 | 8,000 | 1.5 |
| P-55 | M-2/M-3/M-4/M-32 = 40/20/20/20 | 12,000 | 1.7 |
| P-56 | M-1/M-17 = 50/50 | 6,000 | 1.3 |
| P-57 | M-4/M-11/M-20/M-32 = 35/30/20/15 | 6,000 | 1.4 |
| P-58 | M-3/M-9/M-17/M-35 = 30/20/35/15 | 6,000 | 1.5 |
| P-59 | M-4/M-9/M-11/M-29 = 40/10/30/20 | 6,000 | 1.4 |
| P-60 | M-2/M-3/M-9/M-32 = 30/20/20/30 | 8,000 | 1.6 |
| P-61 | M-4/M-9/M-17/M-29 = 40/10/40/10 | 12,000 | 1.8 |
| P-62 | M-4/M-11/M-35 = 50/35/15 | 12,000 | 1.6 |
| P-63 | M-3/M-32/M-33 = 30/30/40 | 4,000 | 1.3 |
| P-64 | M-4/M-11/M-17/M-20 = 25/25/25/25 | 6,000 | 1.3 |
| P-65 | M-1/M-4/M-17/M-32/M-33 = 10/20/20/30/20 | 5,500 | 1.7 |
| P-66 | M-1/M-2/M-29/M-32 = 10/40/10/40 | 5,000 | 1.6 |
| P-67 | M-2/M-4/M-9/M-17/M-29 = 25/40/10/15/10 | 8,000 | 1.5 |

[Cationic Moiety of Photoacid Generator]

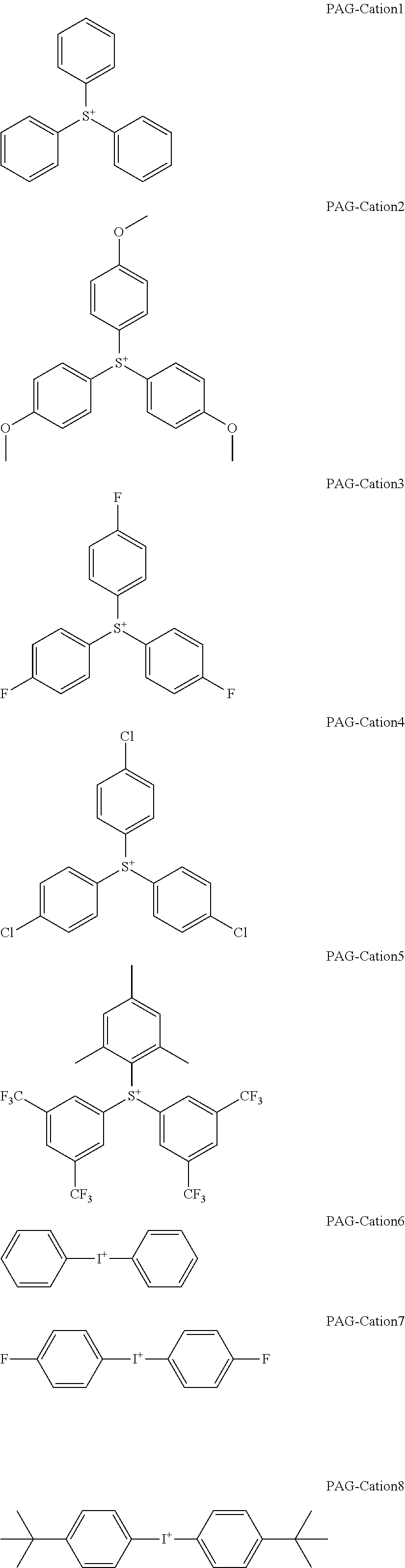

[Anionic Moiety of Photoacid Generator]

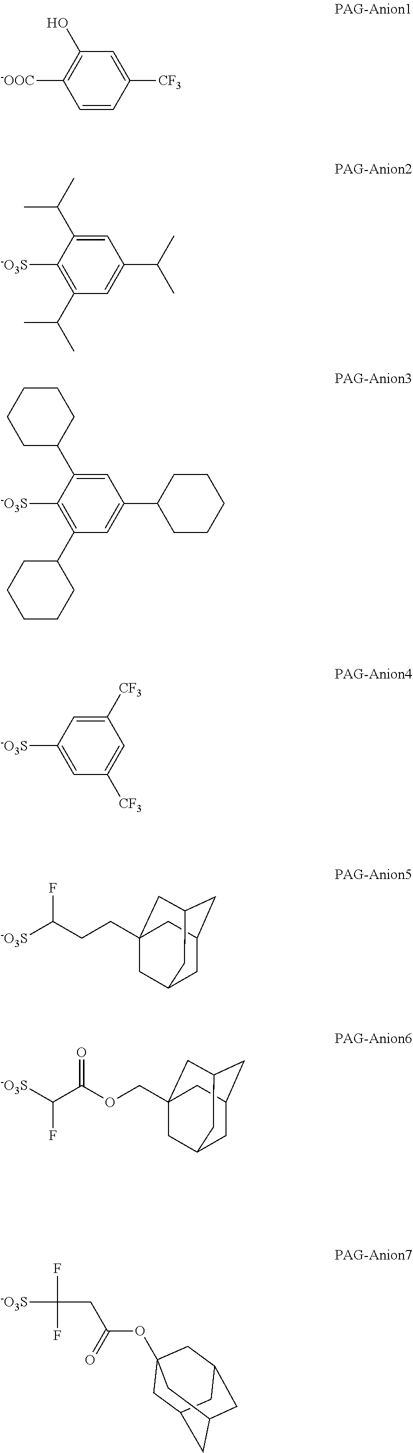

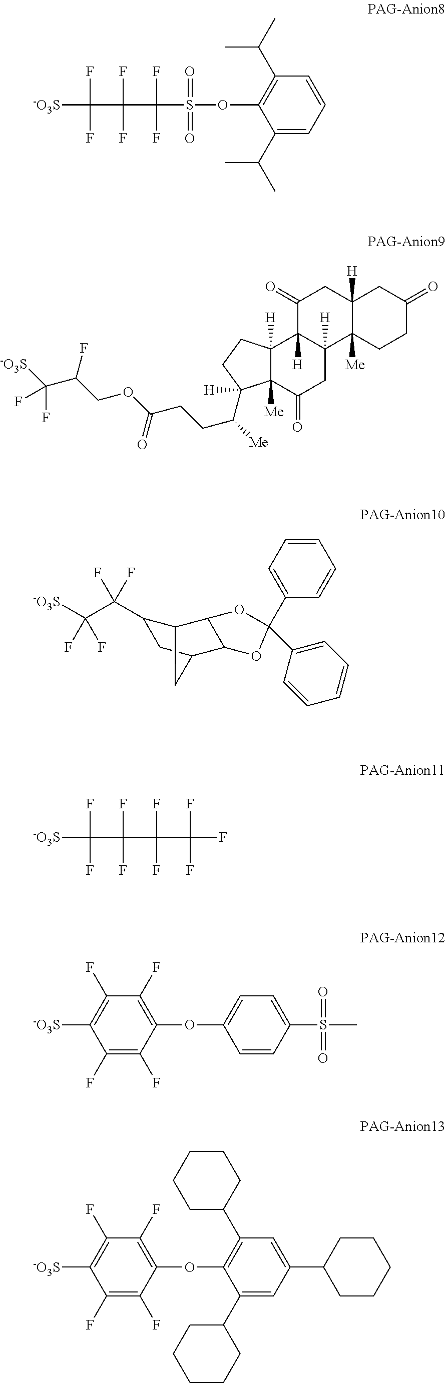

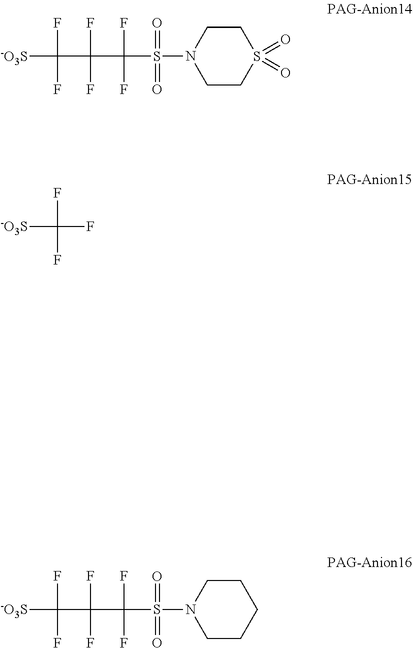

[Acid Diffusion Control Agent]

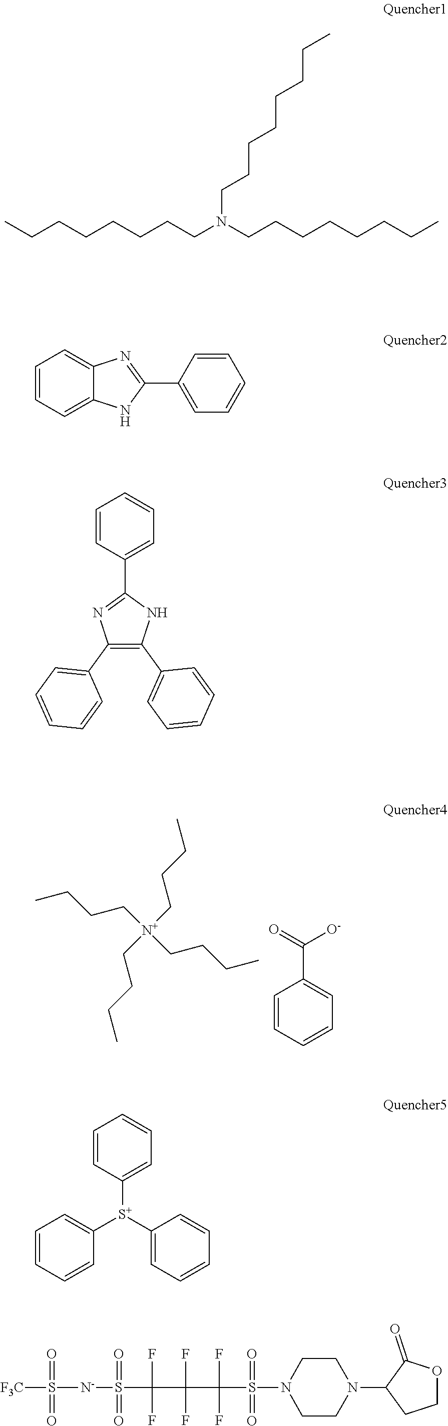

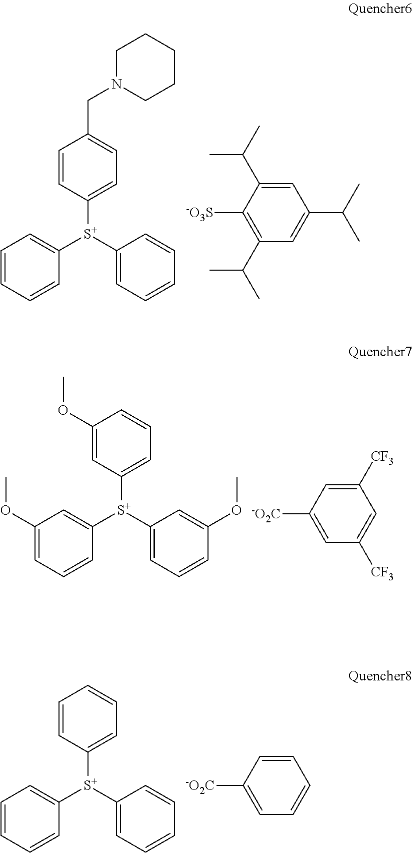

[Hydrophobic Resin]

In addition, the numerical value in the following Formulae represent % by mol of each repeating unit.

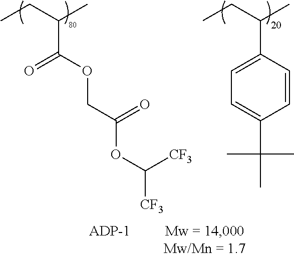

[Surfactant]
W-1: MEGAFACE F176 (manufactured by DIC Corporation; fluorine-based)
W-2: MEGAFACE R08 (manufactured by DIC Corporation; fluorine- and silicon-based)

[Solvent]
SL-1: Propylene glycol monomethyl ether acetate
SL-2: Propylene glycol monomethyl ether
SL-3: Ethyl lactate
SL-4: γ-butyrolactone
SL-5: cyclohexanone

[Developer]
D-1: 3.00% by mass of tetramethylamonium hydroxide aqueous solution
D-2: 2.38% by mass of tetramethylamonium hydroxide aqueous solution
D-3: 1.50% by mass of tetramethylamonium hydroxide aqueous solution
D-4: 1.00% by mass of tetramethylamonium hydroxide aqueous solution
D-5: 0.80% by mass of tetramethylamonium hydroxide aqueous solution
D-6: Butyl acetate
D-7: 3-methylbutyl acetate
D-8: 3-heptanone

[Underlayer Film]
UL-1: AL412 (manufactured by Brewer Science, Inc.)
UL-2: SHB-A940 (manufactured by Shin-Etsu Chemical Co., Ltd.)

[Preparation of Photosensitive Composition]

The materials were mixed at the concentration of solid contents and the compositions shown in Table 2 to prepare resist materials each of which was filtered through a polyethylene filter having a pore size of 0.03 μm to prepare a photosensitive composition.

The content (% by mass) of each component described in the following “Polymer” column, “Photoacid generator” column, “Acid diffusion control agent” column, “Added polymer” column, and “Surfactant” column represents the ratio of each component to the total solid content.

The “Solvent” column represents parts by mass of each solvent.

TABLE 2

| | Concen- | | | | | | | | |
|---|---|---|---|---|---|---|---|---|---|
| Photo- | tration | | | | | | | | |
| sensi- | of solid | Polymer | | Photoacid generator | | | Photoacid generator | | |
| tive | contents | | Content | | | Content | | | Content |
| compo- | (% by | | (% by | Cationic | Anionic | (% by | Cationic | Anionic | (% by |
| sition | mass) | Kind | mass) | moiety | moiety | mass) | moiety | moiety | mass) |

(First Table thereof)

| | | | | | | | | | |
|---|---|---|---|---|---|---|---|---|---|
| R-1 | 1.4 | P-1 | 74.0 | PAG-Cation1 | PAG-Anion3 | 15.0 | PAG-Cation1 | PAG-Anion12 | 10.0 |
| R-2 | 1.6 | P-2 | 79.2 | PAG-Cation8 | PAG-Anion7 | 20.0 | | | |
| R-3 | 1.2 | P-3 | 83.8 | PAG-Cation1 | PAG-Anion12 | 15.0 | | | |
| R-4 | 1.3 | P-4 | 71.9 | PAG-Cation3 | PAG-Anion14 | 26.0 | | | |
| R-5 | 1.6 | P-5 | 80.0 | PAG-Cation3 | PAG-Anion12 | 8.0 | PAG-Cation3 | PAG-Anion6 | 8.0 |
| R-6 | 1.4 | P-6 | 74.7 | PAG-Cation5 | PAG-Anion8 | 20.0 | | | |
| R-7 | 1.4 | P-7 | 80.7 | PAG-Cation7 | PAG-Anion13 | 13.0 | PAG-Cation7 | PAG-Anion7 | 3.0 |
| R-8 | 1.4 | P-8 | 69.5 | PAG-Cation1 | PAG-Anion3 | 12.0 | PAG-Cation5 | PAG-Anion12 | 9.0 |
| R-9 | 1.6 | P-9 | 84.3 | PAG-Cation5 | PAG-Anion13 | 14.0 | | | |
| R-10 | 1.5 | P-10 | 86.6 | PAG-Cation4 | PAG-Anion3 | 12.0 | | | |
| R-11 | 1.4 | P-11 | 77.6 | PAG-Cation6 | PAG-Anion13 | 20.0 | | | |
| R-12 | 1.6 | P-12 | 80.0 | PAG-Cation7 | PAG-Anion12 | 14.0 | | | |
| R-13 | 1.6 | P-13 | 72.0 | PAG-Cation6 | PAG-Anion3 | 20.0 | | | |
| R-14 | 1.4 | P-14 | 75.3 | PAG-Cation5 | PAG-Anion12 | 20.0 | | | |
| R-15 | 1.3 | P-15 | 76.0 | PAG-Cation5 | PAG-Anion13 | 18.0 | | | |
| R-16 | 1.9 | P-16 | 82.6 | PAG-Cation5 | PAG-Anion10 | 15.0 | | | |
| R-17 | 1.5 | P-17 | 80.0 | PAG-Cation7 | PAG-Anion14 | 12.0 | | | |
| R-18 | 1.4 | P-18 | 78.9 | PAG-Cation5 | PAG-Anion3 | 17.0 | | | |
| R-19 | 1.5 | P-19 | 76.5 | PAG-Cation1 | PAG-Anion14 | 15.0 | PAG-Cation1 | PAG-Anion1 | 6.0 |
| R-20 | 1.5 | P-20 | 76.2 | PAG-Cation2 | PAG-Anion13 | 22.0 | | | |
| R-21 | 1.6 | P-21 | 78.4 | PAG-Cation2 | PAG-Anion8 | 20.0 | | | |
| R-22 | 1.3 | P-22 | 83.8 | PAG-Cation3 | PAG-Anion16 | 15.0 | | | |
| R-23 | 1.4 | P-23 | 75.0 | PAG-Cation4 | PAG-Anion7 | 5.0 | PAG-Cation4 | PAG-Anion5 | 10.0 |
| R-24 | 2.3 | P-24 | 73.0 | PAG-Cation5 | PAG-Anion13 | 25.0 | | | |
| R-25 | 2.1 | P-25 | 72.4 | PAG-Cation4 | PAG-Anion7 | 20.0 | | | |
| R-26 | 1.5 | P-26 | 78.4 | PAG-Cation3 | PAG-Anion15 | 20.0 | | | |

(Second Table thereof)

| | | | | | | | | | |
|---|---|---|---|---|---|---|---|---|---|
| R-27 | 1.5 | P-27 | 88.2 | PAG-Cation7 | PAG-Anion4 | 11.0 | | | |
| R-28 | 2.1 | P-28 | 78.4 | PAG-Cation5 | PAG-Anion9 | 20.0 | | | |
| R-29 | 1.8 | P-29 | 92.0 | PAG-Cation7 | PAG-Anion13 | 6.0 | | | |
| R-30 | 1.3 | P-30 | 89.2 | PAG-Cation8 | PAG-Anion14 | 10.0 | | | |
| R-31 | 1.4 | P-31 | 62.2 | PAG-Cation4 | PAG-Anion3 | 20.0 | PAG-Cation5 | PAG-Anion | 15.0 |
| | | | | | | | | 12 | |
| R-32 | 1.5 | P-32 | 56.8 | PAG-Cation5 | PAG-Anion8 | 40.0 | | | |
| R-33 | 1.4 | P-33 | 93.5 | PAG-Cation2 | PAG-Anion8 | 6.0 | | | |
| R-34 | 1.6 | P-34 | 89.2 | PAG-Cation1 | PAG-Anion4 | 10.0 | | | |
| R-35 | 1.5 | P-35 | 79.8 | PAG-Cation1 | PAG-Anion11 | 18.0 | | | |
| R-36 | 1.6 | P-36 | 54.9 | PAG-Cation2 | PAG-Anion3 | 40.0 | | | |
| R-37 | 1.4 | P-40 | 74.0 | PAG-Cation5 | PAG-Anion13 | 15.0 | PAG-Cation5 | PAG-Anion | 10.0 |
| | | | | | | | | 12 | |
| R-38 | 1.4 | P-41 | 74.0 | PAG-Cation1 | PAG-Anion3 | 15.0 | PAG-Cation1 | PAG-Anion | 10.0 |
| | | | | | | | | 12 | |
| R-39 | 1.4 | P-42 | 74.0 | PAG-Cation1 | PAG-Anion3 | 15.0 | PAG-Cation1 | PAG-Anion | 10.0 |
| | | | | | | | | 12 | |
| R-40 | 1.4 | P-43 | 74.0 | PAG-Cation5 | PAG-Anion3 | 15.0 | PAG-Cation5 | PAG-Anion | 10.0 |
| | | | | | | | | 12 | |
| R-41 | 1.4 | P-44 | 74.0 | PAG-Cation1 | PAG-Anion3 | 15.0 | PAG-Cation1 | PAG-Anion | 10.0 |
| | | | | | | | | 12 | |
| R-42 | 1.4 | P-45 | 74.0 | PAG-Cation1 | PAG-Anion3 | 15.0 | PAG-Cation1 | PAG-Anion | 10.0 |
| | | | | | | | | 12 | |
| R-43 | 1.4 | P-46 | 74.0 | PAG-Cation1 | PAG-Anion3 | 15.0 | PAG-Cation1 | PAG-Anion | 10.0 |
| | | | | | | | | 12 | |
| R-44 | 1.3 | P-47 | 83.8 | PAG-Cation3 | PAG-Anion16 | 15.0 | | | |
| R-45 | 1.9 | P-48 | 82.6 | PAG-Cation5 | PAG-Anion10 | 15.0 | | | |
| R-46 | 1.9 | P-49 | 82.6 | PAG-Cation5 | PAG-Anion10 | 15.0 | | | |
| R-47 | 1.4 | P-50 | 69.5 | PAG-Cation1 | PAG-Anion3 | 12.0 | PAG-Cation5 | PAG-Anion | 9.0 |
| | | | | | | | | 12 | |
| R-48 | 1.4 | P-51 | 69.5 | PAG-Cation1 | PAG-Anion3 | 12.0 | PAG-Cation5 | PAG-Anion | 9.0 |
| | | | | | | | | 12 | |
| R-49 | 1.4 | P-52 | 69.5 | PAG-Cation1 | PAG-Anion3 | 12.0 | PAG-Cation5 | PAG-Anion | 9.0 |
| | | | | | | | | 12 | |

(Third Table thereof)

| | | | | | | | | | |
|---|---|---|---|---|---|---|---|---|---|
| R-50 | 1.4 | P-50 | 69.5 | PAG-Cation1 | PAG-Anion3 | 12.0 | PAG-Cation5 | PAG-Anion | 9.0 |
| | | | | | | | | 12 | |
| R-51 | 1.4 | P-51 | 69.5 | PAG-Cation1 | PAG-Anion3 | 12.0 | PAG-Cation5 | PAG-Anion | 9.0 |
| | | | | | | | | 12 | |
| R-52 | 1.4 | P-52 | 69.5 | PAG-Cation1 | PAG-Anion3 | 12.0 | PAG-Cation5 | PAG-Anion | 9.0 |
| | | | | | | | | 12 | |
| R-53 | 1.4 | P-53 | 81.0 | PAG-Cation2 | PAG-Anion14 | 15.0 | | | |
| R-54 | 1.6 | P-54 | 80.0 | PAG-Cation1 | PAG-Anion3 | 5.0 | PAG-Cation1 | PAG-Anion | 8.0 |
| | | | | | | | | 11 | |
| R-55 | 1.5 | P-55 | 81.0 | PAG-Cation1 | PAG-Anion3 | 8.0 | PAG-Cation2 | PAG-Anion | 8.0 |
| | | | | | | | | 10 | |
| R-56 | 1.4 | P-56 | 88.1 | PAG-Cation1 | PAG-Anion7 | 10.0 | | | |
| R-57 | 1.6 | P-57 | 86.4 | PAG-Cation2 | PAG-Anion13 | 11.0 | | | |
| R-58 | 1.6 | P-58 | 77.0 | PAG-Cation1 | PAG-Anion3 | 11.0 | PAG-Cation1 | PAG-Anion | 6.0 |
| | | | | | | | | 7 | |
| R-59 | 1.4 | P-59 | 78.5 | PAG-Cation1 | PAG-Anion3 | 12.0 | PAG-Cation1 | PAG-Anion | 5.0 |
| | | | | | | | | 7 | |
| R-60 | 1.3 | P-60 | 78.0 | PAG-Cation1 | PAG-Anion14 | 18.0 | | | |
| R-61 | 1.9 | P-61 | 81.5 | PAG-Cation1 | PAG-Anion3 | 6.0 | PAG-Cation1 | PAG-Anion | 7.0 |
| | | | | | | | | 7 | |
| R-62 | 1.5 | P-62 | 86.0 | PAG-Cation2 | PAG-Anion5 | 8.0 | PAG-Cation2 | PAG-Anion | 5.0 |
| | | | | | | | | 10 | |
| R-63 | 1.4 | P-63 | 92.6 | PAG-Cation1 | PAG-Anion13 | 6.0 | | | |
| R-64 | 1.5 | P-64 | 73.0 | PAG-Cation1 | PAG-Anion3 | 5.0 | PAG-Cation1 | PAG-Anion | 20.0 |
| | | | | | | | | 6 | |
| R-65 | 1.5 | P-65 | 83.0 | PAG-Cation1 | PAG-Anion5 | 5.0 | PAG-Cation1 | PAG-Anion | 8.0 |
| | | | | | | | | 10 | |
| R-66 | 1.6 | P-66 | 73.0 | PAG-Cation1 | PAG-Anion10 | 23.0 | | | |
| R-67 | 1.3 | P-67 | 87.0 | PAG-Cation1 | PAG-Anion13 | 10.0 | | | |

| Photo- | Acid diffusion control | | Added | Surfac- | |
|---|---|---|---|---|---|
| sensi- | agent | | polymer | tant | |
| tive | | Content | (Content: | (Content: | |
| compo- | | % by | % by | (% by | |
| sition | Kind | mass) | mass) | mass) | Solvent |
| (First Table thereof) | | | | | |
| R-1 | Quencher2 | 1.0 | — | — | SL-1/SL-2/SL-3 = |
| | | | | | 30/20/50 |
| R-2 | Quencher3 | 0.8 | — | — | SL-1/SL-3 = 60/40 |
| R-3 | Quencher1 | 1.2 | — | — | SL-1/SL-2 = 60/40 |
| R-4 | Quencher4 | 2.1 | — | — | SL-1/SL-2 = 90/10 |
| R-5 | Quencher5 | 4.0 | — | — | SL-1 = 100 |
| R-6 | Quencher6 | 5.0 | — | W-1(0.3) | SL-3 = 100 |
| R-7 | Quencher3 | 1.3 | ADP-1(2.0) | — | SL-1 = 100 |
| R-8 | Quencher5 | 9.0 | — | W-2(0.5) | SL-1/SL-3 = 80/20 |
| R-9 | Quencher3 | 1.7 | — | — | SL-1/SL-3 = 80/20 |
| R-10 | Quencher4 | 1.4 | — | — | SL-1/SL-3 = 90/10 |
| R-11 | Quencher4 | 2.4 | — | — | SL-1/SL-2/SL-3 = |
| | | | | | 30/20/50 |
| R-12 | Quencher6 | 6.0 | — | — | SL-1/SL-2/SL-3 = |
| | | | | | 60/20/20 |
| R-13 | Quencher6 | 8.0 | — | — | SL-1/SL-2 = 70/30 |
| R-14 | Quencher4 | 3.2 | ADP-1(1.5) | — | SL-1/SL-2 = 90/10 |
| R-15 | Quencher5 | 6.0 | — | — | SL-1/SL-2 = 80/20 |
| R-16 | Quencher3 | 2.4 | — | — | SL-3/SL-4 = 95/5 |
| R-17 | Quencher5 | 8.0 | — | — | SL-1/SL-4 = 90/10 |
| R-18 | Quencher4 | 4.1 | — | — | SL-1/SL-2 = 70/30 |
| R-19 | Quencher5 | 2.5 | — | — | SL-1/SL-3 = 80/20 |
| R-20 | Quencher3 | 1.8 | — | — | SL-1 = 100 |
| R-21 | Quencher1 | 1.6 | — | — | SL-1/SL-3/SL-4 = |
| | | | | | 30/90/10 |
| R-22 | Quencher4 | 1.2 | — | — | SL-1/SL-3/SL-5 = |
| | | | | | 30/40/30 |
| R-23 | Quencher5 | 10.0 | — | — | SL-1/SL-2 = 90/10 |
| R-24 | Quencher4 | 2.0 | — | — | SL-1/SL-2 = 90/10 |
| R-25 | Quencher3/ | 1.6/ | — | — | SL-1/SL-2 = 90/10 |
| | Quencher6 | 6.0 | | | |
| R-26 | Quencher4 | 1.6 | — | — | SL-1/SL-2/SL-3 = |
| | | | | | 30/20/50 |
| (Second Table thereof) | | | | | |
| R-27 | Quencher 3 | 0.8 | — | — | SL-1/SL-3 = 60/40 |
| R-28 | Quencher 3 | 1.6 | — | — | SL-1/SL-2 = 60/40 |
| R-29 | Quencher 5 | 2.0 | — | — | SL-1/SL-2 = 90/10 |
| R-30 | Quencher 3 | 0.8 | — | — | SL-1/SL-2/SL-3 = |
| | | | | | 30/20/50 |
| R-31 | Quencher | 2.8 | — | — | SL-1/SL-3 = 60/40 |
| | 4 | | | | |
| R-32 | Quencher | 3.2 | — | — | SL-1/SL-2 = 60/40 |
| | 4 | | | | |
| R-33 | Quencher | 0.5 | — | — | SL-1 = 100 |
| | 3 | | | | |
| R-34 | Quencher | 0.8 | — | — | SL-3 = 100 |
| | 4 | | | | |
| R-35 | Quencher | 2.2 | — | — | SL-1 = 100 |
| | 3 | | | | |
| R-36 | Quencher | 4.8 | — | W-1(0.3 | SL-3/SL-5 = 90/10 |
| | 4 | | | wt %) | |
| R-37 | Quencher | 1.0 | — | — | SL-1/SL-2/SL-3 = |
| | 2 | | | | 30/20/50 |
| R-38 | Quencher | 1.0 | — | — | SL-1/SL-2/SL-3 = |
| | 2 | | | | 30/20/50 |
| R-39 | Quencher | 1.0 | — | — | SL-1/SL-2/SL-3 = |
| | 2 | | | | 30/20/50 |
| R-40 | Quencher | 1.0 | — | — | SL-1/SL-2/SL-3 = |
| | 2 | | | | 30/20/50 |
| R-41 | Quencher | 1.0 | — | — | SL-1/SL-2/SL-3 = |
| | 2 | | | | 30/20/50 |
| R-42 | Quencher | 1.0 | — | — | SL-1/SL-2/SL-3 = |
| | 2 | | | | 30/20/50 |
| R-43 | Quencher | 1.0 | — | — | SL-1/SL-2/SL-3 = |
| | 2 | | | | 30/20/50 |
| R-44 | Quencher | 1.2 | — | — | SL-1/SL-3/SL-5 = |
| | 4 | | | | 30/40/30 |
| R-45 | Quencher | 2.4 | — | — | SL-3/SL-4 = 95/5 |
| | 3 | | | | |
| R-46 | Quencher | 2.4 | — | — | SL-3/SL-4 = 95/5 |
| | 3 | | | | |
| R-47 | Quencher | 9.0 | — | W-2(0.5) | SL-1/SL-3 = 80/20 |
| | 5 | | | | |
| R-48 | Quencher | 9.0 | — | W-2(0.5) | SL-1/SL-3 = 80/20 |
| | 5 | | | | |
| R-49 | Quencher | 9.0 | — | W-2(0.5) | SL-1/SL-3 = 80/20 |
| | 5 | | | | |
| (Third Table thereof) | | | | | |
| R-50 | Quencher | 9.0 | — | W-2(0.5) | SL-1/SL-3 = 80/20 |
| | 5 | | | | |
| R-51 | Quencher | 9.0 | — | W-2(0.5) | SL-1/SL-3 = 80/20 |
| | 5 | | | | |
| R-52 | Quencher | 9.0 | — | W-2(0.5) | SL-1/SL-3 = 80/20 |
| | 5 | | | | |
| R-53 | Quencher | 4.0 | — | — | SL-1/SL-3 = 80/20 |
| | 4 | | | | |
| R-54 | Quencher | 7.0 | — | — | SL-1/SL-3 = 80/20 |
| | 7 | | | | |
| R-55 | Quencher | 3.0 | — | — | SL-1/SL-3 = 90/10 |
| | 4 | | | | |
| R-56 | Quencher | 1.9 | — | — | SL-1/SL-2/SL-3 = |
| | 2 | | | | 30/20/50 |
| R-57 | Quencher | 2.1 | — | W-2(0.5) | SL-1/SL-2/SL-3 = |
| | 4 | | | | 60/20/20 |
| R-58 | Quencher | 6.0 | — | — | SL-1/SL-2 = 70/30 |
| | 7 | | | | |
| R-59 | Quencher | 3.0 | ADP- | — | SL-1/SL-3 = 90/10 |
| | 8 | | 1(1.5) | | |
| R-60 | Quencher | 4.0 | — | — | SL-1/SL-2 = 80/20 |
| | 4 | | | | |
| R-61 | Quencher | 5.0 | — | W-2(0.5) | SL-3/SL-4 = 95/5 |
| | 7 | | | | |
| R-62 | Quencher | 1.0 | — | — | SL-1/SL-4 = 90/10 |
| | 4 | | | | |
| R-63 | Quencher | 1.4 | — | — | SL-1/SL-2 = 70/30 |
| | 4 | | | | |
| R-64 | Quencher | 2.0 | — | — | SL-1/SL-3 = 80/20 |
| | 4 | | | | |
| R-65 | Quencher | 4.0 | — | — | SL-1 = 100 |
| | 8 | | | | |
| R-66 | Quencher | 4.0 | — | — | SL-1/SL-3/SL-4 = |
| | 4 | | | | 30/90/10 |
| R-67 | Quencher | 3.0 | — | — | SL-1/SL-3/SL-5 = |
| | 1 | | | | 30/40/30 |

[Preparation of Composition for Forming Pattern Reversal Film]

Tetraethoxysilane (TEOS) (8.93 g), methyltriethoxysilane (METEOS) (17.83 g), and acetone (40.14 g) were placed in the flask. A cooling pipe was attached to the flask. Furthermore, a hydrochloric acid aqueous solution (0.01 mol/L) (8.50 g) was slowly added dropwise to the flask at room temperature, and the obtained solution was stirred for several minutes.

Then, this flask was set in an oil bath, and the liquid in the flask was allowed to undergo a reaction in an environment of 85° C. for 4 hours. After completion of the reaction, the flask containing the reaction solution was left to be cooled and then was set in an evaporator to remove ethanol produced during the reaction, and as a result, a reaction product (polysiloxane) was obtained. Furthermore, acetone was substituted with 4-methyl-2-pentanol using the evaporator.

As a result of measurement by a calcination method, the solid content in the obtained product was 25% by mass. The weight-average molecular weight (Mw) of the obtained product S-1 (solid content) was 1,400.

The weight-average molecular weight of the product S-1 synthesized to obtain a pattern reversal film forming composition was measured by the GPC method under the following conditions.

GPC apparatus: HLC-8220GPC (manufactured by Tosoh Corporation), GPC column: Shodex (registered trademark) KF803L, KF802, KF801 (manufactured by Showa Denko K.K.), Column temperature: 40° C., Eluent: THF, Flow rate: 1.0 mL/min, Standard sample: polystyrene (manufactured by Showa Denko K.K.).

The product S-1 (polysiloxane) (5 g) was dissolved in 4-methyl-2-pentanol (30 g). Benzyltriethylammonium chloride (0.375 g), maleic acid (0.0375 g), and a surfactant (MEGAFACE R-30, manufactured by DIC Corporation) (0.625 g) were added to each of the obtained solutions. Each of these solutions was filtered with a filter having a pore size of 0.1 μm, and the obtained filtrate was used as a pattern reversal film forming composition.

### Examples 1 to 63 and Comparative Examples 1 to 4

The composition shown in Table 3 was applied to a silicon wafer (12 inches) on which the underlayer film (base film, thickness 200 nm) described in Table 3 was formed, and the coating film was heated under the bake conditions described in (Resist application conditions) to form a resist film having a film thickness shown in Table 3. As a result, a silicon wafer having the resist film was obtained.

Pattern irradiation was performed on the silicon wafer having the obtained resist film by using an EUV exposure apparatus (Micro Exposure Tool, NA0.3, Quadrupol, Outer Sigma 0.68, Inner Sigma 0.36, manufactured by Exitech Corporation). As the reticle, a mask having a line size=20 nm and line:space=1:1 was used.

Then, after baking (Post Exposure Bake (PEB)) under the conditions shown in Table 3 below, development was carried out by puddling developers shown in Table 3 below for 30 seconds, and then the pattern reversal film forming composition was applied to the resist pattern formed. Thereafter, the silicon wafer coated with the pattern reversal film forming composition was spin-dried at 1500 rpm for 60 seconds and dried on a hot plate at 110° C. for one minute to form a pattern reversal film.

Next, by using RIE-10NR (manufactured by SAMCO Inc.) as a dry etching apparatus, the etch-back was performed on the pattern reversal film under the conditions of CF₄/Ar=50/200 sccm, 15 Pa, and 200 W to expose a surface of the resist pattern. Next, dry etching was performed under the conditions of O₂/N₂=10/20 sccm, 1 Pa, and 300 W to remove the resist pattern, and as a result, a reversed pattern was obtained. Thereafter, dry etching was performed under the conditions of CF₄/Ar=50/200 sccm, 15 Pa, and 200 W with the obtained reversed pattern as an etching mask, patterning was carried out on the underlayer film.

<Evaluation>

The following evaluation was performed on the resist pattern formed as described above.

[A value]

The following A value was calculated for atoms in the components derived from the total solid content, which are included in the composition.

A=([H]×0.04+[C]×1.0+[N]×2.1+[O]×3.6+[F]×5.6+[S]×0.04+[I]×39.5)/([H]×1+[C]×12+[N]×14+[O]×16+[F]×19+[S]×32+[I]×127). General Expression (1):

The above [H], [C], [N], [O], [F], [S], and [I] were calculated from the structures and contents of the components included in the photosensitive composition.

[Content of Acid Group]

In a case where an acid group has an acid dissociation constant (pKa) of 13 or less, the density (mmol/g) of the acid group included in 1 g of a polymer was calculated. In a case where there are plural corresponding acid groups, the density of the total acid group was calculated. Marvinsketch (Chem Axon) was used for the calculation of pKa.

[LER]

In observation of a line and space resist pattern resolved at the optimum exposure amount in the sensitivity evaluation, in a case where the pattern is observed from the top using a length-measuring scanning electron microscope (SEM (CG-4100 manufactured by Hitachi High-Tech Corporation)), a distance from the center of the pattern to the edge was observed at any point, and the measurement variation thereof was evaluated by 3a. The smaller the value, the better the performance. The evaluation is carried out in four stages, and 3 or higher is preferable.
4: LER is 3.0 or less.
3: LER is more than 3.0 and 4.0 or less.
2: LER is more than 4.0.
1: The target pattern is not resolved (collapse).

[Embedability of Pattern Reversal Film Forming Composition]

After the pattern reversal film is formed, the cross-section of the obtained pattern reversal film is observed by SEM (S-4800 manufactured by Hitachi High-Tech Corporation), and voids which are presumed to be caused by bubbles or uniform in height of the pattern reversal film was evaluated. The evaluation is carried out in four stages, and 3 or higher is preferable. The height of the pattern reversal film corresponds, in other words, to the thickness of the pattern reversal film, and the uniform in height can be said to be uniform in thickness.
4: No voids are seen, and the height of the pattern reversal film is uniform.
3: No void is seen, but the height of the pattern reversal film varies slightly.
2: A few voids are seen.
1: Voids are seen, and the height of the pattern reversal film varies.

[Removal Selectivity of Resist Pattern]

<Dry Etching Rate of Resist Film>

The composition shown in Table 3 was applied to a silicon wafer (12 inches) on which the underlayer film (thickness 200 nm) described in Table 3 was formed, and the coating film was heated under the bake conditions described in (Resist application conditions) to form a resist film having a film thickness shown in Table 3. This operation was repeated to thicken the resist, and then the obtained resist film was subjected to dry-etching under the conditions of O₂/N₂=10/20 sccm, 1 Pa, and 300 W to calculate a dry etching rate (film thickness reduction rate per unit time). Then, the calculated value was compared with the dry etching rate of the resist film obtained from the composition of Comparative Example 1.

<Residue after Performing Dry Etching on Reversed Pattern>

Etch-back processing was performed on the pattern reversal film of the line and space, dry etching was then performed under the conditions of O₂/N₂=10/20 sccm, 1 Pa, 300 W, and 5 seconds to remove the resist pattern, and as a result, a reversed pattern was obtained. The cross section of the obtained reversed pattern was observed by SEM (S-4800 manufactured by Hitachi High-Tech Corporation), and the presence or absence of roughness and residue between patterns of the reversed pattern was observed.

From the above evaluation, removal selectivity of a resist pattern was evaluated. The evaluation is carried out in four stages, and 3 or higher is preferable.
4: The dry etching rate of the resist film was 20% or higher faster than the dry etching rate of the resist film obtained from the composition of Comparative Example 1, and neither roughness nor residue was observed between patterns of the reversed pattern.
3: The dry etching rate of the resist film was 5% or higher and lower than 20% faster than the dry etching rate of the resist film obtained from the composition of Comparative Example 1, and neither roughness nor residue was observed between patterns of the reversed pattern.
2: The dry etching rate of the resist film has few changes (less than 5%) or was slower than the dry etching rate of the resist film obtained from the composition of Comparative Example 1, and a little roughness or residue was observed between reversed patterns of the reversed pattern.
1: The dry etching rate of the resist film has few changes (less than 5%) or was slower than the dry etching rate of the resist film obtained from the composition of Comparative Example 1, and roughness or residue was notably observed between reversed patterns of the reversed pattern.

TABLE 3

| | | | | Resist characteristic value | | | | | | | | |
|---|---|---|---|---|---|---|---|---|---|---|---|---|
| | | | | | | Amount of | | | | Evaluation result | | |
| | | | | | | photoacid | | | | | Embed- | Removal |
| Resist application conditions | | | | | Volume of | generator | Content | | | | ability of a | selec- |
| | | Film | | | generated | (Content: | of acid | | | | pattern | tivity of |
| Compo- | Base | thickness | | A | acid | % by | group | PEB | Devel- | | reversal | resist |
| sition | film | [nm] | Bake | Value | (Å³) | mass) | [mmol/g] | condition | oper | LER | film | pattern |

(First Table thereof)

| | | | | | | | | | | | | | |
|---|---|---|---|---|---|---|---|---|---|---|---|---|---|
| Exam- | R-1 | UL-1 | 50 | 100° C./60 | 0.15 | 437/257 | 25 | 2.00 | 120° C./60 | D-2 | 4 | 4 | 4 |
| ple 1 | | | | seconds | | | | | seconds | | | | |
| Exam- | R-2 | UL-1 | 55 | 120° C./60 | 0.18 | 271 | 20 | 1.62 | 90° C./60 | D-2 | 4 | 4 | 4 |
| ple 2 | | | | seconds | | | | | seconds | | | | |
| Exam- | R-3 | UL-1 | 45 | 100° C./60 | 0.14 | 257 | 15 | 3.24 | 90° C./60 | D-2 | 3 | 4 | 3 |
| ple 3 | | | | seconds | | | | | seconds | | | | |
| Exam- | R-4 | UL-1 | 50 | 90° C./60 | 0.17 | 252 | 26 | 2.67 | 105° C./30 | D-4 | 3 | 4 | 4 |
| ple 4 | | | | seconds | | | | | seconds | | | | |
| Exam- | R-5 | UL-2 | 55 | 100° C./60 | 0.17 | 257/270 | 16 | 1.90 | 100° C./50 | D-2 | 4 | 4 | 4 |
| ple 5 | | | | seconds | | | | | seconds | | | | |
| Exam- | R-6 | UL-2 | 50 | 100° C./45 | 0.20 | 347 | 20 | 0.94 | 120° C./60 | D-1 | 4 | 4 | 4 |
| ple 6 | | | | seconds | | | | | seconds | | | | |
| Exam- | R-7 | UL-1 | 55 | 120° C./60 | 0.22 | 585/270 | 16 | 0.94 | 120° C./60 | D-2 | 4 | 4 | 4 |
| ple 7 | | | | seconds | | | | | seconds | | | | |
| Exam- | R-8 | UL-1 | 50 | 100° C./60 | 0.14 | 437/257 | 21 | 3.31 | 110° C./60 | D-2 | 3 | 4 | 3 |
| ple 8 | | | | seconds | | | | | seconds | | | | |
| Exam- | R-9 | UL-1 | 55 | 90° C./60 | 0.16 | 585 | 14 | 1.62 | 100° C./60 | D-2 | 4 | 4 | 4 |
| ple 9 | | | | seconds | | | | | seconds | | | | |
| Exam- | R-10 | UL-1 | 55 | 100° C./60 | 0.18 | 437 | 12 | 2.02 | 120° C./45 | D-3 | 4 | 4 | 4 |
| ple 10 | | | | seconds | | | | | seconds | | | | |
| Exam- | R-11 | UL-1 | 50 | 100° C./60 | 0.20 | 585 | 20 | 1.00 | 100° C./60 | D-2 | 4 | 4 | 4 |
| ple 11 | | | | seconds | | | | | seconds | | | | |
| Exam- | R-12 | UL-2 | 55 | 120° C./60 | 0.21 | 257 | 14 | 1.37 | 100° C./60 | D-2 | 3 | 4 | 4 |
| ple 12 | | | | seconds | | | | | seconds | | | | |
| Exam- | R-13 | UL-2 | 50 | 100° C./50 | 0.14 | 437 | 20 | 3.03 | 120° C./60 | D-5 | 3 | 4 | 3 |
| ple 13 | | | | seconds | | | | | seconds | | | | |
| Exam- | R-I4 | UL-1 | 50 | 90° C./60 | 0.17 | 257 | 20 | 1.04 | 90° C./60 | D-2 | 3 | 4 | 4 |
| ple 14 | | | | seconds | | | | | seconds | | | | |
| Exam- | R-15 | UL-1 | 45 | 100° C./60 | 0.17 | 585 | 18 | 1.00 | 105° C./60 | D-2 | 4 | 4 | 4 |
| ple 15 | | | | seconds | | | | | seconds | | | | |
| Exam- | R-16 | UL-1 | 60 | 100° C./60 | 0.20 | 354 | 15 | 0.92 | 100° C./60 | D-2 | 4 | 4 | 4 |
| ple 16 | | | | seconds | | | | | seconds | | | | |
| Exam- | R-17 | UL-1 | 55 | 120° C./60 | 0.22 | 252 | 12 | 1.00 | 90° C./60 | D-3 | 3 | 4 | 4 |
| ple 17 | | | | seconds | | | | | seconds | | | | |
| Exam- | R-18 | UL-2 | 50 | 100° C./60 | 0.17 | 437 | 17 | 3.07 | 110° C./60 | D-2 | 4 | 4 | 4 |
| ple 18 | | | | seconds | | | | | seconds | | | | |
| Exam- | R-19 | UL-1 | 50 | 90° C./60 | 0.17 | 252/138 | 21 | 2.02 | 105° C./60 | D-2 | 3 | 4 | 4 |
| ple 19 | | | | seconds | | | | | seconds | | | | |
| Exam- | R-20 | UL-1 | 50 | 100° C./60 | 0.16 | 585 | 22 | 2.47 | 100° C./60 | D-2 | 4 | 4 | 4 |
| ple 20 | | | | seconds | | | | | seconds | | | | |
| Exam- | R-21 | UL-1 | 55 | 100° C./60 | 0.18 | 347 | 20 | 1.21 | 90° C./60 | D-2 | 4 | 4 | 4 |
| ple 21 | | | | seconds | | | | | seconds | | | | |
| Exam- | R-22 | UL-2 | 50 | 120° C./30 | 0.20 | 244 | 15 | 0.76 | 105° C./30 | D-2 | 3 | 4 | 3 |
| ple 22 | | | | seconds | | | | | seconds | | | | |
| Exam- | R-23 | UL-1 | 50 | 100° C./60 | 0.16 | 271/266 | 15 | 0.74 | 100° C./60 | D-2 | 3 | 4 | 3 |
| ple 23 | | | | seconds | | | | | seconds | | | | |
| Exam- | R-24 | UL-1 | 65 | 90° C./60 | 0.16 | 585 | 25 | 0.69 | 90° C./60 | D-2 | 3 | 4 | 3 |
| ple 24 | | | | seconds | | | | | seconds | | | | |
| Exam- | R-25 | UL-1 | 65 | 100° C./60 | 0.16 | 271 | 20 | 0.78 | 100° C./60 | D-2 | 3 | 4 | 3 |
| ple 25 | | | | seconds | | | | | seconds | | | | |
| Exam- | R-26 | UL-1 | 55 | 100° C./60 | 0.17 | 70 | 20 | 1.60 | 90° C./60 | D-2 | 3 | 4 | 4 |
| ple 26 | | | | seconds | | | | | seconds | | | | |
| Exam- | R-27 | UL-1 | 50 | 120° C./60 | 0.23 | 168 | 11 | 0.30 | 120° C./60 | D-2 | 3 | 4 | 3 |
| ple 27 | | | | seconds | | | | | seconds | | | | |
| Exam- | R-28 | UL-1 | 60 | 100° C./60 | 0.16 | 452 | 20 | 1.95 | 100° C./60 | D-2 | 4 | 4 | 4 |
| ple 28 | | | | seconds | | | | | seconds | | | | |
| Exam- | R-29 | UL-2 | 60 | 90° C./90 | 0.24 | 585 | 6 | 0.40 | 90° C./90 | D-2 | 3 | 3 | 3 |
| ple 29 | | | | seconds | | | | | seconds | | | | |
| Exam- | R-30 | UL-1 | 50 | 100° C./60 | 0.20 | 252 | 10 | 1.83 | 105° C./60 | D-2 | 3 | 4 | 4 |
| ple 30 | | | | seconds | | | | | seconds | | | | |
| Exam- | R-31 | UL-1 | 50 | 100° C./60 | 0.16 | 437/257 | 35 | 2.43 | 100° C./60 | D-2 | 4 | 4 | 4 |
| ple 31 | | | | seconds | | | | | seconds | | | | |
| Exam- | R-32 | UL-1 | 55 | 120° C./60 | 0.18 | 347 | 40 | 1.00 | 100° C./60 | D-2 | 4 | 4 | 4 |
| ple 32 | | | | seconds | | | | | seconds | | | | |
| Exam- | R-37 | UL-1 | 50 | 100° C./60 | 0.15 | 437/257 | 25 | 3.33 | 120° C./60 | D-2 | 4 | 4 | 4 |
| ple 33 | | | | seconds | | | | | seconds | | | | |
| Exam- | R-38 | UL-1 | 50 | 100° C./60 | 0.15 | 437/257 | 25 | 3.24 | 120° C./60 | D-2 | 4 | 4 | 4 |
| ple 34 | | | | seconds | | | | | seconds | | | | |
| Exam- | R-39 | UL-1 | 50 | 100° C./60 | 0.15 | 437/257 | 25 | 4.99 | 120° C./60 | D-2 | 4 | 3 | 4 |
| ple 35 | | | | seconds | | | | | seconds | | | | |
| Exam- | R-40 | UL-1 | 50 | 100° C./60 | 0.15 | 437/257 | 25 | 2.90 | 120° C./60 | D-2 | 4 | 4 | 4 |
| ple 36 | | | | seconds | | | | | seconds | | | | |
| Exam- | R-41 | UL-1 | 50 | 100° C./60 | 0.15 | 437/257 | 25 | 1.04 | 120° C./60 | D-2 | 4 | 4 | 4 |
| ple 37 | | | | seconds | | | | | seconds | | | | |
| Exam- | R-42 | UL-1 | 50 | 100° C./60 | 0.15 | 437/257 | 25 | 0.40 | 120° C./60 | D-2 | 3 | 4 | 3 |
| ple 38 | | | | seconds | | | | | seconds | | | | |
| Exam- | R-43 | UL-1 | 50 | 100° C./60 | 0.15 | 437/257 | 25 | 0.78 | 120° C./60 | D-2 | 3 | 4 | 3 |
| ple 39 | | | | seconds | | | | | seconds | | | | |
| Exam- | R-44 | UL-2 | 50 | 120° C./30 | 0.17 | 244 | 15 | 2.00 | 105° C./30 | D-2 | 3 | 4 | 4 |
| ple 40 | | | | seconds | | | | | seconds | | | | |
| Exam- | R-45 | UL-1 | 60 | 100° C./60 | 0.19 | 354 | 15 | 2.00 | 100° C./60 | D-2 | 4 | 4 | 4 |
| ple 41 | | | | seconds | | | | | seconds | | | | |
| Exam- | R-46 | UL-1 | 60 | 100° C./60 | 0.19 | 354 | 15 | 2.00 | 100° C./60 | D-2 | 4 | 4 | 4 |
| ple 42 | | | | seconds | | | | | seconds | | | | |
| Exam- | R-47 | UL-1 | 50 | 100° C./60 | 0.14 | 437/257 | 21 | 0.96 | 110° C./60 | D-2 | 3 | 4 | 3 |
| ple 43 | | | | seconds | | | | | seconds | | | | |
| Exam- | R-48 | UL-1 | 50 | 100° C./60 | 0.14 | 437/257 | 21 | 1.89 | 110° C./60 | D-2 | 3 | 4 | 3 |
| ple 44 | | | | seconds | | | | | seconds | | | | |
| Exam- | R-49 | UL-1 | 50 | 100° C./60 | 0.14 | 437/257 | 21 | 2.00 | 110° C./60 | D-2 | 3 | 4 | 3 |
| ple 45 | | | | seconds | | | | | seconds | | | | |
| Compar- | R-33 | UL-1 | 50 | 100° C./60 | 0.11 | 347 | 6 | 2.00 | 100° C./60 | D-2 | 2 | 2 | 2 |
| ative | | | | seconds | | | | | seconds | | | | |
| Exam- | | | | | | | | | | | | | |
| ple 1 | | | | | | | | | | | | | |
| Compar- | R-34 | UL-2 | 55 | 90° C./60 | 0.12 | 168 | 10 | 0.76 | 90° C./60 | D-2 | 2 | 2 | 2 |
| ative | | | | seconds | | | | | seconds | | | | |
| Exam- | | | | | | | | | | | | | |
| ple 2 | | | | | | | | | | | | | |
| Compar- | R-35 | UL-1 | 55 | 100° C./60 | 0.11 | 135 | 18 | 0.92 | 90° C./90 | D-2 | 2 | 2 | 2 |
| ative | | | | seconds | | | | | seconds | | | | |
| Exam- | | | | | | | | | | | | | |
| ple 3 | | | | | | | | | | | | | |
| Compar- | R-36 | UL-1 | 55 | 100° C./60 | 0.11 | 437 | 40 | 0.92 | 110° C./60 | D-2 | 2 | 2 | 2 |
| ative | | | | seconds | | | | | seconds | | | | |
| Exam- | | | | | | | | | | | | | |
| ple 4 | | | | | | | | | | | | | |

(second Table thereof)

| | | | | | | | | | | | | | |
|---|---|---|---|---|---|---|---|---|---|---|---|---|---|
| Exam- | R-50 | UL-1 | 50 | 100° C./60 | 0.14 | 437/257 | 21 | 3.31 | 110° C./60 | D-2 | 4 | 4 | 4 |
| ple 46 | | | | seconds | | | | | seconds | | | | |
| Exam- | R-51 | UL-1 | 50 | 100° C./60 | 0.14 | 437/257 | 21 | 4.25 | 110° C./60 | D-2 | 4 | 4 | 4 |
| ple 47 | | | | seconds | | | | | seconds | | | | |
| Exam- | R-52 | UL-1 | 50 | 100° C./60 | 0.14 | 437/257 | 21 | 3.31 | 110° C./60 | D-2 | 4 | 4 | 4 |
| ple 48 | | | | seconds | | | | | seconds | | | | |
| Exam- | R-53 | UL-1 | 50 | 100° C./60 | 0.14 | 252 | 15 | 3.26 | 110° C./60 | D-2 | 3 | 4 | 4 |
| ple 49 | | | | seconds | | | | | seconds | | | | |
| Exam- | R-54 | UL-1 | 55 | 90° C./60 | 0.14 | 437/135 | 13 | 3.68 | 100° C./60 | D-2 | 4 | 4 | 4 |
| ple 50 | | | | seconds | | | | | seconds | | | | |
| Exam- | R-55 | UL-1 | 55 | 100° C./60 | 0.15 | 437/354 | 18 | 2.30 | 120° C./45 | D-3 | 4 | 4 | 4 |
| ple 51 | | | | seconds | | | | | seconds | | | | |
| Exam- | R-56 | UL-1 | 50 | 100° C./60 | 0.14 | 271 | 10 | 4.16 | 100° C./60 | D-2 | 4 | 4 | 4 |
| ple 52 | | | | seconds | | | | | seconds | | | | |
| Exam- | R-57 | UL-2 | 55 | 120° C./60 | 0.15 | 585 | 11 | 1.97 | 100° C./60 | D-2 | 4 | 4 | 4 |
| ple 53 | | | | seconds | | | | | seconds | | | | |
| Exam- | R-58 | UL-2 | 50 | 100° C./50 | 0.15 | 437/271 | 17 | 4.05 | 120° C./60 | D-5 | 4 | 4 | 4 |
| ple 54 | | | | seconds | | | | | seconds | | | | |
| Exam- | R-59 | UL-1 | 50 | 90° C./60 | 0.14 | 437/271 | 17 | 3.07 | 90° C./60 | D-2 | 4 | 4 | 4 |
| ple 55 | | | | seconds | | | | | seconds | | | | |
| Exam- | R-60 | UL-1 | 45 | 100° C./60 | 0.14 | 252 | 18 | 4.81 | 105° C./60 | D-2 | 3 | 3 | 4 |
| ple 56 | | | | seconds | | | | | seconds | | | | |
| Exam- | R-61 | UL-1 | 60 | 100° C./60 | 0.17 | 437/271 | 13 | 3.07 | 100° C./60 | D-2 | 4 | 4 | 4 |
| ple 57 | | | | seconds | | | | | seconds | | | | |
| Exam- | R-62 | UL-1 | 55 | 120° C./60 | 0.15 | 266/354 | 13 | 2.00 | 90° C./60 | D-3 | 4 | 4 | 4 |
| ple 58 | | | | seconds | | | | | seconds | | | | |
| Exam- | R-63 | UL-2 | 50 | 100° C./60 | 0.15 | 585 | 6 | 2.25 | 110° C./60 | D-2 | 4 | 4 | 4 |
| ple 59 | | | | seconds | | | | | seconds | | | | |
| Exam- | R-64 | UL-1 | 50 | 90° C./60 | 0.14 | 437/270 | 25 | 1.00 | 105° C./60 | D-2 | 4 | 4 | 4 |
| ple 60 | | | | seconds | | | | | seconds | | | | |
| Exam- | R-65 | UL-1 | 50 | 100° C./60 | 0.16 | 266/354 | 13 | 2.77 | 100° C./60 | D-2 | 4 | 4 | 4 |
| ple 61 | | | | seconds | | | | | seconds | | | | |
| Exam- | R-66 | UL-1 | 55 | 100° C./60 | 0.14 | 354 | 23 | 2.35 | 90° C./60 | D-2 | 4 | 4 | 4 |
| ple 62 | | | | seconds | | | | | seconds | | | | |
| Exam- | R-67 | UL-2 | 50 | 120° C./30 | 0.15 | 585 | 10 | 3.07 | 105° C./30 | D-2 | 4 | 4 | 4 |
| ple 63 | | | | seconds | | | | | seconds | | | | |

As shown in Tables described above, it was confirmed that the desired effect can be obtained by the method of forming a reversed pattern according to the embodiment of the present invention.

Particularly, it was confirmed that the effect was more excellent in a case where the content of the acid group was 0.80 to 4.50 mmol/g.

In addition, it was also confirmed that the effect was more excellent in a case where the volume of the acid generated from the photoacid generator was 270 Å³ or more.

The A1 values of the compositions R-1 to R-32 and R-37 to R-67 described above were all 0.14 or more.

### Examples 64 to 67, and Comparative Example 5

The composition shown in Table 4 was applied to a silicon wafer (12 inches) on which the underlayer film (thickness 200 nm) described in Table 4 was formed, and the coating film was heated under the bake conditions described in (Resist application conditions) to form a resist film having a film thickness shown in Table 4. As a result, a silicon wafer having the resist film was obtained.

Pattern irradiation was performed on the silicon wafer having the obtained resist film by using an EUV exposure apparatus (Micro Exposure Tool, NA0.3, Quadrupol, Outer Sigma 0.68, Inner Sigma 0.36, manufactured by Exitech Corporation). As the reticle, a mask having a line size=20 nm and line:space=1:1 was used.

Then, after baking (Post Exposure Bake (PEB)) under the conditions shown in Table 4 below, development was carried out by puddling organic-based developers shown in Table 4 for 30 seconds, and then the pattern reversal film forming composition was applied to the resist pattern formed. Thereafter, the silicon wafer coated with the pattern reversal film forming composition was spin-dried at 1500 rpm for 60 seconds and dried on a hot plate at 110° C. for one minute to form a pattern reversal film.

Next, by using RIE-10NR (manufactured by SAMCO Inc.) as a dry etching apparatus, the etch-back was performed on the pattern reversal film under the conditions of CF₄/Ar=50/200 sccm, 15 Pa, and 200 W to expose a surface of the resist pattern. Next, dry etching was performed under the conditions of O₂/N₂=10/20 sccm, 1 Pa, and 300 W to remove the resist pattern, and as a result, a reversed pattern was obtained. Thereafter, dry etching was performed under the conditions of CF₄/Ar=50/200 sccm, 15 Pa, and 200 W with the obtained reversed pattern as an etching mask, patterning was carried out on the underlayer film.

The LER, the embedability of a pattern reversal film forming composition, and the removal selectivity of a resist pattern were evaluated with respect to the obtained patterns in the same manner as above.

The dry etching rate of the resist film was evaluated by calculating a relative value with respect to the dry etching rate of the resist film obtained from the composition of Comparative Example 5. The evaluation is carried out in four stages, and 3 or higher is preferable.
4: The dry etching rate of the resist film was 20% or higher faster than the dry etching rate of the resist film obtained from the composition of Comparative Example 5, and neither roughness nor residue was observed between patterns of the reversed pattern.
3: The dry etching rate of the resist film was 5% or higher and lower than 20% faster than the dry etching rate of the resist film obtained from the composition of Comparative Example 5, and neither roughness nor residue was observed between patterns of the reversed pattern.
2: The dry etching rate of the resist film has few changes (less than 5%) or was slower than the dry etching rate of the resist film obtained from the composition of Comparative Example 5, and a little roughness or residue was observed between the reversed patterns.
1: The dry etching rate of the resist film has few changes (less than 5%) or was slower than the dry etching rate of the resist film obtained from the composition of Comparative Example 5, and roughness or residue was notably observed between the reversed patterns.

TABLE 4

| | | | | | Resist characteristic value | | | | | | | | |
|---|---|---|---|---|---|---|---|---|---|---|---|---|---|
| | | | | | | | Amount of | | | | Evaluation result | | |
| | Resist application conditions | | | | | Volume | photoacid | | | | | Embed- | |
| | | | Film | | | of gen- | generator | Content | | | | dability of | Removal |
| | | | thick- | | | erated | (Content: | of acid | | | | a pattern | selectivity |
| | Compo- | Base | ness | | A | acid | % by | group | PEB | Devel- | | reversal | of resist |
| | sition | film | [nm] | bake | Value | (Å³) | mass) | [mmol/g] | condition | oper | LER | film | pattern |
| Example | R-1 | UL-1 | 55 | 100° C./60 | 0.15 | 437/257 | 25 | 2.00 | 120° C./60 | D-6 | 4 | 4 | 4 |
| 64 | | | | seconds | | | | | seconds | | | | |
| Example | R-4 | UL-1 | 60 | 90° C./60 | 0.17 | 252 | 26 | 2.67 | 105° C./30 | D-6 | 3 | 4 | 4 |
| 65 | | | | seconds | | | | | seconds | | | | |
| Example | R-1 | UL-1 | 55 | 100° C./60 | 0.15 | 437/257 | 25 | 2.00 | 120° C./60 | D-7 | 4 | 4 | 4 |
| 66 | | | | seconds | | | | | seconds | | | | |
| Example | R-1 | UL-1 | 55 | 100° C./60 | 0.15 | 437/257 | 25 | 2.00 | 120° C./60 | D-8 | 4 | 4 | 4 |
| 67 | | | | seconds | | | | | seconds | | | | |
| Compar- | R-33 | UL-1 | 55 | 100° C./60 | 0.11 | 347 | 6 | 2.00 | 100° C./60 | D-6 | 2 | 2 | 2 |
| ative | | | | seconds | | | | | seconds | | | | |
| Example | | | | | | | | | | | | | |
| 5 | | | | | | | | | | | | | |

As shown in Tables described above, it was confirmed that the desired effect can be obtained by the method of forming a reversed pattern according to the embodiment of the present invention.

### EXPLANATION OF REFERENCES

10 substrate
12 resist film
14 mask
16 resist pattern
18 pattern reversal film
20 reversed pattern

1. A method of forming a reversed pattern comprising:
a step of forming a resist film on a substrate using a photosensitive composition having an A value of 0.14 or more, which is determined by Expression (1);
a step of exposing the resist film to light;
a step of developing the exposed resist film to form a resist pattern;
a step of applying a pattern reversal film forming composition such that the resist pattern is coated and thereby forming pattern reversal film;
a step of performing etch-back on the pattern reversal film and exposing a surface of the resist pattern to light; and
a step of removing the resist pattern to form the reversed pattern,
A=([H]×0.04+[C]×1.0+[N]×2.1+[O]×3.6+[F]×5.6+[S]×0.04+[I]×39.5)/([H]×1+[C]×12+[N]×14+[O]×16+[F]×19+[S]×32+[I]×127), Expression (1):
in Expression (1), [H] represents a molar ratio of hydrogen atoms derived from a total solid content to all atoms of the total solid content in the photosensitive composition,
[C] represents a molar ratio of carbon atoms derived from a total solid content to all atoms of the total solid content in the photosensitive composition,
[N] represents a molar ratio of nitrogen atoms derived from a total solid content to all atoms of the total solid content in the photosensitive composition,
[O] represents a molar ratio of oxygen atoms derived from a total solid content to all atoms of the total solid content in the photosensitive composition,
[F] represents a molar ratio of fluorine atoms derived from a total solid content to all atoms of the total solid content in the photosensitive composition,
[S] represents a molar ratio of sulfur atoms derived from a total solid content to all atoms of the total solid content in the photosensitive composition, and
[I] represents a molar ratio of iodine atoms derived from a total solid content to all atoms of the total solid content in the photosensitive composition.

2. The method of forming a reversed pattern according to claim 1, wherein the photosensitive composition includes a resin whose solubility in an alkaline developer increases and solubility in an organic solvent decreases due to increase in polarity by an action of an acid, and a photoacid generator consisting of a cationic moiety and an anionic moiety.

3. The method of forming a reversed pattern according to claim 2, wherein a content of the photoacid generator is 5% to 50% by mass with respect to a total solid content in the photosensitive composition.

4. The method of forming a reversed pattern according to claim 2, wherein the resin includes an acid group having an acid dissociation constant of 13 or less.

5. The method of forming a reversed pattern according to claim 4, wherein a content of the acid group is 0.80 to 4.50 mmol/g.

6. The method of forming a reversed pattern according to claim 2, wherein an acid generated from the photoacid generator has a volume of 270 Å³ or more.

7. The method of forming a reversed pattern according to claim 1, wherein the step of exposing is carried out with extreme ultraviolet rays.

8. A method of manufacturing an electronic device which includes the method of forming a reversed pattern according to claim 1.
